(19) United States
(12) Patent Application Publication
(10) Pub. No.: US 2025/0060673 A1
(43) Pub. Date: Feb. 20, 2025

(54) DEVELOPMENT STRATEGY FOR HIGH-ABSORBING METAL-CONTAINING PHOTORESISTS

(71) Applicant: Lam Research Corporation, Fremont, CA (US)

(72) Inventors: Chenghao Wu, San Jose, CA (US); Eric Calvin Hansen, San Jose, CA (US); Timothy William Weidman, Sunnyvale, CA (US); Jason Philip Coyle, San Jose, CA (US); Raymond Nicholas Vrtis, Carlsbad, CA (US)

(21) Appl. No.: 18/719,815

(22) PCT Filed: Dec. 16, 2022
(86) PCT No.: PCT/US2022/081845

§ 371 Date: Jun. 13, 2024

Related U.S. Application Data
(60) Provisional application No. 63/265,558, filed on Dec. 16, 2021.

(51) Int. Cl. G03F 7/36; G03F 7/00; G03F 7/32; G03F 7/40; H01L 21/027

(52) U.S. Cl. CPC G03F 7/36; G03F 7/32; G03F 7/40; G03F 7/70033; G03F 7/70525; H01L 21/0274

(57) ABSTRACT

The present disclosure relates to use of an acid for developing or treating a radiation-sensitive film including two or more elements having a high patterning radiation-absorption cross-section. The acid can be employed to form a pattern by a negative tone development process or to treat a developed pattern by further removing residual resist components.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### FIELD

The present disclosure relates to use of an acid for developing or treating a radiation-sensitive film including two or more elements having a high patterning radiation-absorption cross-section. The acid can be employed to form a pattern by a negative tone development process or to treat a developed pattern by further removing residual resist components.

### BACKGROUND

As semiconductor fabrication continues to advance, feature sizes continue to shrink, and new processing methods are needed. One area where advances are being made is in the context of patterning, for example using photoresist materials that are sensitive to lithographic radiation.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, materials, apparatus, and systems for developing or treating a photoresist (PR) material on a substrate. In particular, the PR film includes two or more highly absorbing elements. While having such a combination of elements can enhance absorptive properties of the film, removing or solubilizing such elements during development can be challenging. Described herein are methods and processes employing an acid (in vapor or liquid form) to remove such films having two or more highly absorbing elements. Non-limiting examples of such elements include tin (Sn), indium (In), bismuth (Bi), antimony (Sb), tellurium (Te), an oxide thereof, an alloy thereof, or a combination thereof.

In one instance, the acid can be employed to form a pattern by a negative tone development process. When negative tone development is employed with organometallic photoresists (PR), the radiation-exposed regions can be processed to provide dense, metal oxide (MOx)-containing networks. Acid can be used as a dry development process or a wet development process to remove unexposed regions. The use of an acid can assist in removing such regions, even though they may have two or more different highly absorbing elements.

In another instance, the acid can be employed to treat a developed pattern by further removing residual resist components. The use of an acid can assist in removing any residual species remaining after development, even if such species possess two or more highly absorbing elements. For instance, such residual species may include volatile metal species. Here, the acid can be provided as a dry treatment process or a wet treatment process.

Accordingly, in a first aspect, the present disclosure features a method including: exposing a radiation-sensitive resist film to a patterning radiation source, thereby providing an exposed resist film having an exposed region and an unexposed region, wherein the resist film includes two or more elements having a high patterning radiation-absorption cross-section; developing the exposed resist film by removing the unexposed region, thereby forming a pattern by a negative tone development process; and optionally treating the pattern. In some embodiments, the method includes either: performing said developing in the presence of an acid, or performing said treating the pattern in the presence of an acid.

In some embodiments, the method includes performing said developing in the presence of an acid. In particular embodiments, said developing includes a dry development process.

In some embodiments, said developing includes delivering a vapor of an acid to the exposed film. Non-limiting acids include an inorganic acid, a halogen-containing acid, a hydrogen halide, an organic acid, a phosphorus oxoacid, a sulfur oxoacid, a carboxylic acid, or a silyl halide. In particular embodiments, the inorganic acid is selected from the group consisting of hydrogen chloride (HCl), hydrogen bromide (HBr), hydrogen iodide (HI), and a combination thereof. In some embodiments, the organic acid include a vapor pressure of at least about 15 Torr. In other embodiments, the organic acid includes formic acid, acetic acid, trifluoroacetic acid, or a combination thereof.

In some embodiments, said developing includes delivering a vapor of a reactant configured to provide an acid to the exposed film. Non-limiting reactants configured to provide the acid includes a halogenated borane including trichloroborane (BCl₃), tribromoborane (BBr₃), triiodoborane (BI₃), a halogenated silane including tetrachlorosilane (SiCl₄), tetrabromosilane (SiBr₄), tetraiodosilane (SiI₄), a trialkyl silyl halide including trimethylsilyl chloride, trimethylsilyl bromide, trimethylsilyl iodide, triethylsilyl chloride, triethylsilyl bromide, triethylsilyl iodide, tripropylsilyl chloride, tripropylsilyl bromide, tripropylsilyl iodide, triisopropylsilyl chloride, triisopropylsilyl bromide, triisopropylsilyl iodide, tributylsilyl chloride, tributylsilyl bromide, tributylsilyl iodide, triisobutylsilyl chloride, triisobutylsilyl bromide, triisobutylsilyl iodide, trisecbutylsilyl chloride, trisecbutylsilyl bromide, trisecbutylsilyl iodide, tritertbutylsilyl chloride, tritertbutylsilyl bromide, tritertbutylsilyl iodide, dimethyl-ethyl-silyl chloride, dimethyl-propyl-silyl chloride, dimethyl-isopropyl-silyl chloride, dimethyl-butyl-silyl chloride, dimethyl-isobutyl-silyl chloride, dimethyl-secbutyl-silyl chloride, dimethyl-tertbutyl-silyl chloride, dimethyl-tertbutyl-silyl bromide, dimethyl-tertbutyl-silyl iodide, methyl-diethyl-silyl chloride, methyl-diethyl-silyl bromide, methyl-diethyl-silyl iodide, methyl-dipropyl-silyl chloride, methyl-diisopropyl-silyl chloride, methyl-dibutyl-silyl chloride, methyl-diisobutyl-silyl chloride, methyl-disecbutyl-silyl chloride, methyl-ditertbutyl-silyl chloride, methyl-ditertbutyl-silyl bromide, methyl-ditertbutyl-silyl iodide, a dialkyl dihalo silane including: dimethyldichloro silane, dimethyldibromo silane, dimethyldiiodo silane, diethyldichloro silane, diethyldibromo silane, diethyldiiodo silane, dipropyldichloro silane, dipropyldibromo silane, dipropyldiiodo silane, diisopropyldichloro silane, diisopropyldibromo silane, diisopropyldiiodo silane, dibutyldichloro silane, dibutyldibromo silane, dibutyldiiodo silane, diisobutyldichloro silane, diisobutyldibromo silane, diisobutyldiiodo silane, disecbutyldichloro silane, disecbutyldibromo silane, disecbutyldiiodo silane, ditertbutyldichloro silane, ditertbutyldibromo silane, ditertbutyldiiodo silane, methyl-ethyl-dichloro silane, methyl-ethyl-dibromo silane, methyl-ethyl-diiodo silane, methyl-propyl-dichloro silane, methyl-isopropyl-dichloro silane, methyl-butyl-dichloro silane, methyl-isobutyl-dichloro silane, methyl-secbutyl-dichloro silane, methyl-tertbutyl-dichloro silane, methyl-tertbutyl-dibromide silane, methyl-tertbutyl-diiodo silane, or a combination thereof.

In some embodiments, said developing further includes delivering a vapor of an oxygen-containing reagent. Non-limiting oxygen-containing reagents include oxygen (O₂), ozone (O₃), hydrogen peroxide (H₂O₂), or other reagents include one or more oxygen atoms.

In some embodiments, said developing includes a wet development process. In particular embodiments, said developing includes delivering the acid in a solvent. Non-limiting acids include an inorganic acid (e.g., hydrogen chloride (HCl), hydrogen bromide (HBr), hydrogen iodide (HI), phosphoric acid, sulfuric acid, and a combination thereof), a halogen-containing acid, a hydrogen halide, an organic acid (e.g., formic acid, acetic acid, trifluoroacetic acid, oxalic acid, citric acid, or a combination thereof), a phosphorus oxoacid, a sulfur oxoacid, a carboxylic acid, any described herein, or a combination of any of these. Non-limiting solvents include an aqueous solvent or an organic solvent, such as water, an alcohol, a ketone, an ether, an ester, or a combination thereof.

In some embodiments, said developing is conducted at a temperature of about −10° C. to 200° C. to remove volatile products present within the unexposed regions. In further embodiments, the method includes (e.g., after said developing): performing a plasma-based etch process. In other embodiments, the method includes (e.g., after said developing): performing a post-development bake (PDB).

In some embodiments, the method includes performing said treating the pattern in the presence of an acid. Non-limiting acids include any described herein, such as an inorganic acid, a halogen-containing acid, a hydrogen halide, an organic acid, a phosphorus oxoacid, a sulfur oxoacid, a carboxylic acid, or a combination of any of these

In some embodiments, said developing includes use of an acidic developer. Optionally, such an acidic developer can be used to provide a pattern, which can then be treated in the presence of an acid, as described herein. In particular embodiments, said developing includes use of a vapor-based acidic etchant. Non-limiting the vapor-based acidic etchants include hydrogen chloride (HCl), hydrogen bromide (HBr), boron trichloride (BCl₃), silicon tetrachloride (SiCl₄), a combination of hydrogen gas (H₂) and chlorine gas (Cl₂), or a combination of hydrogen gas (H₂) and bromine gas (Br₂), or a trialkyl silyl halide including trimethylsilyl chloride, trimethylsilyl bromide, trimethylsilyl iodide, triethylsilyl chloride, triethylsilyl bromide, triethylsilyl iodide, tripropylsilyl chloride, tripropylsilyl bromide, tripropylsilyl iodide, triisopropylsilyl chloride, triisopropylsilyl bromide, triisopropylsilyl iodide, tributylsilyl chloride, tributylsilyl bromide, tributylsilyl iodide, triisobutylsilyl chloride, triisobutylsilyl bromide, triisobutylsilyl iodide, trisecbutylsilyl chloride, trisecbutylsilyl bromide, trisecbutylsilyl iodide, tritertbutylsilyl chloride, tritertbutylsilyl bromide, tritertbutylsilyl iodide, dimethyl-ethyl-silyl chloride, dimethyl-propyl-silyl chloride, dimethyl-isopropyl-silyl chloride, dimethyl-butyl-silyl chloride, dimethyl-isobutyl-silyl chloride, dimethyl-secbutyl-silyl chloride, dimethyl-tertbutyl-silyl chloride, dimethyl-tertbutyl-silyl bromide, dimethyl-tertbutyl-silyl iodide, methyl-diethyl-silyl chloride, methyl-diethyl-silyl bromide, methyl-diethyl-silyl iodide, methyl-dipropyl-silyl chloride, methyl-diisopropyl-silyl chloride, methyl-dibutyl-silyl chloride, methyl-diisobutyl-silyl chloride, methyl-disecbutyl-silyl chloride, methyl-ditertbutyl-silyl chloride, methyl-ditertbutyl-silyl bromide, methyl-ditertbutyl-silyl iodide, a dialkyl dihalo silane including: dimethyldichloro silane, dimethyldibromo silane, dimethyldiiodo silane, diethyldichloro silane, diethyldibromo silane, diethyldiiodo silane, dipropyldichloro silane, dipropyldibromo silane, dipropyldiiodo silane, diisopropyldichloro silane, diisopropyldibromo silane, diisopropyldiiodo silane, dibutyldichloro silane, dibutyldibromo silane, dibutyldiiodo silane, diisobutyldichloro silane, diisobutyldibromo silane, diisobutyldiiodo silane, disecbutyldichloro silane, disecbutyldibromo silane, disecbutyldiiodo silane, ditertbutyldichloro silane, ditertbutyldibromo silane, ditertbutyldiiodo silane, methyl-ethyl-dichloro silane, methyl-ethyl-dibromo silane, methyl-ethyl-diiodo silane, methyl-propyl-dichloro silane, methyl-isopropyl-dichloro silane, methyl-butyl-dichloro silane, methyl-isobutyl-dichloro silane, methyl-secbutyl-dichloro silane, methyl-tertbutyl-dichloro silane, methyl-tertbutyl-dibromide silane, methyl-tertbutyl-diiodo silane, or a combination thereof.

In some embodiments, said treating includes removing a residual species containing at least one of the two or more elements having the high patterning radiation-absorption cross-section. In particular embodiments, said treating includes a dry process. For instance, said treating can include delivering a vapor of the acid or a reactant configured to provide the acid to the exposed film.

In other embodiments, said treating includes a wet process. In particular embodiments, said treating includes delivering the acid in a solvent. Non-limiting acids include an inorganic acid, a halogen-containing acid, a hydrogen halide, an organic acid, a phosphorus oxoacid, a sulfur oxoacid, a carboxylic acid, any acid described herein, or a combination of any of these.

In some embodiments, the method further includes (e.g., after said treating): rinsing the pattern with a solvent (e.g., any solvent described herein). After such a rinse, an optional drying operation can be performed.

In a second aspect, the present disclosure encompasses a method including: exposing a radiation-sensitive resist film to a patterning radiation source, thereby providing an exposed resist film having an exposed region and an unexposed region, wherein the resist film includes two or more elements having a high patterning radiation-absorption cross-section; developing the exposed resist film by removing the unexposed region with an acid, thereby forming a pattern by a negative tone dry development process; and treating the pattern with a plasma-based etch process.

In some embodiments, said developing includes an oxygen-containing reagent (e.g., any described herein).

In some embodiments, the method further includes (e.g., after said developing): performing a post-development bake (PDB).

In some embodiments, the resist film includes an Extreme Ultraviolet (EUV)-sensitive photoresist layer or an EUV-sensitive inorganic photoresist layer. In further embodiments, the patterning radiation source includes an EUV radiation source.

In some embodiments, the method further includes (e.g., before said exposing): applying the radiation-sensitive resist film on a surface of a substrate; and optionally providing a radiation-absorbing layer between the resist film and the substrate. In other embodiments, the method further includes (e.g., before said exposing): providing a radiation-absorbing layer on a surface of a substrate.

In some embodiments, the method further includes: applying the radiation-sensitive resist film on a surface of the radiation-absorbing layer. In particular embodiments, said applying includes: providing one or more precursors including a structure having formula (I), formula (II), or any precursor described herein to the surface of the substrate. In other embodiments, said applying includes: providing a first precursor including tellurium (Te) and a second precursor including tin (Sn) to the surface of the substrate, wherein the first and second precursors are each provided in any order or simultaneously to the substrate.

In yet other embodiments, said providing the radiation-absorbing layer includes providing a first precursor, and said applying the radiation-sensitive resist film includes providing a second precursor, wherein the first precursor includes a first atom having a high EUV absorption cross-section, wherein the second precursor includes a second atom having a high EUV absorption cross-section, and wherein the first atom and the second atom are different. In particular embodiments, the first atom includes tellurium (Te), bismuth (Bi), indium (In), or antimony (Sb); and the second atom includes tin (Sn).

In a third aspect, the present disclosure encompasses an apparatus for processing a substrate, the apparatus including: one or more process chambers, each process chamber optionally including a chuck or a pedestal; one or more inlets into the process chambers and associated flow-control hardware; and a controller having at least one processor and a memory.

In some embodiments, the at least one processor and the memory are communicatively connected with one another; the at least one processor is at least operatively connected with the flow-control hardware; and the memory stores computer-executable instructions for controlling the at least one processor to at least control the flow-control hardware and for causing any of method described herein.

In a fourth aspect, the present disclosure features an apparatus for forming a resist film, the apparatus including: a deposition module, a patterning module, a development module, an optional treatment module, and a controller including one or more memory devices, one or more processors, and system control software coded with instructions including machine-readable instructions.

In some embodiments, the deposition module includes a chamber for depositing a resist film (e.g., a patterning radiation-sensitive film, such as an EUV-sensitive film), in which the chamber can be configured to house a semiconductor substrate. In other embodiments, the patterning module includes a photolithography tool with a source of sub-300 nm wavelength radiation (e.g., in which the source can be a source of sub-30 nm wavelength radiation). In some embodiments, the development module includes a chamber for developing the resist film. In other embodiments, the treatment module includes a chamber for treating the resist film (e.g., the resist film having a pattern).

In further embodiments, the instructions include machine-readable instructions for (e.g., in the deposition module) causing deposition of a precursor in the optional presence of a counter-reactant on a top surface of a semiconductor substrate to form the resist film. In some embodiments, such deposition can form the patterning radiation-sensitive film as a resist film.

In some embodiments, the instructions include machine-readable instructions for (e.g., in the patterning module) causing patterning of the resist film with sub-300 nm resolution (e.g., or with sub-30 nm resolution) directly by patterning radiation exposure (e.g., by EUV exposure), thereby forming an exposed film having radiation exposed areas and radiation unexposed areas. In other embodiments, the exposed film has EUV exposed areas and EUV unexposed areas.

In other embodiments, the instructions include machine-readable instructions for (e.g., in the development module) causing development of the film to remove the radiation exposed areas or the radiation unexposed areas to provide a pattern within the resist film. In particular embodiments, the machine-readable instructions include instructions for causing removal of the EUV exposed areas or the EUV unexposed areas. In some embodiments, such development can include delivering one or more acids into the development module.

In yet other embodiments, the instructions include machine-readable instructions for (e.g., in the treatment module) causing treatment of the film to remove residual species from the film. In some embodiments, such treatment can include delivering one or more acids into the treatment module.

In any embodiment herein, the acid includes an inorganic acid, a halogen-containing acid, a hydrogen halide, an inorganic acid, a phosphorus oxoacid, a sulfur oxoacid, or a carboxylic acid. Such an acid can be provided within a dry process (e.g., as a vapor) or a wet process (e.g., as a liquid).

In any embodiment herein, the reactant configured to provide the acid includes a halogenated borane including trichloroborane (BCl₃), tribromoborane (BBr₃), triiodoborane (BI₃), a halogenated silane including tetrachlorosilane (SiCl₄), tetrabromosilane (SiBr₄), tetraiodosilane (SiI₄), a trialkyl silyl halide including trimethylsilyl chloride, trimethylsilyl bromide, trimethylsilyl iodide, triethylsilyl chloride, triethylsilyl bromide, triethylsilyl iodide, tripropylsilyl chloride, tripropylsilyl bromide, tripropylsilyl iodide, triisopropylsilyl chloride, triisopropylsilyl bromide, triisopropylsilyl iodide, tributylsilyl chloride, tributylsilyl bromide, tributylsilyl iodide, triisobutylsilyl chloride, triisobutylsilyl bromide, triisobutylsilyl iodide, trisecbutylsilyl chloride, trisecbutylsilyl bromide, trisecbutylsilyl iodide, tritertbutylsilyl chloride, tritertbutylsilyl bromide, tritertbutylsilyl iodide, dimethyl-ethyl-silyl chloride, dimethyl-propyl-silyl chloride, dimethyl-isopropyl-silyl chloride, dimethyl-butyl-silyl chloride, dimethyl-isobutyl-silyl chloride, dimethyl-secbutyl-silyl chloride, dimethyl-tertbutyl-silyl chloride, dimethyl-tertbutyl-silyl bromide, dimethyl-tertbutyl-silyl iodide, methyl-diethyl-silyl chloride, methyl-diethyl-silyl bromide, methyl-diethyl-silyl iodide, methyl-dipropyl-silyl chloride, methyl-diisopropyl-silyl chloride, methyl-dibutyl-silyl chloride, methyl-diisobutyl-silyl chloride, methyl-disecbutyl-silyl chloride, methyl-ditertbutyl-silyl chloride, methyl-ditertbutyl-silyl bromide, methyl-ditertbutyl-silyl iodide, a dialkyl dihalo silane including: dimethyldichloro silane, dimethyldibromo silane, dimethyldiiodo silane, diethyldichloro silane, diethyldibromo silane, diethyldiiodo silane, dipropyldichloro silane, dipropyldibromo silane, dipropyldiiodo silane, diisopropyldichloro silane, diisopropyldibromo silane, diisopropyldiiodo silane, dibutyldichloro silane, dibutyldibromo silane, dibutyldiiodo silane, diisobutyldichloro silane, diisobutyldibromo silane, diisobutyldiiodo silane, disecbutyldichloro silane, disecbutyldibromo silane, disecbutyldiiodo silane, ditertbutyldichloro silane, ditertbutyldibromo silane, ditertbutyldiiodo silane, methyl-ethyl-dichloro silane, methyl-ethyl-dibromo silane, methyl-ethyl-diiodo silane, methyl-propyl-dichloro silane, methyl-isopropyl-dichloro silane, methyl-butyl-dichloro silane, methyl-isobutyl-dichloro silane, methyl-secbutyl-dichloro silane, methyl-tertbutyl-dichloro silane, methyl-tertbutyl-dibromide silane, methyl-tertbutyl-diiodo silane, or a combination thereof. Yet other reactants are described herein.

In any embodiment herein, the patterning radiation-sensitive film includes an extreme ultraviolet (EUV)-sensitive film, an EUV-sensitive inorganic photoresist layer, a deep-ultraviolet (DUV)-sensitive film, a photoresist film, or a photopatternable film.

In any embodiment herein, the resist film includes tin (Sn), indium (In), bismuth (Bi), antimony (Sb), tellurium (Te), an oxide thereof, an alloy thereof, or a combination thereof.

In any embodiment herein, the resist film includes a chemical vapor deposited (CVD) film, a spin-on film, an organometallic oxide film, an organometallic oxide hydroxide film, a tin oxide film, or an organotin oxide film.

In any embodiment herein, a precursor (e.g., to provide a resist film) includes a structure having formula (I):

MₐR_{b} (I),
wherein: M is a metal or an atom having a high EUV absorption cross-section; each R is, independently, H, halo, optionally substituted alkyl, optionally substituted cycloalkyl, optionally substituted cycloalkenyl, optionally substituted alkenyl, optionally substituted alkynyl, optionally substituted alkoxy, optionally substituted alkanoyloxy, optionally substituted aryl, optionally substituted amino, optionally substituted bis(trialkylsilyl)amino, optionally substituted trialkylsilyl, oxo, an anionic ligand, a neutral ligand, or a multidentate ligand; a≥1; and b≥1.

In any embodiment herein, a precursor (e.g., to provide a resist film) includes a structure having formula (II):

MₐR_{b}L_{c} (II),
wherein: M is a metal or an atom having a high EUV absorption cross-section; each R is, independently, halo, optionally substituted alkyl, optionally substituted aryl, optionally substituted amino, optionally substituted alkoxy, or L; each L is, independently, a ligand, an anionic ligand, a neutral ligand, a multidentate ligand, ion, or other moiety that is reactive with a counter-reactant, in which R and L with M, taken together, can optionally form a heterocyclyl group or in which R and L, taken together, can optionally form a heterocyclyl group; a≥1; b≥1; and c≥1.

In any embodiment herein, a precursor (e.g., to provide a resist film) includes one or more precursors selected from: InR₃, wherein each R is, independently, halo, optionally substituted C₁₋₁₂ alkyl, or diketonate; SnR₂ or SnR₄, wherein each R is, independently, halo, optionally substituted C₁₋₁₂ alkoxy, optionally substituted amino, optionally substituted aryl, cyclopentadienyl, or a diketonate; BiR₃, wherein each R is, independently, halo, optionally substituted C₁₋₁₂ alkyl, mono-C₁₋₁₂ alkylamino, di-C₁₋₁₂ alkylamino, optionally substituted aryl, optionally substituted bis(trialkylsilyl)amino, or a diketonate; SbR₃, wherein each R is, independently, halo, optionally substituted C₁₋₁₂ alkyl, optionally substituted C₁₋₁₂ alkoxy, or optionally substituted amino; or TeR₂ or TeR₄, wherein each R is, independently, halo, optionally substituted C₁₋₁₂ alkyl, optionally substituted C₁₋₁₂ alkoxy, optionally substituted aryl, hydroxyl, oxo, or optionally substituted trialkylsilyl.

In any embodiment herein, said providing the resist film or said depositing the resist film further includes providing a counter-reactant. Non-limiting counter-reactants include oxygen or a chalcogenide precursor, as well as any described herein (e.g., an oxygen-containing counter-reactant, including oxygen (O₂), ozone (O₃), water, a peroxide, hydrogen peroxide, oxygen plasma, water plasma, an alcohol, a dihydroxy alcohol, a polyhydroxy alcohol, a fluorinated dihydroxy alcohol, a fluorinated polyhydroxy alcohol, a fluorinated glycol, formic acid, and other sources of hydroxyl moieties, as well as combinations thereof).

Other features and advantages of the disclosure will be apparent from the following description and the claims.

### BRIEF DESCRIPTION OF THE DRAWINGS

FIG. 1A-1D presents schematic diagrams of non-limiting patterning structures. Provided are (A) a structure having a substrate 101 and a homogeneous film 102 with a relatively low EUV absorption of 30%; (B) another structure having a substrate 111 and a homogeneous film 112 with a relatively high EUV absorption of 90%; (C) a structure having a substrate 121 and a gradient film 122; and (D) a structure having a substrate 131, a film 132, and a radiation-absorbing layer 133 under the film 132.

FIG. 1E presents a non-limiting graph showing extreme ultraviolet (EUV) photoabsorption cross-sections of various elements. Absorption of EUV light (92 eV, 13.5 nm) associated with excitation of inner shell electrons can have little dependence on chemical bonding.

FIG. 2A-2C presents a schematic diagrams of non-limiting methods for making and using a patterning structure.

FIG. 3A-3D presents reaction schemes between a non-limiting first precursors and non-limiting second precursors.

FIG. 4A-4B presents schematic diagram of non-limiting methods that employ an acid with a resist film. Provided are (A) a non-limiting method 400 using a negative tone development process with the acid; (B) another non-limiting method 450 using a negative tone development process and then treatment with an acid.

FIG. 5A-5E presents schematic block diagrams of non-limiting methods for making and using a resist film.

FIG. 6 presents a schematic illustration of an embodiment of a process station 600 for dry development.

FIG. 7 presents a schematic illustration of an embodiment of a multi-station processing tool 700.

FIG. 8 presents a schematic illustration of an embodiment of an inductively coupled plasma apparatus 800.

FIG. 9 presents a schematic illustration of an embodiment of a semiconductor process cluster tool architecture 900.

FIG. 10 depicts a cross-sectional schematic view of an example of a dry deposition apparatus 1000.

### DETAILED DESCRIPTION

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

The present disclosure relates to methods for processing a photoresist (PR) film including two or more highly absorbing elements. Differing atoms can exhibit differing sensitivity to radiation absorption. By increasing the concentration of highly absorbing elements within the film, the absorptive properties of the film can be enhanced. Non-limiting examples of such elements include tin (Sn), indium (In), bismuth (Bi), antimony (Sb), tellurium (Te), as well as others described herein. Such films can also be configured to include an absorbing layer including such elements, and the methods and processes herein can be used to develop films having such an absorbing layer.

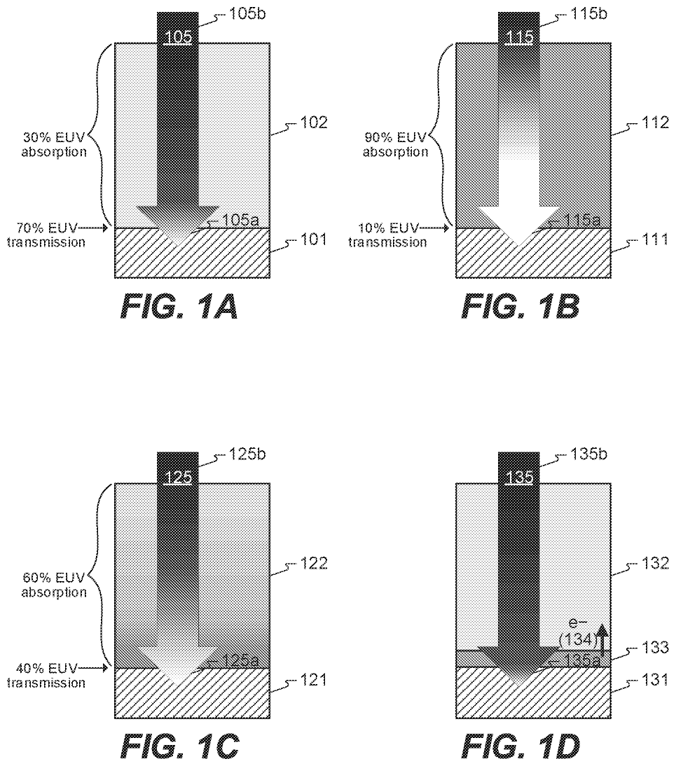

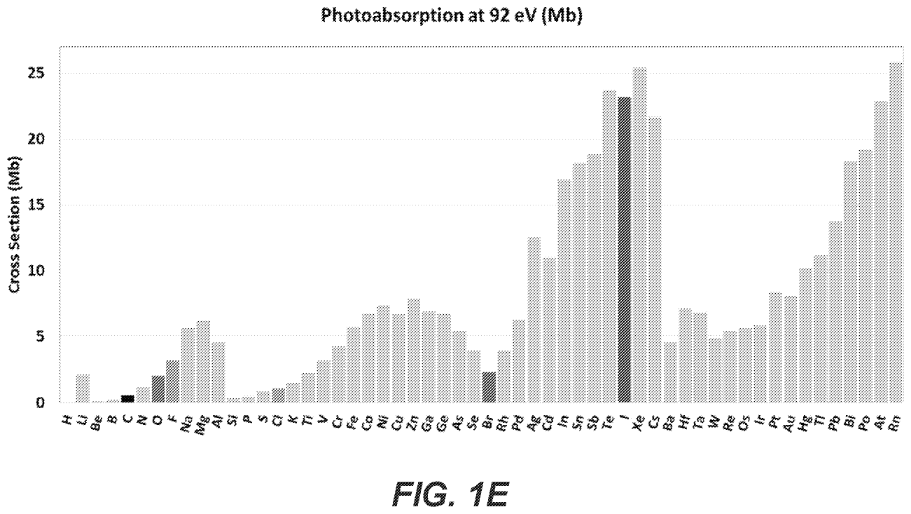

Another strategy that can further improve the radiation sensitivity in a PR film is to create a film in which the film composition is vertically graded, resulting in depth-dependent radiation sensitivity. In a homogenous PR with a high absorption coefficient, the decreasing light intensity throughout the film depth can employ a higher radiation dose to ensure the bottom is sufficiently exposed. By increasing the density of atoms with high radiation absorptivity at the bottom of the film relative to the top of the film (e.g., by creating a gradient with increasing radiation absorption), it becomes possible to more efficiently use available photons while more uniformly distributing absorption (and the effects of secondary electrons) towards the bottom of more highly absorbing films. The methods and processes herein can be used to develop such gradient films. Other examples of patterning structures and films are described in FIG. 1A-1D.

In particular, the methods herein employ an acid, as part of a dry process or a wet process, to develop or treat a film having two or more highly absorbing elements. The presence of two or more different elements can improve radiation absorption, but removing undesired regions including such elements can be challenging. Taking the example of a bimetallic film having two elements (e.g., tin (Sn) and tellurium (Te)), the Te-containing species can be difficult to remove as such species can exhibit low volatility. Furthermore, most solvents do not dissolve both Sn-containing species and Te-containing species. Described herein are acid-containing development processes (e.g., to remove radiation-unexposed region) and acid-containing treatment processes (e.g., to remove residual metal-containing species after development), in which such processes can be wet or dry.

In one non-limiting embodiment, the present disclosure encompasses dry development methods for highly absorbing metal-containing photoresist (PR) films (e.g., bimetallic PR containing Sn and Te). In particular non-limiting embodiments, the PR films are employed in conjunction with extreme ultraviolet (EUV) lithography. The presence of such highly absorbing metal elements (e.g., Te, antimony (Sb), bismuth (Bi), and the like) incorporated into the film can further EUV absorption and potentially lower lithographic cost.

Incorporation of new elements generally changes the composition and properties of the PRs, and such changes can require additional development methods. By using the vapor of an acid (e.g., an inorganic acid; a hydrogen halide, such as hydrogen chloride (HCl), hydrogen bromide (HBr), and the like; an organic acid, such as trifluoroacetic acid, or others described herein), such bimetallic PR films (or other films having two or more highly absorbing elements) can be developed, thereby generating negative tone patterns.

In some embodiments, development includes providing a vapor including an acid or including a reactant configured to provide the acid. Non-limiting acids and reagents are described herein. In one instance, the acid includes a halogen-containing acid (e.g., HBr, HCl, HI, HF, and the like), and the reagents include those that can provide such an acid. Examples of such reagents include boron halides (e.g., BX₃, in which X is F, Cl, Br, or I), silicon halides (e.g., SiX₄, in which X is F, Cl, Br, or I), hydrogen halides (e.g., HX, in which X is F, Cl, Br, or I), a hydrogen gas (H₂), and a halogen gas (e.g., X₂, in which X is F, Cl, or Br), and combinations thereof (e.g., a combination of H₂ with X₂).

In one embodiment, vapors of inorganic acid molecules (such as HCl, HBr, and possibly HI) as well as molecules that can decompose or hydrolyze to generate these acid molecules (e.g., BCl₃ or SiCl₄), are able to selectively remove the unexposed films (e.g., unexposed organic tin tellurium films), thereby generating negative tone patterns. However, the reaction products of certain elements (e.g., tellurium halides, such as TeCl₂ and/or TeBr₂) have much lower volatility than other elements (e.g., tin halides, such as SnCl₄ and/or SnBr₄). Lower volatility species can be removed by using higher temperatures, either during deposition (e.g., up to 200° C.) or during a post-development hard bake step in order to vaporize the reaction products.

In addition to inorganic acid molecules, the acid can be an organic acid. In particular embodiments, the acid has a high vapor pressure and selectively removes unexposed films. Non-limiting examples of organic acids include trifluoroacetic acid, formic acid, acetic acid, and the like.

In certain embodiments, development can include the use of an acid in combination with an oxygen-containing reagent (e.g., oxygen gas (O₂), ozone (O₃), hydrogen peroxide (H₂O₂), and the like) to produce more consistent etch results.

Any useful process conditions can be applied during development. For example, a process may be conducted at a pressure of less than about 3 Torr (e.g., such as from 10 mTorr to 2 Torr), at temperatures from about −10° C. to 150° C. (e.g., −10° C. to 100° C. or 0° C. to 150° C.), and at flow rates of 1 to 1000 standard cubic centimeters per minute (sccm), e.g., from about 1 to 500 sccm.

Furthermore, development can include any useful temperature. For a dry development process, the operating temperature can include those to 150° C. to remove volatile reaction products (e.g., tellurium halide, tellurium acetate, and other metal- or metalloid-containing species) in the unexposed region. In another embodiment, processes can include a post-development bake (PDB) operation to more volatile species (e.g., a PDB at a temperature of up to 250° C.).

Due to the lower volatility of some metal- or metalloid-containing species, a dry development process can result in residual resist components that remain on the substrate. To remove such components, a plasma-based etch operation may be optionally performed after development. Plasma can include any useful chemistry, inert gas, or reactive gas: a fluorocarbon, including CₓF_{y}H_{z}, in which x is from 1-6 and y is from 1-12 and z is from 0-12, CₓF_{y}, in which x is from 1-6 and y is from 2-12, carbon tetrafluoride (CF₄), hexafluoro-2-butyne (C₄F₆), fluoromethane (CH₃F), difluoromethane (CH₂F₂), trifluoromethane (CHF₃), octafluorocyclobutane (C₄F₈), and combinations thereof; hydrogen (H₂); a boron-containing gas, such boron chloride (BCl₃), boron trifluoride (BF₃), borane (BH₃), diborane (B₂H₆), and the like; a hydrogen halide, such as hydrogen chloride (HCl), hydrogen bromide (HBr), and the like; a halogen-containing gas, such as chlorine (Cl₂), nitrogen trifluoride (NF₃), bromine (Br₂), fluorine (F₂), and the like; an oxygen-containing gas, such as oxygen (O₂), ozone (O₃), carbon dioxide (CO₂), carbon monoxide (CO), nitrous oxide (N₂O), nitric oxide (NO), and the like; inert gases, such as argon (Ar), nitrogen (N₂), helium (He), krypton (Kr), and the like; and combinations thereof.

Such plasma can be remote plasma or in situ plasma, which may be inductively coupled plasma (ICP) or a capacitively coupled plasma (CCP). Further plasma conditions include any described herein, including ICP set at a plasma between about 50 W and about 2000 W; an applied bias between about 0 V and 500 V.

In one non-limiting embodiments, the method and processes herein encompass an all dry process, in which deposition, exposure, and development includes only dry processes. In another embodiment, the method and processes include dry deposition, dry exposure, dry development, and dry treatment of the developed pattern. In yet other embodiments, one or more wet processes may be implemented, such as in a method including dry deposition, dry exposure, and wet development; wet deposition, dry exposure, and dry development; wet deposition, dry exposure, and wet development; dry deposition, dry exposure, wet development, and wet treatment of the developed pattern; dry deposition, dry exposure, wet development, and dry treatment of the developed pattern; wet deposition, dry exposure, dry development, and wet treatment of the developed pattern; wet deposition, dry exposure, dry development, and dry treatment of the developed pattern; wet deposition, dry exposure, wet development, and wet treatment of the developed pattern; and wet deposition, dry exposure, wet development, and dry treatment of the developed pattern.

In another non-limiting embodiment, the present disclosure encompasses wet development methods for highly absorbing metal-containing PR films (e.g., bimetallic PR containing Sn and Te). In particular, wet development includes delivering an acid in a solvent to the film. Non-limiting acids and solvents include any herein. In one embodiment, the acid is an inorganic acid, a halogen-containing acid, a hydrogen halide, an organic acid, a phosphorus oxoacid, a sulfur oxoacid, a carboxylic acid, or a silyl halide. In another embodiments, the solvent is an aqueous solvent, an organic solvent, as well as combinations or mixtures thereof.

Using an acid solution in different solvents or solvent mixtures, this highly absorbing PR film can be developed, thereby generating negative tone patterns. Both acid concentration and the type of solvent/solvent mixture can impact selectivity, etch rate, and consequently exposure sensitivity of the resist.

Without wishing to be limited by mechanism, the wet development strategy for this type of highly absorbing resist relies on the solubility switch upon exposure and post-exposure bake (PEB). For example, by incorporating elements like Te into the film, we have demonstrated increasing EUV absorption, as compared to a film lacking Te. However, both unexposed and exposed Sn—Te films may not be soluble in most common organic solvents. Described herein are acid solutions in different solvents or solvent mixtures can selectively remove unexposed SnTe resist materials, thereby generating negative tone patterns. Such acid solutions can be used in any film described herein that contains two or more highly absorbing elements. In some non-limiting embodiments, wet development includes a PEB operation.

Non-limiting acids include any described herein. In one embodiment, the acid is an inorganic acid, such as a hydrogen halide, a phosphorus oxoacid, or a sulfur oxoacid, which exhibited selectivity and higher etch rate at concentrations from about 0.01% (v/v) or greater. Weaker acids, such as organic acids, can be employed at higher concentrations (e.g., up to about 10% (v/v) or 15% (v/v) of the acid in a solvent).

Various solvents may be combined within one or more acids. Both aqueous and various organic solvents (e.g., isopropyl alcohol (IPA), 2-heptanone, propylene glycol methyl ether (PGME), propylene glycol methyl ether acetate (PGMEA), n-butyl acetate, etc.) with the above-mentioned acids can work as wet developers. The choice of solvent/solvent mixtures can impact selectivity and etch rate. Yet other non-limiting solvents include an alcohol (e.g., isopropyl alcohol (IPA)), a ketone (e.g., 2-heptanone, cyclohexanone, or acetone), an ester (e.g., n-butyl acetate, γ-butyrolactone, or ethyl 3-ethoxypropionate (EEP)), or an ether, such as a glycol ether (e.g., propylene glycol methyl ether (PGME) or propylene glycol methyl ether acetate (PGMEA)), as well as combinations thereof.

### Patterning Structures

The methods and processes herein can be employed to develop or treat a resist film described herein. In one embodiment, the resist film is provided within a patterning structure, which in turn can include a resist film (or an imaging layer) disposed on a surface of a substrate. In other embodiments, the patterning structure includes a resist film, a substrate, and a radiation-absorbing layer disposed between the resist film and the substrate. In particular embodiments, the presence of the radiation-absorbing layer provides increased radiation absorptivity and/or patterning performance of the resist film. In other embodiments, the resist film includes atoms that increase radiation absorptivity and/or patterning performance.

Generally, photon absorption through a layer is depth dependent. When a homogenous layer or film is exposed to radiation, the lower portion of the layer is exposed to a lower dose of radiation, as compared to the upper portion of that same layer, because fewer photons reach that lower portion. Thus, to ensure sufficient and uniform exposure through the entire depth of a layer, the layer must provide sufficient transmission of the radiation. As seen in FIG. 1A, a homogenous resist film 102 is disposed on a top surface of a substrate 101. Upon exposure to radiation, photoabsorption 105 through the homogenous layer is depth dependent and has a lower value 105a towards the substrate (and in the lower portion of the layer 102) and a higher value 105b away from the substrate (and in the upper portion of the layer 102). In one non-limiting instance, the resist film 102 of FIG. 1A is a homogeneous organotin oxide photoresist having relatively low EUV absorption of 30%, with 70% transmission.

To increase adsorption, one strategy can include employing a material higher radiation absorption. However, such a strategy can provide a less effective resist. For instance, the patterning structure of FIG. 1B can be a homogeneous film 112 having a relatively high EUV absorption of 90% with 10% transmission. As EUV absorption and resulting chemistry would be weighted toward the top of the photoresist, this photoresist would generally be less effective for patterning applications.

Another strategy that can further improve the EUV sensitivity in a resist film is to create a film in which the film composition is vertically graded, resulting in depth-dependent EUV sensitivity. In a homogenous PR with a high absorption coefficient, the decreasing light intensity throughout the film depth necessitates a higher EUV dose to ensure the bottom is sufficiently exposed. By increasing the density of atoms with high EUV absorptivity at the bottom of the film relative to the top of the film (e.g., by creating a gradient with increasing EUV absorption), it becomes possible to more efficiently use available EUV photons while more uniformly distributing absorption (and the effects of secondary electrons) towards the bottom of more highly absorbing films.

The graded film can include any useful atom or concentration gradient. In one instance, the graded film is characterized by at least a first concentration of a first metal (M1) and a second concentration of a second metal (M2), in which M1 and M2 are different. In another instance, the graded film is characterized by a concentration gradient of one or more atoms having a high EUV-absorption cross-section. In yet another instance, the graded film is characterized by a concentration of a first metal (M1) that changes vertically throughout the film layer. Non-limiting atoms having high EUV-absorption cross-sections include iodine (I), tellurium (Te), indium (In), tin (Sn), antimony (Sb), bismuth (Bi), or combinations thereof. In yet another instance, the graded film is characterized by a concentration gradient of carbon content (e.g., alkyl content).

FIG. 1C provides an exemplary patterning structure having a graded film. In particular, the structure can include a substrate 121 (e.g., a semiconductor substrate) having a top surface and a film 122 disposed on the top surface of the substrate 121, in which the film 122 possesses a vertical gradient characterized by a change in EUV absorbance and/or metal content and/or metal type. Upon exposure to radiation, photoabsorption 125 through the gradient layer is depth dependent and has a lower value 125a towards the substrate (and in the lower portion of the layer 122) and a higher value 125b away from the substrate (and in the upper portion of the layer 122). Overall, the gradient provides a more uniform absorption 125 between the top and lower portions of the resist layer 122.

In one instance, the gradient film 122 can include a first concentration of a first metal (M1) in a top portion of the film and a second concentration of a second metal (M2) in a bottom portion of the film, in which M1 and M2 are different. In one instance, the first concentration is greater than the second concentration. In another instance, the first concentration is less than the second concentration. Non-limiting gradients include a linear gradient, an exponential gradient, a sigmoidal gradient, and the like. In particular embodiments, gradient density films of EUV-responsive organic moieties can yield more homogeneous film properties of EUV exposed regions at all depths in the film, which might improve development processes, improve EUV sensitivity, and/or improve patterning quality (e.g., having improved linewidth roughness (LWR) and/or line edge roughness (LER)).

In a number of cases, the resist material deposited on the substrate includes the composition gradient along a thickness of the resist film. In some such cases, the photoresist material includes M2 in addition to M1, where M2 is a metal having a high EUV-absorption cross-section and is different from M1, where the composition gradient in the photoresist material provides different ratios of M1:M2 at different vertical positions within the photoresist material. In some embodiments, the composition gradient in the resist material may provide different ratios of M1:R (a ligand) at different vertical positions within the resist material. In some such cases, a percentage of metal atoms bonded to R may vary at different vertical positions within the photoresist material.

In some embodiments, the composition gradient in the photoresist material may provide different concentrations of iodine (I), tellurium (Te), or another atom having a high radiation-absorption cross-section at different vertical positions within the photoresist material. In various embodiments, the composition gradient may provide a higher density of high-EUV absorbing elements in a bottom part of the photoresist material compared to a top part of the photoresist material, the bottom part being deposited before the top part. I and Te may be introduced in any useful manner. In one instance, iodine may be introduced as hydrogen iodide (HI) or a suitable alkyl iodide during deposition of a precursor, in which the flow rate of the iodine source can be varied throughout deposition or be introduced at certain times during deposition. In another instance, iodine may be introduced as an iodine vapor (I₂) in the optional presence of plasma. In yet another instance, tellurium may be introduced as a precursor or a counter-reactant during deposition, in which the flow rate of the tellurium source can be varied throughout deposition or be introduced at certain times during deposition.

A similar strategy (also employing tris(t-butoxy)isopropyltin and water as the base chemistry) can be employed for the gradient introduction of iodine using low concentrations of HI (or suitable alkyl iodide) together with water to achieve gradient doping with iodine near the interface. Other Sn-containing precursors and I-containing reactants can be employed in this manner.

Yet another strategy involves the introduction of an alternative (or additional) counter-reactant to water for the introduction of an element with a far higher EUV absorption coefficient than oxygen. One example is the incorporation of tellurium, in which a Te-containing reactant offers a viable option as a gas phase counter-reactant. As the deposition progresses, the ratio of Te-containing counter-reactant:Sn-containing precursor can decrease, thereby forming film that has relatively less Te and relatively more Sn, as compared to the initial portion of the film. In various embodiments, the film may transition to a Te-free composition near the top surface of the film, for example to help minimize contamination and handling issues.

The strategy of engineering a vertical composition gradient in a resist film is particularly applicable to dry deposition methods such as CVD and ALD and can be realized by tuning the flow ratios between different reactants (or precursor) during deposition. The type of composition gradients that can be engineered include: the ratios between different high-absorbing metals, the percentage of metal atoms that have EUV-cleavable bulky groups (or relatedly, the ratios between the metal atoms and the EUV-cleavable bulky groups), the percentages of bulky groups or counter-reactants that contain high-absorbing elements (such as Te, and I) (or relatedly, the ratios between the metal atoms and the additional high-absorbing elements such as Te and I), and combinations herein.

In one embodiment, the resist film 122 of FIG. 1C is a graded tin-based EUV photoresist that has a composition gradient providing an overall 60% EUV absorption with 40% transmission. The increasing EUV absorption gradient provided by the composition gradient in FIG. 1C results in more uniform absorption throughout the thickness of the resist film 122. The gradient can be formed based on alkyl content, in which the inclusion of regions with higher SnO₂-like properties can increase EUV absorption in the film. The given examples are all increasing in Sn-alkyl content toward the surface of the film, but concepts where there are laminate layers of alternating Sn-alkyl heavy, Sn-alkyl light regions are also envisioned.

One example to produce graded Sn-based resists with varying alkyl groups involves the use of tetrakis(dimethylamino)tin and isopropyltris(dimethylamino)tin precursors and water as a counter-reactant. The tetrakis(dimethylamino)tin can be initially introduced as a minor to significant component to produce a relatively dense component of Sn that is not bonded to an alkyl group (essentially SnO₂ and Sn—OH derivatives). The ratio of tetrakis(dimethylamino)tin: isopropyltris(dimethylamino)tin precursors can decrease as the film grows. This can produce a film with an increasing amount of Sn—R bonds in the film toward the upper surface of the film. (An example of the increase in the absorption of a film produced by this process is described below). This process may be performed either by ALD or CVD methods.

A related approach involving an absorption gradient targets the use of somewhat tin-based resist films using two precursors—both with alkyl groups—but one containing one or more alkyl ligands than the other. For example, isopropyltris(dimethylamino)tin and diisopropyldi(dimethylamino)tin can be used. Initially, a flow of the diisopropyldi(dimethylamino)tin is introduced during the film deposition and the ratio is increased relative to the flow of isopropyltris(dimethylamino)tin as the film is deposited. This results in a film with a higher amount of Sn bonded to two alkyl groups on the surface relative to the bottom of the film.

Another method to create graded films involves the use of a plasma to remove some of the alkyl groups bonded to metal centers during the initial deposition of the film. For example, the Sn-alkyl bond is cleaved easily in the presence of plasma either by vacuum ultraviolet (VUV) or the bombardment of electrons or ions from the plasma. Ideally, a plasma with conditions that simply removes the alkyl groups, but does not etch the film, is used. For example, an O₂, Ar, He, or CO₂ plasma may be used. As the film is deposited, the efficiency of the plasma for removing alkyl groups is reduced (i.e., the power of the plasma is reduced), and eventually is turned off. This can result in a graded film with a higher number of M-alkyl bonds at the surface of the film than the bottom of the film.

The composition gradient in the EUV resist film can provide various benefits. For instance, high density of high-EUV-absorbing elements in the bottom part of the film can effectively generate more secondary electrons that can better expose upper portions of the film. In addition, such compositional gradients can also be directly correlated with a higher fraction of EUV absorbing species which are not bonded to bulky, terminal substituents. For example, in the case of Sn-based resists, the incorporation of tin precursors with four leaving groups is possible, thereby promoting the formation of Sn—O-Substrate bonding at the interface for improved adhesion.

By using a radiation-absorbing layer below the resist film, radiation absorption can be increased through the resist film. For instance, by providing an absorbing layer having an increased density of atoms with high EUV absorptivity at the bottom of the film, relative to the resist film, it becomes possible to more efficiently use available EUV photons while more uniformly distributing absorption (and the effects of secondary electrons) towards the bottom of the patterning structure. Furthermore, in some instances, the absorbing layer can effectively generate more secondary electrons that can better expose lower portions of the patterning structure.

As seen in FIG. 1D, a patterning structure can include a resist film 132, as well as a radiation-absorbing layer 133 under the resist film 132 and above a substrate 131. As compared to a structure lacking the absorbing layer, photoabsorption between the lower portion 135a and upper portion 135b of the layer 132 can be more uniform. Upon exposure to radiation, photoabsorption 135 through the layers is influenced by the absorbing layer 133, which can result in the generation of additional secondary electrons 134 that can assist in radiation exposure of the bottom of the resist film. In this way, photoabsorption 135 can be improved, as compared to photoabsorption in a resist film lacking the absorbing layer.

The absorbing layer can include an element (e.g., a metal atom or a non-metal atom) having a high photoabsorption cross-section (or a high-absorbing element), such as I, Te, In, Sn, Sb, and/or Bi. The absorbing layer can also include EUV-labile groups, which may also vary and may include alkyl groups CₙH₂ₙ₊₁, preferably wherein n≥3, and include fluorine substituted alkyl groups. Such elements and labile groups can be provided as a layer in any useful manner, such as by sputter deposition, physical vapor deposition (PVD) including PVD co-sputtering, chemical vapor deposition (CVD), plasma enhanced CVD (PE-CVD), low pressure CVD (LP-CVD), atomic layer deposition (ALD, including thermal ALD and plasma-enhanced ALD (PE-ALD)), spin-coat deposition, plasma-based deposition, thermal-induced decomposition, plasma-induced decomposition, electron-beam (e-beam) deposition including e-beam co-evaporation, etc., or a combination thereof, with one or more precursors (e.g., any described herein). The absorbing layer can be a photoresist layer or a surface modification layer disposed on a surface of the substrate.

One or both of the absorbing layer and the resist film can include a high-absorbing element. In one instance, the absorbing layer and the resist film both include a high-absorbing element. The element in each of the absorbing layer and the resist film can be the same or different.

In particular non-limiting instances, the absorbing layer is characterized by having an increased radiation absorptivity, as compared to the resist film. For instance, the absorbing layer can include a higher fraction of EUV-absorbing species that are not bonded to bulky, terminal substituents. In another instance, the absorbing layer can include an element having a higher absorption coefficient than the element that is present in the resist film. For example, the resist film can include Sn, and the absorbing layer can include Te (e.g., Te alone or a mixture of Te and Sn). In yet another instance, the concentration of a high-absorbing element is higher in the absorbing layer than in the resist film.

The thickness of absorbing layer will vary depending on integration scheme. A resulting absorbing layer can be very thin, ranging from 0.3 nm to 5 nm, since secondary electrons generated deeper than 5 nm are less likely to penetrate up through the film and into the resist layer. However, any EUV absorbing layer that can be etched with high etch selectivity to the photoresist film can also be applied much thicker, and, in some cases, this can prove advantageous if etch chemistries exist to allow underlayer device layers to be selectively removed using the underlayer film as an etch mask.

In one instance, the absorbing layer is a metal oxide or metal with alkyl group termination: A thin metal oxide or metal may be deposited by ALD or CVD. Examples include SnOx, BiOx, and Te. Following deposition, the film may be capped with an alkyl substituted precursor of the form MRₓL_{y} where M is a metal preferably with high EUV absorption, R is an alkyl or fluoroalkyl group, L is a ligand that reacts with the surface of the thin metal oxide or metal, x is an integer equal to or greater than 1 and y is an integer equal to or greater than 1. A counter-reactant may be used to better remove the ligands and multiple cycles may be repeated to ensure complete saturation of the substrate surface. The surface is then ready for the EUV-sensitive resist film to be deposited. One possible method is to produce a thin film of SnOx. Possible chemistries include growth of SnO₂ by cycling tetrakis(dimethylamino)tin and a counter-reactant such as water or O₂ plasma. After the growth, a capping agent could be used. For example, isopropyltris(dimethylamino)tin vapor may be flown over the surface.

The absorbing layer can provide other functionalities, in addition to modulating photon or radiation absorption. In one instance, the absorbing layer can be a photoresponsive adhesion layer, in which exposure to radiation can enhance adhesion to the overlying resist film. Prior to radiation exposure, a top surface of the absorbing layer can include a labile moiety that is cleavable under exposure to the patterning radiation. Upon exposure, the labile moiety can provide a reactive center, which then participates in the formation of a covalent bond between the absorbing layer and the resist film. In this way, the top surface of the absorbing layer can be characterized as a photoresponsive surface, and the absorbing layer itself can be characterized as a photoresponsive adhesion layer.

The advantage of the deposition of an absorption layer may be observed with any element with higher EUV cross-section than the substrate. Most employed carbon-based underlayers have relatively low EUV cross-sections. Hence, a wide variety of elements may be appropriate for surface modification. Some particularly suitable elements are those exhibiting the high EUV absorption cross-section and which can be effectively be removed using dry etch processes, including In, Sn, Sb, Te, I, Pb, and Bi (see FIG. 1E). Alloys and oxides and other compounds of these elements may also be used.

The resist film and/or the absorbing layer by surface modified. One method to achieve a surface modification is through the use of a reactive species containing an EUV-absorbing element. In some iterations, a vapor of the reactive species may be passed over the wafer. The wafer may be heated to provide thermal energy for the reaction to proceed. In some iterations, the heating can be between 50-250° C. In some cases, pulses of the reactant may be used, separated by pump and/or purging steps. In some cases, a counter-reactant may be pulsed between the reactant pulses resulting in ALD or ALD-like growth. In other cases, both the reactant and the counter-reactant may be flowed at the same time. Examples of elements useful for surface modification include I, F, Sn, Bi, Sb, Te, and oxides or alloys of these compounds.

Some examples of surface modification according to this technique include evaporation/sublimation of either pure elements or any sufficiently volatile compound of them. Coatings may also be applied by various sputtering or physical vapor deposition techniques.

The modification process can leave a surface terminated with EUV-labile groups such as alkyl groups (e.g., t-butyl, n-butyl, sec-butyl, i-propyl, etc.) or fluorine substituted alkyl groups, such as —CF₃, —CF₂CF₃, for example. Such a modification can be provided on a surface of the substrate, a surface of the absorbing layer, and/or a surface of the resist film.

Atomic layer deposition (ALD) techniques may also be advantageously used to controllably apply such thin films. In this way, thin, highly EUV absorbing layers of tin, antimony, bismuth, and/or tellurium (e.g., as in tin telluride (SnTe) films, antimony telluride (SbTe) films, or bismuth telluride (BiTe) films) may be deposited using alternating flows of various volatile metal alkoxide based precursors together with a Te-containing precursor (e.g., bis(trimethylsilyl)tellurium or any described herein). A non-limiting advantage of such a process is the ability to fine tune the interface to maximize adhesion to an inorganic metal oxide-based resist overlayer.

Another method that may be applied to achieve surface modification according to this disclosure is through plasma techniques. A plasma may be struck such that the reactive species within the plasma reacts with the surface to deposit highly EUV-absorbing elements. The plasma may be a remote plasma or a direct plasma.

Some examples of these plasma techniques include a plasma-deposited ashable carbon hardmask (AHM) film modified by exposure to a plasma generated in a flow of iodine vapor (I₂) in an inert carrier gas. I₂ plasma can be used to create reactive I₂ or atomic I species that can break surface C—C bonds and insert themselves to create C—I functionality at the surface. Such a plasma strategy can be applicable both to diamond-like carbon film, which contains mostly C—C single bonds, as well as materials containing double bonds between carbon atoms. Alternatively, a thin iodine-rich layer can be grafted onto the surface by exposure to a plasma discharge generated in a flow of di-iodomethane/He or other iodinated hydrocarbon over the wafer surface.

Alternatively, a thermal, chemical reaction, or plasma-induced decomposition of a volatile organometallic precursor can be employed to generate films with a predominately elemental composition. For example, a thin tellurium-rich film may be deposited by the thermal decomposition of bis(t-butyl)tellurium on an AHM carbon film heated to 250° C. Alternatively, an RF plasma can be ignited in a flow of bis(t-butyl)tellurium and H₂ or He causing a tellurium-rich layer to deposit onto the surface of an AHM film. Similarly, such a layer can be deposited by a chemical vapor deposition reaction between bis(trimethylsilyl)tellurium and water vapor. In yet another example, a thin Sn-rich film may be formed by generating a plasma in a mixture containing a tin precursor such as tetrakis(dimethylamino)tin or tetra(isopropyl)tin, resulting in a Sn-containing species bonded to the surface through the loss of one or more of the dimethylamino or isopropyl ligands.

The film or absorbing layer can include a capping layer. In one embodiments, the capping layer can provide a gradient film. One approach involves the deposition of a thin metallic Sn or Sn alloy based film on the surface of the substrate. The vapor of an alkyl organometallic tin precursor can be flown into the chamber. The alkyl tin precursor may have the form of SnR₂ or SnR₄, depending on the Sn oxidation state. The alkyl group can be CₙH₂ₙ₊₁, where n is generally greater than or equal to 2. Examples include tetraisopropyltin, tetra(t-butyl)tin, and others described herein. Precursor vapors can be entrained in a suitable carrier gas (for example H₂, He, Ar, or N₂) and flown into the chamber, and an RF plasma ignited between the wafer and showerhead. The result is the deposition of a film with a basic composition resembling elemental Sn. The power of the plasma may be adjusted throughout the deposition, and possibly ramped down at the end. The plasma power is then stopped, but the alkyl tin precursor is still flown. The result can be a tin layer capped with alkyl groups. A resist such as a metalorganic resist can then be deposited on top of the modified layer and brought into an EUV scanner for exposure. Upon EUV exposure, the alkyl groups of the modified interface can undergo a beta-hydrogen elimination, resulting in the formation of Sn—H bonds at the interface. At this stage, or during the post exposure bake, the Sn—H bonds may react with the resist to form Sn—O—Sn bridges across the interface, effectively increasing the adhesion of the film in the exposed region.

Similar to the process described for alkyl-terminated Sn interface modification, an organotellurium precursor can be employed to deposit a thin predominately Te composition film providing high EUV absorptivity. The organo-Te precursor may have the form of RTeH or R₂Te, where R is an alkyl group or a ligand molecule. The alkyl group may be CₙH₂ₙ₊₁, where n is greater than or equal to 3. Examples include t-butyl tellurium hydride, di(t-butyl) tellurium, di(isopropyl)tellurium, or bis(trimethylsilyl)tellurium. Diluent or carrier gases may include H₂, He, Ar, or N₂, and a plasma can be struck resulting in the deposition of a thin Te-containing film. Igniting an RF plasma results in the deposition of a predominately Te film. The power of the plasma may be adjusted throughout the deposition, may be ramped down at the end and extinguished while still flowing the organotellurium precursor, resulting in a Te underlayer capped with alkyl groups. An EUV resist, such as a spun-on or dry-deposited metalorganic resist as described above, can then be deposited on top of the modified layer and brought into an EUV scanner for exposure. Upon EUV exposure, the Te at the bottom of the film (e.g., deposited on the surface of an AHM carbon underlayer) will strongly absorb EUV photons not captured in the resist material, thereby maximizing the generation of secondary electrons likely to induce alkyl group cleavage and the formation of Te—Sn bonds at the interface. Alkyl groups present at the modified interface can undergo a beta-hydrogen elimination, resulting in the formation of reactive Te—H bonds at the interface. Upon bake, Te—H may optionally react with Sn in the resist film on top and form stable Sn—Te bonds. Optionally, these Te—H bonds may be converted to Te—OH bonds through the introduction of moisture.

In another instance, enhanced EUV absorption can be achieved through the incorporation of F at the interface, while also including OH, O, or COO groups to adjust adhesion. Absorption can be enhanced in the EUV-exposed region by the presence of F from a fluorocarbon-based film (e.g., a CFₓ polymer film) or from fluorocarbon (or NF₃, SF₆, or other F source) plasma treatment of an organic (carbon based) underlayer. In one instance, a fluorocarbon-based film is deposited on top of a high EUV absorbing film. In another instance, gases with fluorine, carbon, and optionally hydrogen may be flown into the chamber to deposit the fluorocarbon-based film. Example gases include, but are not limited to, CH₂F₂, C₄F₆, CHF₃, CH₃F, CF₄ and C₄F₈. In some cases, inert gases such as N₂, Ar, or He, and optionally hydrogen may also be added, and a plasma struck with conditions selected such that a CFX layer is deposited on the wafer. The CFₓ layer chemistry and deposition conditions can be tuned such that it is very inert to the certain vapor phase chemistries.

In yet another instance, to create a thin CFX terminated surface, an RF plasma can be generated in one or more fluorinated hydrocarbon precursor (examples include CH₂F₂, C₄F₆, CHF₃, CH₃F, CF₄, or C₄F₈), optionally in combination with gases such as O₂, H₂, and/or CO₂ to promote the formation of polar moieties to facilitate adhesion of EUV-exposed metal oxide based resist materials to the substrate surface. A plasma is struck and conditions are selected such that a CFX layer is deposited on the wafer under conditions also shown to be effective at forming surface functionality expected to enhance adhesion with exposed metalorganic films. The resist—for example a dry-deposited metalorganic film—is then applied over the modified substrate surface and subjected to EUV-patterning.

Upon EUV exposure, free F ions can be generated, and exhibit the tendency to form insoluble fluoride complexes more resistant to dissolution in photoresist developers. In other embodiments, reactive sites may be created on the surface through abstraction of F or CFX groups as a result of EUV generated secondary electrons. The wafer may then be brought into an ALD chamber where surface imaging can be performed. The ALD precursors may not exhibit reactivity with the unmodified fluorocarbon modified interface, but may nucleate on the exposed regions. An etch hardmask may be thus be formed through this method, and transferred into the underlying layers, for example as described in our prior application No. 62/767,198, incorporated herein by reference for its disclosure of surface imaging techniques.

### Methods Employing an Acid

Any patterning structure or film herein can be processed in any method employing an acid to develop or treat the resist film.

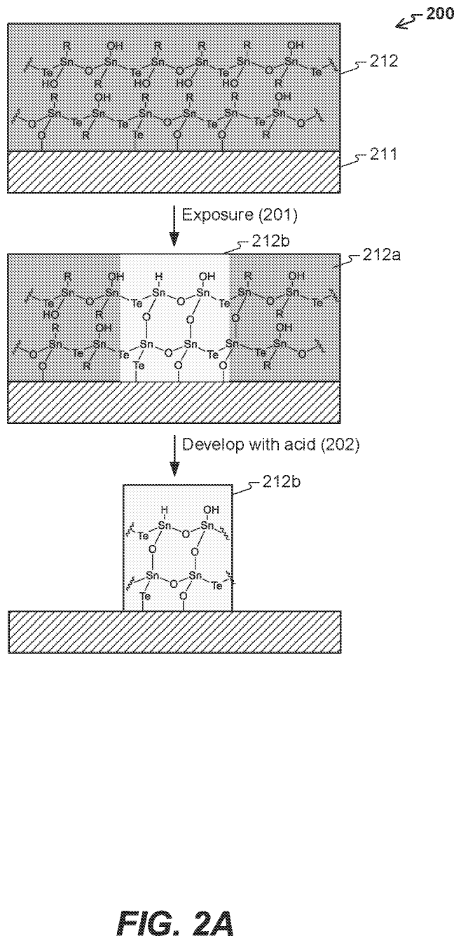

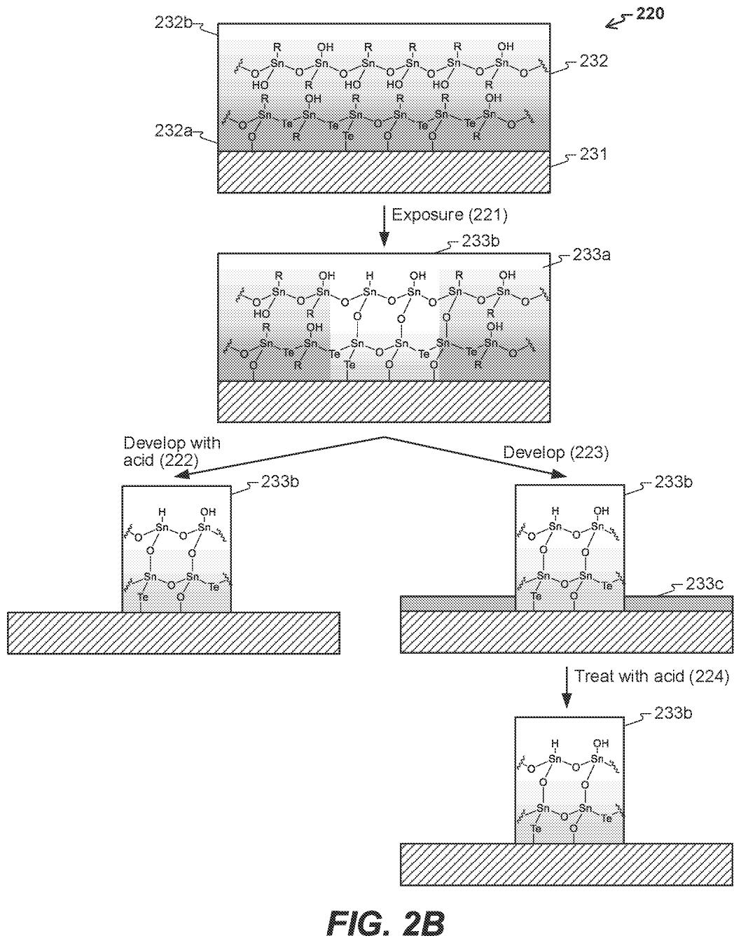

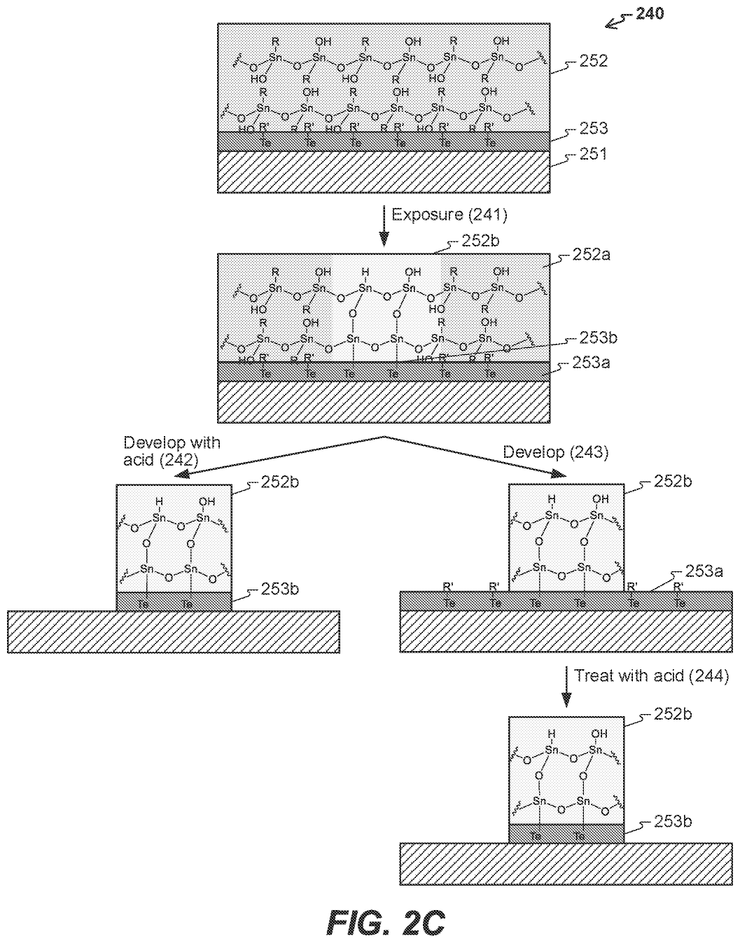

FIG. 2A-2C provides methods in which the patterning structure can include a homogenous resist film, a graded resist film, or a resist film having an absorbing layer. In particular, FIG. 2A provides a non-limiting method 200 of using a patterning structure having a resist film 212. The non-limiting patterning structure can include a resist film 212 disposed on a top surface of a substrate 211. As can be seen, the resist film can include two different elements having a high patterning radiation-absorption cross-section. In one embodiment, the element includes tin (Sn) and tellurium (Te). The resist film can include one or more other atoms provided by a counter-reactant, in which such an atom can include oxygen (O). The resist film can further include one or more ligands (R), which can be introduced by way of a precursor and can be characterized as a labile, EUV-cleavable ligand. The patterning structure including such layers can be formed in any useful manner, as described herein. In one embodiment, the resist film is a radiation-sensitive resist film, an EUV-sensitive film, or a photoresist layer.

In operation 201, the patterning structure is exposed to a patterned radiation exposure to provide an exposed film having radiation-unexposed region(s) 212a and radiation-exposed region(s) 212b. Patterning can include the use of a mask having radiation transparent region(s) and radiation opaque region(s), as described herein.

In some embodiments, the EUV resist film includes a metal atoms (M) and an EUV-labile ligand (R, e.g., alkyl groups) present on the surface in EUV-exposed region(s) can undergo beta-hydrogen elimination, such that the alkyl groups are removed, leaving M-H groups on the interface. These groups may be converted to M-OH groups upon exposure to oxygen and moisture. During the exposure or subsequent post exposure bake steps, some of these groups may react with hydroxyl groups either already present in the film or generated by EUV-induced reactions in the resist film, creating strong bonds between the exposed resist film and the substrate. A post exposure bake (PEB) may further enhance the adhesion and increase the number of cross-linking points. This adhesion difference can assist in selectively removing unexposed regions as desired in a negative tone resist. Spin-coated organic or metal-organic resists may also benefit by similar mechanisms.

In operation 202, the exposed film is developed in the presence of an acid. Non-limiting acids include any described herein. As can be seen, developing can result in selectively removing the radiation-unexposed region(s) 212a and maintaining the radiation-exposed region(s) 212b of the resist film 212. Optionally, the exposed film can be baked before or after development, which can further increase contrast in etch selectivity of the exposed film and/or enhance hardness of the developed film. In other embodiments, the developed film is further exposed to a plasma-based etch process. In particular embodiments, the radiation-unexposed region(s) are removed, thereby providing a negative tone resist. In other embodiments, the radiation-exposed region(s) are removed, thereby providing a positive tone resist.

FIG. 2B provides a non-limiting method 220 of using a patterning structure having a graded resist film 232. The non-limiting patterning structure can include a resist film 232 disposed on a top surface of a substrate 231. As can be seen, the resist film can include two different elements having a high patterning radiation-absorption cross-section, in which such elements are provided within a vertical gradient having a first concentration 232a of a first metal (here, a higher concentration of Te) in proximity to the substrate 231 and having a second concentration 232b of the first metal (here, a lower concentration of Te) in proximity to the top surface of the film. As can be further seen, the resist film can include one or more other atoms provided by a counter-reactant, in which such an atom can include oxygen (O); and can include one or more ligands (R), which can be introduced by way of a precursor and can be characterized as a labile, EUV-cleavable ligand. The patterning structure including such layers can be formed in any useful manner, as described herein. In one embodiment, the resist film is a radiation-sensitive resist film, an EUV-sensitive film, or a photoresist layer.

In operation 221, the patterning structure is exposed to a patterned radiation exposure to provide an exposed film having radiation-unexposed region(s) 233a and radiation-exposed region(s) 233b. Patterning can include the use of a mask having radiation transparent region(s) and radiation opaque region(s), as described herein.

The presence of two different elements within the film can, in some instances, affect how the film is developed. For instance, if one of the two elements is more resistant to etching or developing, then additional development or treatment processes may be needed to remove the resist material. Yet, in some instance, even the same element in lower amounts may be removed in a single development process. In other instances, the development conditions can be optimized to remove both types of elements within the film. In non-limiting embodiments, development in the presence of acid and an oxygen-containing reagent (e.g., 02) can remove various types of elements within the film.

As seen in FIG. 2B, the exposed film may be developed in any useful manner to remove the desired regions. In operation 222, the exposed film is developed in the presence of an acid. Non-limiting acids include any described herein. As can be seen, developing can result in selectively removing the radiation-unexposed region(s) 233a and maintaining the radiation-exposed region(s) 233b of the resist film 232. Optionally, the exposed film can be baked before or after development, which can further increase contrast in etch selectivity of the exposed film and/or enhance hardness of the developed film. In particular embodiments, the radiation-unexposed region(s) are removed, thereby providing a negative tone resist. In other embodiments, the radiation-exposed region(s) are removed, thereby providing a positive tone resist.

Alternatively, in operation 223, the exposed film is developed in any useful manner, either in the presence of acid or other reagents and reactants described herein. As can be seen, developing can result in selectively removing the radiation-unexposed region(s) 233a, selectively maintaining the radiation-exposed region(s) 233b of the resist film 232, and resulting in residual species 233c present in any form (e.g., a continuous or non-continuous layer). In particular embodiments, the residual species 233c includes the element that is present within a higher concentration in the initial resist layer 232. Here, the residual species 233c includes an increased concentration of Te. In operation 223, the development conditions can include those that effectively etch away Sn but is less effective in removing Te. In this situation, the process can further include operation 224 configured to more effectively remove Te. As can be seen, in operation 224, the developed film is treated with an acid to remove the residual species 233c, thereby providing a pattern having radiation-exposed region(s) 233b. After operation 224, the resultant film can be considered a treated film.

Optionally, the exposed film can be baked before development, which can further increase contrast in etch selectivity of the exposed film. In some embodiments, the developed film or treated film can be baked, which can further enhance hardness. In other embodiments, the developed film or the treated film is further exposed to a plasma-based etch process.

The present disclosure also encompasses any method that employs a patterning structure having an absorbing layer, in which such methods those of making and/or using such structures. In one embodiment, a method of making a patterning structure includes: providing a substrate to receive a pattern; incorporating an absorbing layer on a top surface of the substrate; and providing a resist film, wherein the absorbing layer underlies the resist film to increase radiation absorptivity and/or patterning performance of the resist film.

The absorbing layer can include a high-absorbing element, which can be deposited by using one or more precursors (e.g., any described herein). The absorbing layer can include predominantly high-absorbing elements. In one embodiment, the absorbing layer includes I, In, Sn, Bi, Sb, Te, or a combination thereof. In another embodiment, a single precursor is employed. In yet another embodiment, two or more precursors are employed. Optionally, the precursor(s) is employed with one or more counter-reactants, as described herein. Deposition can include, e.g., ALD or CVD.

FIG. 2C provides a non-limiting method 240 of using a patterning structure having a radiation-absorbing layer, which can optionally serve as a photoresponsive adhesion layer. The non-limiting patterning structure can include a substrate 251, a resist film 252, and an absorbing layer 253 under the resist film 252. The patterning structure including such layers can be formed in any useful manner, as described herein. In one embodiment, the resist film is a radiation-sensitive resist film, an EUV-sensitive film, or a photoresist layer. In particular embodiments, the absorbing layer includes any useful atom having a high radiation-absorption cross-section (e.g., I, Te, In, Sn, Sb, and/or Bi).

The radiation-absorbing layer can be included to enhance absorptivity of the film, particularly near the lower portion of the resist film. Optionally, the radiation-absorbing layer can be photoresponsive. In this instance, radiation can also be used to pattern a photoresponsive surface of the absorbing layer 253, in which the photoresponsive surface has EUV-labile ligands. As can be seen, the photoresponsive surface includes radiation-unexposed region(s) 253a and radiation-exposed region(s) 253b. In radiation-exposed region(s) 253b, enhanced adhesion is provided between the resist film 252 and the absorbing layer 253. In particular embodiments, enhanced adhesion can lower the required radiation dose to provide desired patterned features within the resist film and/or the absorbing layer.

In operation 241, the patterning structure is exposed to a patterned radiation exposure to provide an exposed film having radiation-unexposed region(s) 252a and radiation-exposed region(s) 252b. Patterning can include the use of a mask having radiation transparent region(s) and radiation opaque region(s), as described herein.

The surface of the absorbing layer can include a labile moiety, such as halo, alkyl (e.g., a branched alkyl), haloalkyl, or any described herein as R for formula (I) or (II) herein. As seen in FIG. 2C, the non-limiting absorbing layer includes Te having a labile moiety R′, and the non-limiting resist film includes a tin oxide film having a labile moiety R. A non-limiting thickness of the absorbing layer is about 3 to 5 nm. In certain instances, the surface of the absorbing layer is treated with an organometallic precursor having a high-absorbing element (e.g., Te) and a labile moiety (e.g., t-butyl). Non-limiting precursors including Te and t-butyl (t-Bu) can be (t-Bu)TeH or (t-Bu)₂Te.

The labile moiety R′ can provide a passivated surface, which can be activated upon exposure to radiation (thereby being photoresponsive). In operation 241, the patterning structure is exposed to a patterned radiation exposure to provide an exposed film having radiation-unexposed region(s) 252a and radiation-exposed region(s) 252b in the resist film 252, as well as radiation-unexposed region(s) 253a and radiation-exposed region(s) 253b in the absorbing layer 253. Due to radiation exposure, the labile moieties R and R′ are removed or cleaved, thus providing metal reactive centers, i.e., Sn in the resist film 252 and Te in the absorbing layer 253, that can react to form a metal-metal (M-M) bond (here, a Sn—Te bond). In the resist film, radiation-induced cleavage of the Sn—R bond in the organotin oxide layer also induces consolidation to provide a more condensed metal oxide (tin oxide) network in the radiation-exposed region(s).

As seen in operation FIG. 2C, in operation 242, the exposed film is developed in the presence of an acid. Non-limiting acids include any described herein. As can be seen, developing can result in selectively removing the radiation-unexposed region(s) 252a and maintaining the radiation-exposed region(s) 252b of the resist film 252. Such developing can, in some instances, result in selectively removing portions of the absorbing layer 253. For instance, developing can selectively remove the radiation-unexposed region(s) 253a and maintaining the radiation-exposed region(s) 253b of the absorbing layer 253. Such developing can include dry etching, e.g., using any halide chemistry described herein or plasma etching (e.g., with CH₄— or F-based plasma, including NF₃, CF₄, etc.).

Optionally, the exposed film can be baked before or after development, which can further increase contrast in etch selectivity of the exposed film and/or enhance hardness of the developed film. In particular embodiments, the radiation-unexposed region(s) are removed, thereby providing a negative tone resist. In other embodiments, the radiation-exposed region(s) are removed, thereby providing a positive tone resist.

Alternatively, in operation 243, the exposed film is developed in any useful manner, either in the presence of acid or other reagents and reactants described herein. As can be seen, developing can result in selectively removing the radiation-unexposed region(s) 252a, selectively maintaining the radiation-exposed region(s) 252b of the resist film 252, and remaining portions of the absorbing layer 253a being present. In particular embodiments, the remaining portion of the absorbing layer 253a includes radiation-unexposed region(s) and includes a high concentration of a highly absorbing element (e.g., Te).

In operation 243, the development conditions can include those that effectively etch away a particular element (e.g., those present in the resist film, such as Sn) but is less effective in removing another particular element (e.g., those present in the absorbing layer, such as Te). In this situation, the process can further include operation 244 configured to more effectively remove Te. As can be seen, in operation 244, the developed film is treated with an acid to remove elements within the unexposed region(s) 253a of the absorbing layer, thereby providing a pattern having radiation-exposed region(s) 252b/253b. After operation 244, the resultant film can be considered a treated film.

Optionally, the exposed film can be baked before development, which can further increase contrast in etch selectivity of the exposed film. In some embodiments, the developed film or treated film can be baked, which can further enhance hardness. In other embodiments, the developed film or the treated film is further exposed to a plasma-based etch process.

The methods herein can include any further step before exposure, after development, and/or after treatment. In one instance, the method can include providing a resist film. Such providing can include applying the resist film on a surface of a substrate; and optionally providing an absorbing layer between the resist film and the substrate. Applying the resist film or providing the absorbing layer can include delivering one or more precursors, counter-reactants, or other reactants to the substrate.

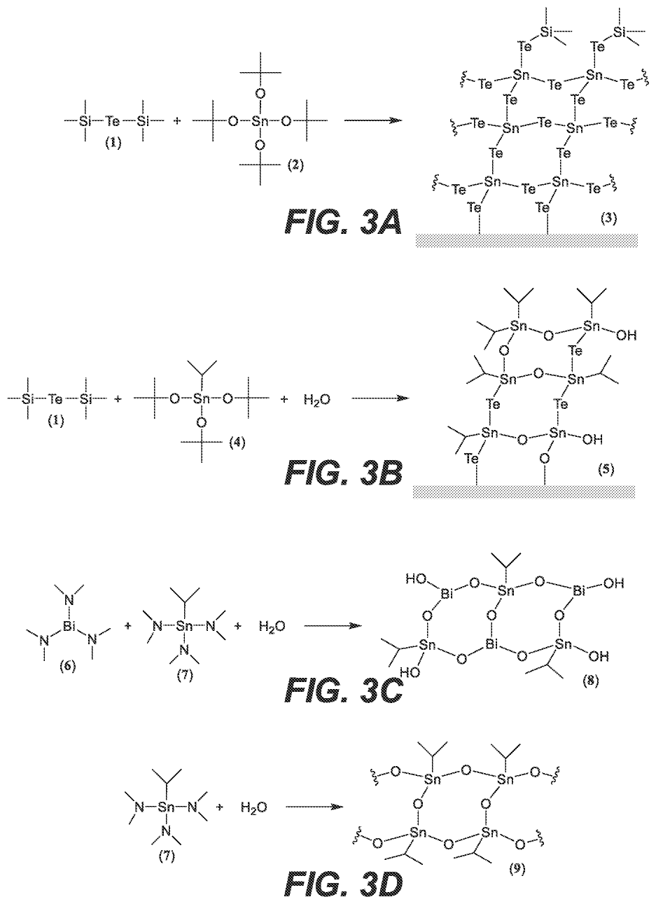

In one instance, the resist film or the absorbing layer can include delivering a first precursor (having a first element that is highly absorbing), a second precursor (having a second element that is highly absorbing), and an optional counter-reactant. One non-limiting strategy includes introduction of a first precursor including Te and a second precursor including Sn. As shown in FIG. 3A, the first precursor includes bis(trimethylsilyl)telluride (1), and the second precursor includes tetra(t-butoxy)tin (2), in which deposition provides a network of a SnTe material (3) having a trimethylsilyl surface, which can be further reacted (e.g., with a counter-reactant or an alcohol) to remove silyl groups. A layer including such a network can be employed as part of the resist layer and/or the absorbing layer.

Another non-limiting strategy involves the introduction of an alternative (or additional) counter-reactants to water for the introduction of an element with a far higher EUV absorption coefficient than oxygen. One example is the incorporation of Te, as shown in FIG. 3B. Bis(trimethyl)telluride (1) offers a viable option as a gas phase co-reactant. In some embodiments, this can be combined with an alkyltin precursor such as tris(t-butoxy)isopropyltin (4) and water. In this way, EUV-reactive films can be produced with little reduction of reactive Sn-alkyl moieties (e.g., Sn-iPr moieties) near the bottom of the films. As shown in FIG. 3B, during an initial portion of the deposition, the co-reactant includes both water and bis(trimethyl)telluride (1). The initial film that forms on the underlying substrate has substantial amounts of both Sn and Te. As the deposition progresses, the ratio of bis(trimethyl)tellurium: tris(t-butoxy)isopropyltin can decrease, thereby forming film that has relatively less Te and relatively more Sn, as compared to the initial portion of the film. In various embodiments, the film may transition to a Te-free composition near the top surface of the film, for example to help minimize contamination and handling issues.

Another example may be to add different metals to the system for enhanced absorption. For example, a gradient film with bismuth and tin metal centers (8) may be synthesized using tris(dimethylamino)bismuth (6) and isopropyltris(dimethylamino)tin (7), as shown in FIG. 3C. The ratio of tris(dimethylamino)bismuth:isopropyltris(dimethylamino)tin in the precursor flow can be decreased as the film is deposited. This can result in the bottom of the film containing more bismuth metal centers than the top of the film. Closer to the top of the film, the gradient film can include more tin centers (9), which may be synthesized using tris(dimethylamino) isopropyltin (7) with water, as shown in FIG. 3D. Like Sn, Bi atoms exhibit extremely high EUV cross-section, but unlike Sn, even without a bulky, EUV labile substituent, appears less prone towards condensation to an intractable, binary metal oxide. Such a film may be processed using wet (aqueous and non-aqueous) and/or dry (e.g., HCl or HBr-based, such as described in International Appl No. PCT/US2020/039615, filed Jun. 25, 2020, published as International Pub. No. WO 2020/264158, which is titled PHOTORESIST DEVELOPMENT WITH HALIDE CHEMISTRIES, which is incorporated by reference herein for the purpose of describing applicable dry development techniques) development strategies.

Various steps, operations, and apparatuses for such patterning and developing steps include those useful for lithography processes, as well as any described herein. In one instance, the lithography process includes use of extreme ultraviolet (EUV) lithography.

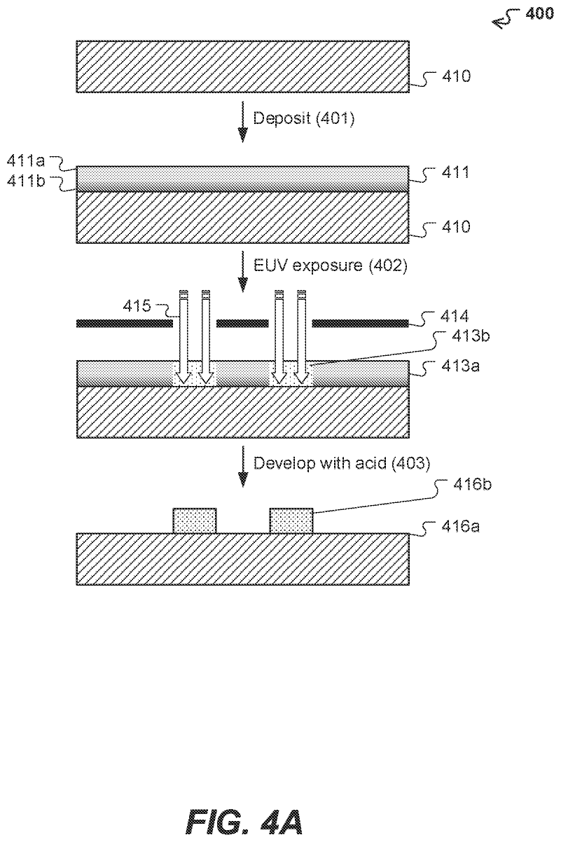

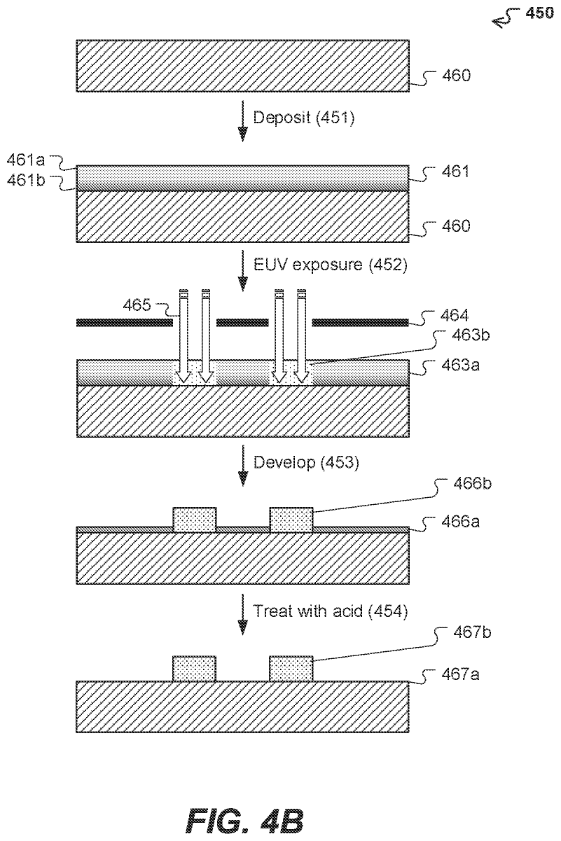

For instance, FIG. 4A provides an exemplary method 400 to provide a negative tone resist, in which EUV unexposed regions can be removed. As can be seen, the method 400 includes depositing 401 a film 411 on the top surface of the substrate 410. As described herein, the film includes an EUV-sensitive material. In particular embodiments, the resist film 411 includes a gradient composition having a first concentration 411a near a top portion of the film and a second concentration 411b near a lower portion of the film, in which the first and second concentrations 411a/411b are different (e.g., either different in terms of concentration value, different atoms or elements, different ligands, and the like).

The method 400 can further include patterning the film by an EUV exposure 402. EUV exposure can include, e.g., an exposure having a wavelength in the range of about 10 nm to about 20 nm in a vacuum ambient (e.g., about 13.5 nm in a vacuum ambient). Patterning can include use of a mask 414 having EUV transparent regions and EUV opaque regions, in which EUV beams 415 are transmitted through the EUV transparent region, into the film 411. In this manner, the film includes EUV unexposed regions 413a and EUV exposed regions 413b.

An additional step includes developing 403 the film with acid, thereby selectively removing the EUV unexposed regions 413a and maintaining the EUV exposed regions 413b, which in turn provides a pattern or a patterned film having removed regions 416a and maintained regions 416b. The developing operation can include any described herein that includes any acid described herein.

The method can include further steps to remove residual resist components. Accordingly, FIG. 4B provides an exemplary method 450 to provide a negative tone resist, in which EUV unexposed regions can be removed. As can be seen, the method 450 includes depositing 451 a film 461 on the top surface of the substrate 460. As described herein, the film includes an EUV-sensitive material. In particular embodiments, the resist film 461 includes a gradient composition having a first concentration 461a near a top portion of the film and a second concentration 461b near a lower portion of the film, in which the first and second concentrations 461a/461b are different (e.g., either different in terms of concentration value, different atoms or elements, different ligands, and the like).

The method 450 can further include patterning the film by an EUV exposure 452. Patterning can include use of a mask 464 having EUV transparent regions and EUV opaque regions, in which EUV beams 465 are transmitted through the EUV transparent region and then into the film 461. In this manner, the film includes EUV unexposed regions 463a and EUV exposed regions 463b.

An additional step includes developing 453 the film, thereby selectively removing the EUV unexposed regions 463a and maintaining the EUV exposed regions 463b, which in turn provides a pattern or a patterned film having maintained regions 466b. The developing operation can include any described herein that includes any acid described herein. In some embodiments, the developing operation results in the formation of residual resist component 466a. In other embodiments, the method further includes conducts a stripping step or a treating step to remove the residual resist component.

The method 450 can further include treating the developed film 454 with an acid. Treating can include exposing the developed film to any acid described herein, including dry or wet processes include the acid. In this matter, the treated film can include maintained regions 467b and removed regions 467a free of residual components.

The treating and developing steps can conducted under the same or different conditions, such as any described herein for a development process (e.g., a dry development process and/or wet development process). In one embodiment, both the stripping and developing steps can include use of an acid that is a dry process. In another embodiment, stripping of the resist layer includes use of acid in a gas phase, and developing of the film includes use of halide chemistry acid in a liquid phase. Additional development process conditions are described herein.

Optionally (e.g., after development, before acid treatment, or after acid treatment), the method can further hardening an exposed film, a developed film, or a patterned film (e.g., to provide a resist mask). Hardening steps can include any useful process to further crosslink or react the EUV unexposed regions or EUV exposed regions. In one embodiments, hardening is performed to further crosslink or react the EUV exposed regions. Exemplary hardening steps can include exposing to plasma, annealing, thermal baking, or combinations thereof that can be useful for a post development baking (PDB) step. In particular embodiments, hardening can include exposure to plasma (e.g., O₂, O₃, Ar, He, or CO₂ plasma); exposure to vacuum ultraviolet (VUV), optionally in the presence of an O₂, Ar, He, or CO₂ plasma environment; thermal annealing (e.g., at a temperature of about 180° C. to about 240° C.), optionally in the presence of an air ambient environment or atomic oxygen or in the presence of an ozone/O₂ ambient environment; or combinations thereof.

In one embodiment, the hardened or densified film is provided by annealing in the absence of an oxygen (O)-containing gas. In some instances, annealing can include heating to a temperature at or above about 190° C. In some embodiments, annealing can be conducted under vacuum, in the presence of an inert gas (e.g., nitrogen gas (N₂), argon gas (Ar), or other non-oxidizing gas), or in the presence of an oxygen (O)-free gas, i.e., a gas free of oxygen atoms. Non-limiting examples of oxygen-free gas include O₂-free gas or H₂O-free gas. The inert gas can include one gas or a combination of inert gases. In some embodiments, a non-oxidizing gas is a gas having less than 1% of an oxygen (O)-containing gas (e.g., less than 1% of an O₂ gas). Gases can be employed at atmosphere pressure or lower.

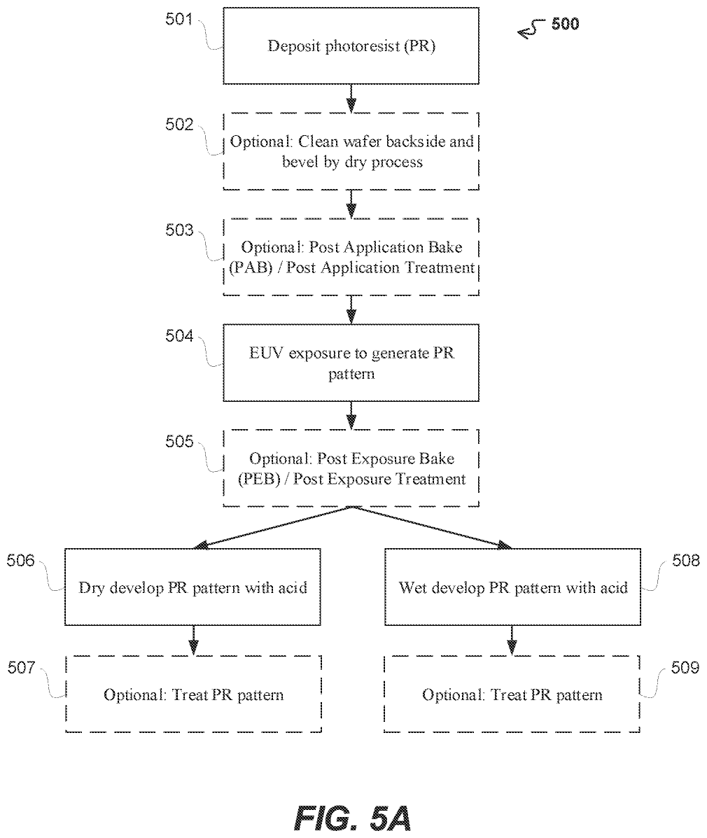

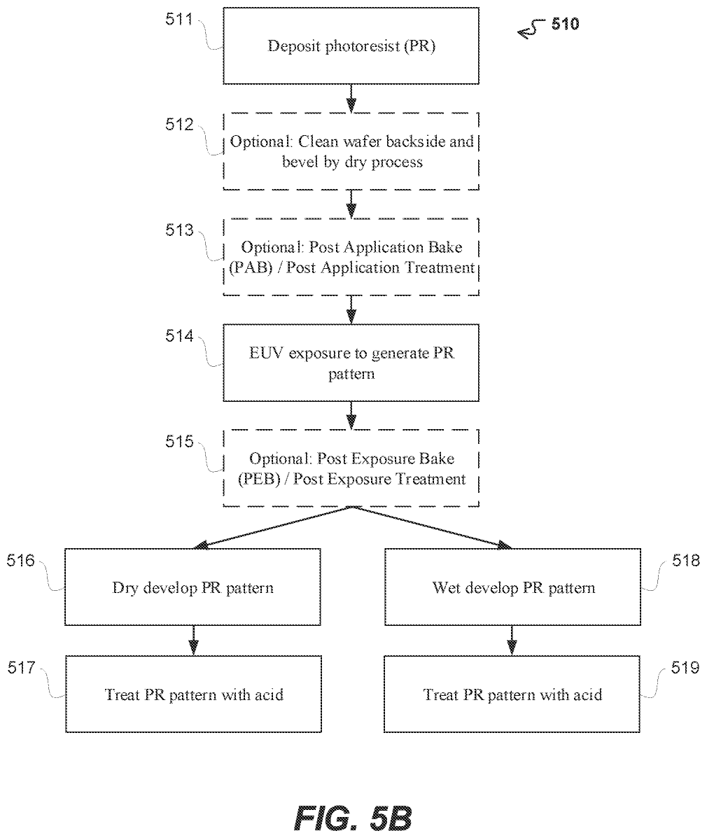

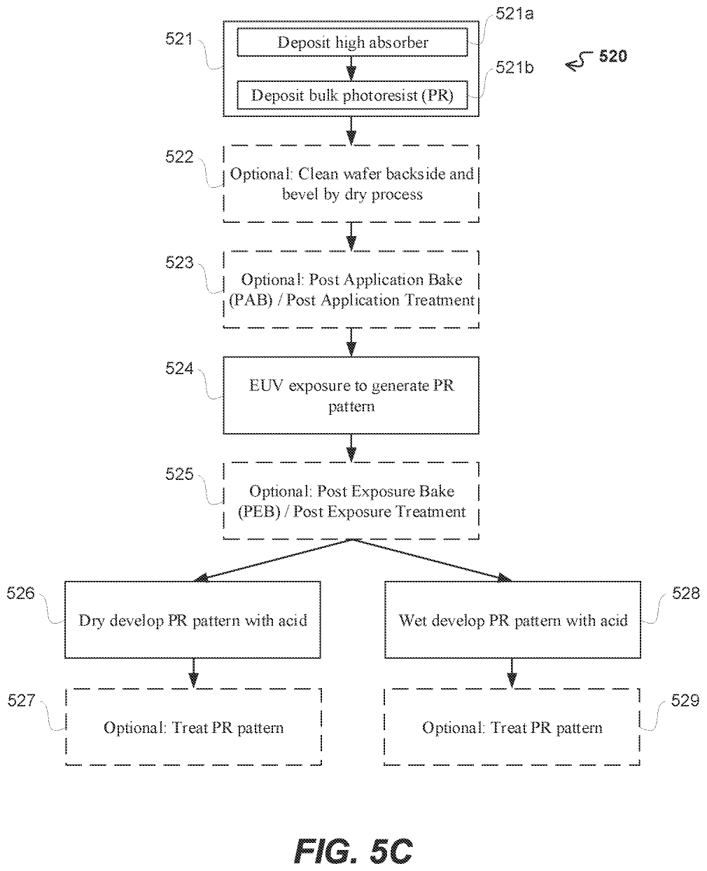

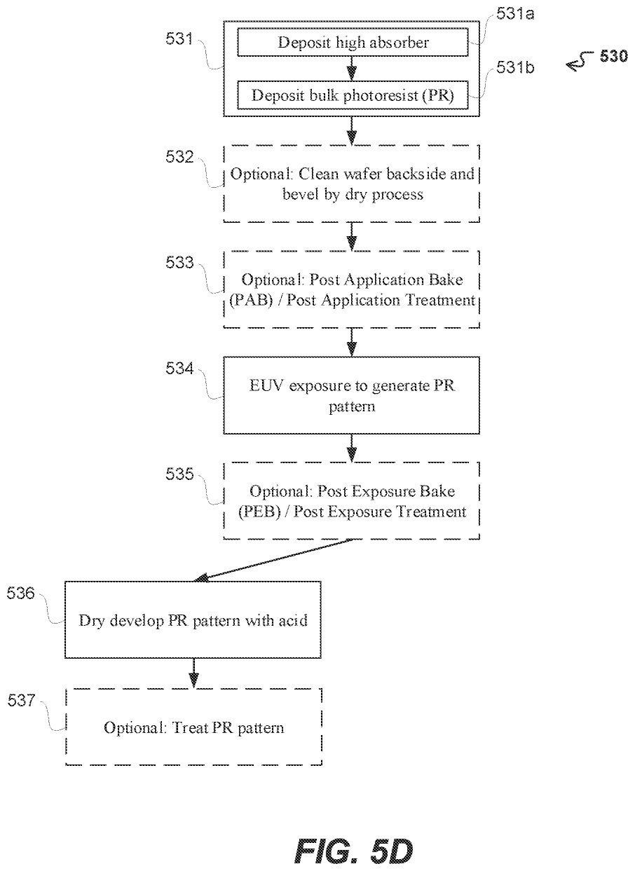

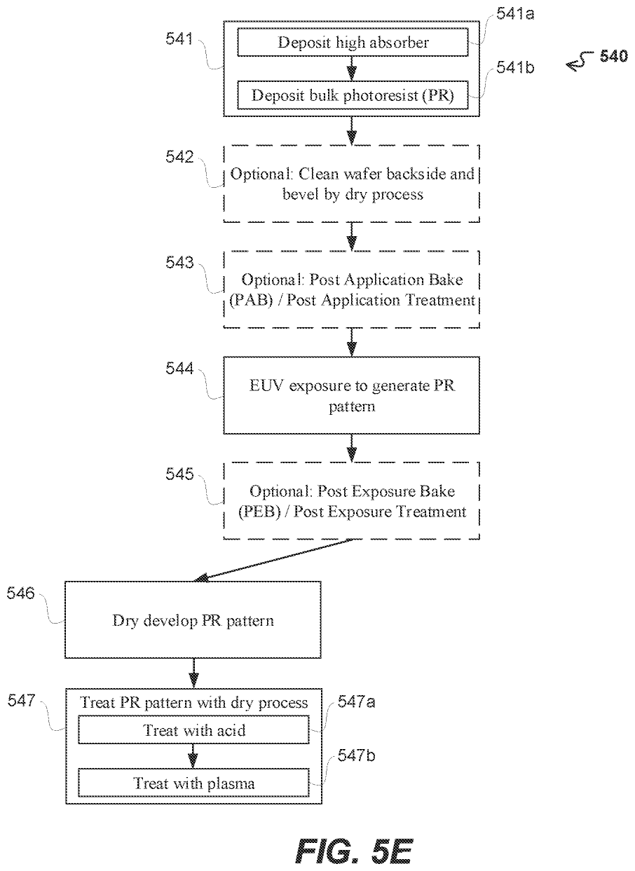

FIG. 5A provides a flow chart of an exemplary method 500 having various operations, including optional operations. Optional steps may be conducted to further modulate, modify, or treat the EUV-sensitive film(s) and/or substrate in any method herein.

As can be seen, in operation 501, a film is deposited employing one or more precursors with an optional counter-reactant to provide a photoresist (PR). In optional operation 502, the backside surface or bevel of the substrate can be cleaned, and/or an edge bead of the photoresist that was deposited in the prior step can be removed. Such cleaning or removing steps can be useful for removing particles that may be present after depositing a photoresist layer. The removing step can include processing the wafer with a wet metal oxide (MeOx) edge bead removal (EBR) step.

In optional operation 503, post-application bake (PAB) or another post-application treatment can be performed. Such treatment can improve etch resistance of unexposed material to acid (in a vapor or a liquid form). In another instance, such treatment can reduce the hydrophobicity difference (or contrast) between unexposed and exposed regions, thus the PAB operation is not conducted. In yet another instance, use of PAB removes residual moisture from the layer to form a hardened resist film. The PAB can involve some combination of thermal treatment, chemical exposure, and/or moisture to increase the EUV sensitivity of the film, thereby reducing the EUV dose to develop a pattern in the film. In particular embodiments, the PAB step is conducted at a temperature greater than about 100° C. or at a temperature of from about 100° C. to about 200° C. or from about 100° C. to about 250° C. In other embodiments, the PAB step is conducted at a temperature from about 190° C. to about 350° C. in the absence of an O-containing gas. In another instance, post-application treatment includes exposing the film to an inert gas or CO₂, which can optionally include cooling or heating. Use of an inert gas can provide metal-oxygen-metal species, and use of CO₂ can provide metal carbonate species within the film.

In operation 504, the film is exposed to EUV radiation to develop a pattern. Generally, the EUV exposure causes a change in the chemical composition of the film, creating a contrast in etch selectivity that can be used to remove a portion of the film. Such a contrast can provide a negative tone resist, as described herein. EUV exposure can include, e.g., an exposure having a wavelength in the range of about 10 nm to about 20 nm in a vacuum ambient (e.g., about 13.5 nm in a vacuum ambient).

Operation 505 is an optional post-exposure bake (PEB) of the exposed film, thereby further removing residual moisture, promoting chemical condensation within the film, or increasing contrast in etch selectivity of the exposed film; or post-treating the film in any useful manner. In one instance, such treatment can reduce the contrast between unexposed and exposed regions, thus the PEB operation is not conducted. In another instance, the exposed film can be thermally treated (e.g., optionally in the presence of various chemical species) to promote reactivity within the EUV exposed or unexposed portions of the resist upon exposure to a stripping agent or a negative tone developer (e.g., a halogen-based acid, such as HCl, HBr, HI, or combinations thereof, in vapor or liquid form). In another instance, the exposed film can be thermally treated to further cross-link ligands within the EUV exposed portions of the resist, thereby providing EUV unexposed portions that can be selectively removed upon exposure to a stripping agent (e.g., a negative tone developer). In yet another instance, PEB is omitted.

Next, the PR pattern can be developed by way of negative tone development or negative tone development. In one instance, the PR pattern is developed by way of negative development (e.g., as described herein). In various embodiments of development, the unexposed regions are removed (to provide a pattern within a negative tone resist). In other various embodiments of development, the exposed regions are removed (to provide a pattern within a positive tone resist). These steps may be dry processes (e.g., any described herein) or wet processes using one or more developers or developing solutions, followed by an optional rinse (e.g., with deionized water or another solvent). In particular embodiments, the development step is a dry process applied to a tin-based film. In other embodiments, the development step is a wet process applied to a tin-based film.

In one instance, operation 506 includes one or more dry processes using one or more developers containing an acid (e.g., an acidic vapor). In another instance, operation 508 includes one or more wet processes using one or more developers containing an acid (e.g., an acidic solution). The wet process may optionally be followed by an optional rinse operation (e.g., with deionized water or another solvent) or an optional dry operation (e.g., with air or under inert conditions with optional heat). Optionally, wet development can include or be followed by a prewetting step (e.g., by use of an aqueous solvent, such as any described herein), a rinse step (e.g., by use of an aqueous solvent, such as any described herein), and/or a drying step. Acidic development (with or without a rinse operation) can be repeated an n number of times, in which n is 1, 2, 3, 4, 5, or more.

After development one or more optional operations may be conducted. For example, the method can include a treatment operation to remove residual species present after development. In one instance, optional operation 507 includes treating a dry developed PR pattern with a plasma-based process, a baking operation, or an acid-based treatment operation. In another instance, optional operation 509 includes treating a wet developed PR pattern with a plasma-based process, a baking operation, or an acid-based treatment operation. When a wet process is employed, such as process may be followed by an optional rinse operation (e.g., with deionized water or another solvent) or an optional dry operation (e.g., with air or under inert conditions with optional heat).

Methods can include treatment of the photoresist pattern with acid. Such methods can include development, which may or may not include the same acid and/or the same conditions as in the treatment operation. FIG. 5B provides a flow chart of an exemplary method 510 having various operations, including optional operations. As can be seen, in operation 511, a film having a photoresist (PR) is deposited.

The method includes various optional operations, which have been described with respect to FIG. 5A. Similarly, exemplary method 510 in FIG. 5B can include optional operation 512 for cleaning the backside surface or bevel of the substrate and/or removing an edge bead of the photoresist that was deposited in the prior step; optional operation 513 for PAB or another post-application treatment; and optional operation 515 for PEB or another post-exposure treatment.

In operation 514, the film is exposed to EUV radiation to develop a pattern. Next, the PR pattern can be developed by way of negative tone development or positive tone development. Operation 516 can be performed to dry develop the PR pattern, and operation 517 can be performed to treat the PR pattern with acid (e.g., thereby removing residual species present after development, in which acid can be provided in vapor form or liquid form). Alternatively, operation 518 can be performed to wet develop the PR pattern, and operation 519 can be performed to treat the PR pattern with acid (e.g., thereby removing residual species present after development, in which acid can be provided in vapor form or liquid form).

The PR film can be deposited in any useful manner. FIG. 5C provides a flow chart of an exemplary method 520 having various operations, including optional operations. As can be seen, in operation 521, a film and an absorbing layer are deposited. In particular, operation 521a includes employing a precursor (e.g., a first precursor different than that employed in operation 521b) with an optional counter-reactant to provide an absorbing layer. Operation 521b includes employing a precursor (e.g., a second precursor) with an optional counter-reactant to provide a bulk photoresist (PR).

The method further includes optional operation 522 for cleaning the backside surface or bevel of the substrate and/or removing an edge bead of the photoresist that was deposited in the prior step. Other optional operations includes operation 523 for PAB or another post-application treatment and/or operation 525 for PEB or another post-exposure treatment.

In operation 524, the film is exposed to EUV radiation to develop a pattern. Next, the PR pattern can be developed by way of negative tone development or positive tone development.

Next, the PR pattern can be developed by way of negative tone development or positive tone development. Operation 526 can be performed to dry develop the PR pattern with acid, and optional operation 527 can be performed to treat the PR pattern (e.g., thereby removing residual species present after development, in which treatment may optionally include an acid in vapor form or liquid form). Alternatively, operation 528 can be performed to wet develop the PR pattern with acid, and optional operation 529 can be performed to treat the PR pattern (e.g., thereby removing residual species present after development, in which treatment may optionally include an acid in vapor form or liquid form).

Dry processes may be employed. In certain instances, only dry processes are employed within the method. FIG. 5D provides a flow chart of an exemplary method 530 having various operations, including optional operations. As can be seen, in operation 531, a film and an absorbing layer are deposited. In particular, operation 531a includes employing a precursor (e.g., a first precursor different than that employed in operation 531b) with an optional counter-reactant to provide an absorbing layer. Operation 531b includes employing a precursor (e.g., a second precursor) with an optional counter-reactant to provide a bulk photoresist (PR).

Optional operations can include operation 532 for cleaning the backside surface or bevel of the substrate and/or removing an edge bead of the photoresist that was deposited in the prior step; operation 533 for PAB or another post-application treatment; and operation 535 for PEB or another post-exposure treatment.

In operation 534, the film is exposed to EUV radiation to develop a pattern in a dry process. Next, the PR pattern can be dry developed by way of negative tone development or positive tone development. Operation 536 can be performed to dry develop the PR pattern with an acid, and optional operation 537 can be performed to treat the PR pattern (e.g., thereby removing residual species present after dry development, in which an acid can be optionally provided in vapor form).

Post-development processes can also include dry processes. FIG. 5E provides a flow chart of an exemplary method 540 having various operations, including optional operations. As can be seen, in operation 541, a film and an absorbing layer are deposited. In particular, operation 541a includes employing a precursor (e.g., a first precursor different than that employed in operation 541b) with an optional counter-reactant to provide an absorbing layer. Operation 541b includes employing a precursor (e.g., a second precursor) with an optional counter-reactant to provide a bulk photoresist (PR).

Optional operations can include operation 542 for cleaning the backside surface or bevel of the substrate and/or removing an edge bead of the photoresist that was deposited in the prior step; operation 543 for PAB or another post-application treatment; and operation 545 for PEB or another post-exposure treatment.

In operation 544, the film is exposed to EUV radiation to develop a pattern in a dry process. Next, the PR pattern can be dry developed by way of negative tone development or positive tone development. Operation 546 can be performed to dry develop the PR pattern with an acid, and operation 547 can be performed to treat the PR pattern with a dry process. In particular, operation 547 can further include operation 547a to treat the PR pattern with an acid in vapor form (e.g., thereby providing a treated pattern) and operation 547b to treat the PR pattern with plasma in the presence of a vapor (e.g., a gas).

In some embodiments, PAB and PEB may (or may not) be performed in a negative tone process. Without wishing to be limited by mechanism, the negative process described herein employs an acid for removing resist components, and even residual resist components that can be present after development (e.g., dry development) and/or treatment (e.g., acid treatment). In particular embodiments, residual resist component can include residual metal halide species or other residual species including at least one highly absorbing element.

In any embodiment herein, the method can include (e.g., after development) rinsing, further hardening, and/or baking the patterned film, thereby providing a resist mask disposed on a top surface of the substrate. Hardening steps can include any useful process to further crosslink or react the EUV unexposed or exposed regions, such as steps of exposing to plasma (e.g., O₂, O₃, Ar, He, or CO₂ plasma), exposing to ultraviolet radiation, annealing (e.g., at a temperature of about 180° C. to about 240° C.), thermal baking, or combinations thereof that can be useful for a post-development baking (PDB) step.

Any useful type of chemistry can be employed during the depositing, patterning, developing, and/or treating steps. Such steps may be based on dry processes employing chemistry in a gaseous phase or wet processes employing chemistry in a wet phase. Various embodiments include combining dry operations of film formation by vapor deposition and (EUV) lithographic photopatterning with dry/wet development operations and with optional dry/wet treatment operations.

Accordingly, it has been demonstrated that high performance, dry deposited EUV photoresist material can be effectively patterned to give negative tone images or to provide treated positive tone images. This could also enable the application of acids, including dilute acids in vapor or liquid forms, to provide novel process flows involving EUV PR films.

### Acids

The acid can be provided as a vapor or as a liquid (e.g., with an optional solvent). The acid can include any useful acid, such as an inorganic acid, a halogen-containing acid, a hydrogen halide, an organic acid, a phosphorus oxoacid, a sulfur oxoacid, a carboxylic acid, or a silyl halide.

In some embodiments, the inorganic acid is any that lacks a carbon atom. In one embodiment, the inorganic acid is a halogen-containing acid (e.g., a hydrogen halide), such as those including fluorine, chlorine, bromine, and/or iodine; a phosphorus oxoacid; or a sulfur oxoacid. Non-limiting hydrogen halides include hydrogen fluoride (HF), hydrogen chloride (HCl), hydrogen bromide (HBr), hydrogen iodide (HI), and combinations thereof.

In some embodiments, the acid is a phosphorus oxoacid (e.g., phosphoric acid), a sulfur oxoacid (e.g., sulfuric acid), or a carboxylic acid (e.g., formic acid, acetic acid, trifluoroacetic acid, oxalic acid, citric acid, and combinations thereof).

In other embodiments, the acid is an organic acid or an organohalide compound. Non-limiting examples of an organic acid includes formic acid, acetic acid, trifluoroacetic acid, oxalic acid, citric acid, and the like. Non-limiting organohalide compounds include an organofluorine compound, including trifluoroacetic acid; an organochlorine compound; an organobromine compound, or an organoiodine compound.

In certain embodiments, the acid can be provided by way of a reactant configured to provide the acid. Non-limiting reactants can include a halogenated borane including trichloroborane (BCl₃), tribromoborane (BBr₃), triiodoborane (BI₃), a halogenated silane including tetrachlorosilane (SiCl₄), tetrabromosilane (SiBr₄), tetraiodosilane (SiI₄), a trialkyl silyl halide including trimethylsilyl chloride, trimethylsilyl bromide, trimethylsilyl iodide, triethylsilyl chloride, triethylsilyl bromide, triethylsilyl iodide, tripropylsilyl chloride, tripropylsilyl bromide, tripropylsilyl iodide, triisopropylsilyl chloride, triisopropylsilyl bromide, triisopropylsilyl iodide, tributylsilyl chloride, tributylsilyl bromide, tributylsilyl iodide, triisobutylsilyl chloride, triisobutylsilyl bromide, triisobutylsilyl iodide, trisecbutylsilyl chloride, trisecbutylsilyl bromide, trisecbutylsilyl iodide, tritertbutylsilyl chloride, tritertbutylsilyl bromide, tritertbutylsilyl iodide, dimethyl-ethyl-silyl chloride, dimethyl-propyl-silyl chloride, dimethyl-isopropyl-silyl chloride, dimethyl-butyl-silyl chloride, dimethyl-isobutyl-silyl chloride, dimethyl-secbutyl-silyl chloride, dimethyl-tertbutyl-silyl chloride, dimethyl-tertbutyl-silyl bromide, dimethyl-tertbutyl-silyl iodide, methyl-diethyl-silyl chloride, methyl-diethyl-silyl bromide, methyl-diethyl-silyl iodide, methyl-dipropyl-silyl chloride, methyl-diisopropyl-silyl chloride, methyl-dibutyl-silyl chloride, methyl-diisobutyl-silyl chloride, methyl-disecbutyl-silyl chloride, methyl-ditertbutyl-silyl chloride, methyl-ditertbutyl-silyl bromide, methyl-ditertbutyl-silyl iodide, a dialkyl dihalo silane including: dimethyldichloro silane, dimethyldibromo silane, dimethyldiiodo silane, diethyldichloro silane, diethyldibromo silane, diethyldiiodo silane, dipropyldichloro silane, dipropyldibromo silane, dipropyldiiodo silane, diisopropyldichloro silane, diisopropyldibromo silane, diisopropyldiiodo silane, dibutyldichloro silane, dibutyldibromo silane, dibutyldiiodo silane, diisobutyldichloro silane, diisobutyldibromo silane, diisobutyldiiodo silane, disecbutyldichloro silane, disecbutyldibromo silane, disecbutyldiiodo silane, ditertbutyldichloro silane, ditertbutyldibromo silane, ditertbutyldiiodo silane, methyl-ethyl-dichloro silane, methyl-ethyl-dibromo silane, methyl-ethyl-diiodo silane, methyl-propyl-dichloro silane, methyl-isopropyl-dichloro silane, methyl-butyl-dichloro silane, methyl-isobutyl-dichloro silane, methyl-secbutyl-dichloro silane, methyl-tertbutyl-dichloro silane, methyl-tertbutyl-dibromide silane, methyl-tertbutyl-diiodo silane, or a combination thereof. To form an acid, a halogenated borane can be provided in the presence of hydrogen gas (H₂), a halide gas (e.g., chlorine gas (Cl₂) or bromine gas (Br₂)), or a hydrogen-containing reagent (e.g., a hydrogen halide, such as HCl, HBr, or HI). In another embodiment, a hydrogen gas (H₂) and a halide gas (e.g., chlorine gas (Cl₂) or bromine gas (Br₂)) are combined to form an acid. In yet another embodiment, a halogenated silane can be provided in the presence of a hydrogen gas (H₂), a halide gas (e.g., chlorine gas (Cl₂) or bromine gas (Br₂)), or a hydrogen-containing reagent (e.g., a hydrogen halide, such as HCl, HBr, or HI). Optionally, the acid can be provided by exposing the reactant(s) to a plasma.

The acid can be employed in a dry process or a wet process. In a dry process, the acid can be used in combination with a vapor of an oxygen-containing reagent. Non-limiting oxygen-containing reagents include an oxygen gas (O₂), ozone (O₃), hydrogen peroxide (H₂O₂), and the like.

In a wet process, the acid can be provided with a solvent. Non-limiting solvents include an aqueous solvent (e.g., water) or an organic solvent, such as an alcohol (e.g., isopropyl alcohol (IPA)), a ketone (e.g., 2-heptanone, cyclohexanone, or acetone), an ether, such as a glycol ether (e.g., propylene glycol methyl ether (PGME) or propylene glycol methyl ether acetate (PGMEA)), or an ester (e.g., n-butyl acetate, γ-butyrolactone or ethyl 3-ethoxypropionate (EEP)), as well as combinations thereof. In other embodiments, the solvent includes a combination of two or more different solvents.

Use of an acid can include any exposure time, such as from about 5 seconds to 3 minutes (e.g., from about 10 seconds to 60 seconds). Such exposure times can be any sufficient for development by removing unexposed regions or for treatment by removing residual species.

An aqueous acid can be provided in any useful concentration, including a concentration of about 0.01% (v/v) to 20% (v/v) of an acid in a solvent (e.g., an aqueous solvent, such as water). In other embodiments, the concentration is about 0.01% (v/v) to 2% (v/v), 0.01% (v/v) to 5% (v/v), or 0.01% (v/v) to 10% (v/v) of an acid in a solvent.

### Precursors

The layers (e.g., absorbing layer) and films (e.g., resist film) herein may include an element (e.g., a metal atom or a non-metal atom, including one, two, three, or more elements) having a high photoabsorption cross-section, such as equal to or greater than 1×10⁷ cm²/mol. Such elements can be provided by depositing one or more precursor(s) to provide the resist film.

In some embodiments, the film is a radiation-sensitive film (e.g., an EUV-sensitive film). This film, in turn, can serve as an EUV resist, as further described herein. In particular embodiments, the layer or film can include one or more ligands (e.g., EUV labile ligands) that can be removed, cleaved, or cross-linked by radiation (e.g., EUV or DUV radiation).

The precursor can provide a patternable film, a patternable layer, and/or an absorbing layer that is sensitive to radiation (or a patterning radiation-sensitive film, a photopatternable film, a radiation-sensitive absorbing layer, a photopatternable absorbing layer). Such radiation can include EUV radiation, DUV radiation, or UV radiation that is provided by irradiating through a patterned mask, thereby being a patterned radiation. The film or absorbing layer itself can be altered by being exposed to such radiation, such that the film or the absorbing layer is radiation-sensitive or photosensitive. In particular embodiments, the precursor is an organometallic compound, which includes at least one metal center.

The precursor can have any useful number and type of ligand(s). In some embodiments, the ligand can be characterized by its ability to react in the presence of a counter-reactant, or in the presence of patterned radiation. For instance, the precursor can include a ligand that reacts with a counter-reactant, which can introduce linkages between metal centers (e.g., an —O— linkage). In another instance, the precursor can include a ligand that eliminates in the presence of patterned radiation. Such an EUV labile ligand can include branched or linear alkyl groups having a beta-hydrogen, as well as any described herein for R in formula (I) or (II). In one embodiment, the precursor is a capping agent having two, three, or more hydrophobic ligands (e.g., organic ligands, including optionally substituted alkyl, alkenyl, or alkynyl).

Other EUV labile ligands include alkyl, alkenyl, or alkynyl groups, which can be branched or linear. Yet other EUV labile ligands include aryl groups, such as those having one, two, or three rings. Such alkyl, alkenyl, alkynyl, and aryl groups can be substituted with one or more halos (e.g., one or more fluoro). Non-limiting labile ligands include optionally substituted C₁₋₁₂ alkyl, optionally substituted C₂₋₁₂ alkenyl, optionally substituted C₂₋₁₂ alkynyl, optionally substituted C₁₋₁₂ haloalkyl, optionally substituted C₂₋₁₂ haloalkenyl, optionally substituted C₂₋₁₂ haloalkynyl, optionally substituted aryl, or optionally substituted haloaryl.

The precursor can be any useful metal-containing precursor or metalloid-containing precursor, such as an organometallic agent, a metal halide, or a capping agent (e.g., as described herein). In a non-limiting instance, the precursor includes a structure having formula (I):

MₐR_{b} (I),

wherein:
M is a metal or an atom having a high EUV absorption cross-section;
each R is, independently, H, halo, optionally substituted alkyl, optionally substituted cycloalkyl, optionally substituted cycloalkenyl, optionally substituted alkenyl, optionally substituted alkynyl, optionally substituted alkoxy, optionally substituted alkanoyloxy, optionally substituted aryl, optionally substituted amino, optionally substituted bis(trialkylsilyl)amino, optionally substituted trialkylsilyl, oxo, an anionic ligand, a neutral ligand, or a multidentate ligand;
a≥1; and b≥1.

In another non-limiting instance, the precursor includes a structure having formula (II):

MₐR_{b}L_{c} (II),

wherein:
M is a metal or an atom having a high EUV absorption cross-section;
each R is, independently, halo, optionally substituted alkyl, optionally substituted aryl, optionally substituted amino, optionally substituted alkoxy, or L;
each L is, independently, a ligand, an anionic ligand, a neutral ligand, a multidentate ligand, ion, or other moiety that is reactive with a counter-reactant, in which R and L with M, taken together, can optionally form a heterocyclyl group or in which R and L, taken together, can optionally form a heterocyclyl group;
a≥1; b≥1; and c≥1.

In some embodiments, each ligand within the precursor can be one that is reactive with a counter-reactant. In one instance, the precursor includes a structure having formula (II), in which each R is, independently, L. In another instance, the precursor includes a structure having formula (IIa):

MₐL_{c} (IIa),

wherein:
M is a metal or an atom having a high EUV absorption cross-section;
each L is, independently, a ligand, ion, or other moiety that is reactive with a counter-reactant, in which two L, taken together, can optionally form a heterocyclyl group;
a≥1; and c≥1. In particular embodiments of formula (IIa), a is 1. In further embodiments, c is 2, 3, or 4.

For any formula herein, M can be a metal or a metalloid or an atom with a high patterning radiation-absorption cross-section (e.g., an EUV absorption cross-section that is equal to or greater than 1×10⁷ cm²/mol). In some embodiments, M is tin (Sn), bismuth (Bi), tellurium (Te), cesium (Cs), antimony (Sb), indium (In), molybdenum (Mo), hafnium (Hf), iodine (I), zirconium (Zr), iron (Fe), cobalt (Co), nickel (Ni), copper (Cu), zinc (Zn), silver (Ag), platinum (Pt), and lead (Pb). In further embodiments, M is Sn, a is 1, and c is 4 in formula (I), (II), or (IIa). In other embodiments, M is Sn, a is 1, and c is 2 in formula (I), (II), or (IIa). In particular embodiments, M is Sn(II) (e.g., in formula (I), (II), or (IIa)), thereby providing a precursor that is a Sn(II)-based compound. In other embodiments, M is Sn(IV) (e.g., in formula (I), (II), or (IIa)), thereby providing a precursor that is a Sn(IV)-based compound. In particular embodiments, the precursor includes iodine (e.g., as in periodate).

For any formula herein, each R is, independently, H, halo, optionally substituted alkyl, optionally substituted cycloalkyl, optionally substituted cycloalkenyl, optionally substituted alkenyl, optionally substituted alkynyl, optionally substituted alkoxy (e.g., —OR¹, in which R¹¹ can be optionally substituted alkyl), optionally substituted alkanoyloxy, optionally substituted aryl, optionally substituted amino, optionally substituted bis(trialkylsilyl)amino, optionally substituted trialkylsilyl, oxo, an anionic ligand (e.g., oxido, chlorido, hydrido, acetate, iminodiacetate, propanoate, butanoate, benzoate, etc.), a neutral ligand, or a multidentate ligand.

In some embodiments, the optionally substituted amino is —NR¹R², in which each R¹ and R² is, independently, H or alkyl; or in which R¹ and R², taken together with the nitrogen atom to which each are attached, form a heterocyclyl group, as defined herein. In other embodiments, the optionally substituted bis(trialkylsilyl)amino is —N(SiR¹R²R³)₂, in which each R¹, R², and R³ is, independently, optionally substituted alkyl. In yet other embodiments, the optionally substituted trialkylsilyl is —SiR¹R²R³, in which each R¹, R², and R³ is, independently, optionally substituted alkyl.

In other embodiments, the formula includes a first R (or first L) that is —NR¹R² and a second R (or second L) that is —NR¹R², in which each R¹ and R² is, independently, H or optionally substituted alkyl; or in which R¹ from a first R (or first L) and R¹ from a second R (or second L), taken together with the nitrogen atom and the metal atom to which each are attached, form a heterocyclyl group, as defined herein. In yet other embodiments, the formula includes a first R that is —OR¹ and a second R that is —OR¹, in which each R¹ is, independently, H or optionally substituted alkyl; or in which R¹ from a first R and R¹ from a second R, taken together with the oxygen atom and the metal atom to which each are attached, form a heterocyclyl group, as defined herein.

In some embodiments, at least one of R or L (e.g., in formula (I), (II), or (IIa)) is optionally substituted alkyl. Non-limiting alkyl groups include, e.g., CₙH₂ₙ₊₁, where n is 1, 2, 3, or greater, such as methyl, ethyl, n-propyl, isopropyl, n-butyl, isobutyl, s-butyl, or t-butyl. In various embodiments, R or L has at least one beta-hydrogen, beta-halogen, or beta-fluorine. In other embodiments, at least one of R or L is a halo-substituted alkyl (e.g., a fluoro-substituted alkyl).

In some embodiments, each R or L or at least one R or L (e.g., in formula (I), (II), or (IIa)) is halo. In particular, the precursor can be a metal halide. Non-limiting metal halides include SnBr₄, SnCl₄, SnI₄, and SbCl₃.

In some embodiments, each R or L or at least one R or L (e.g., in formula (I), (II), or (IIa)) can include a nitrogen atom. In particular embodiments, one or more R or L can be optionally substituted amino, an optionally substituted monoalkylamino (e.g., —NR¹H, in which R¹ is optionally substituted alkyl), an optionally substituted dialkylamino (e.g., —NR¹R², in which each R¹ and R² is, independently, optionally substituted alkyl), or optionally substituted bis(trialkylsilyl)amino. Non-limiting R and L substituents can include, e.g., —NMe₂, —NHMe, —NEt₂, —NHEt, —NMeEt, —N(t-Bu)-[CHCH₃]₂—N(t-Bu)-(tbba), —N(SiMe₃)₂, and —N(SiEt₃)₂.

In some embodiments, each R or L or at least one R or L (e.g., in formula (I), (II), or (IIa)) can include a silicon atom. In particular embodiments, one or more R or L can be optionally substituted trialkylsilyl or optionally substituted bis(trialkylsilyl)amino. Non-limiting R or L substituents can include, e.g., —SiMe₃, —SiEt₃, —N(SiMe₃)₂, and —N(SiEt₃)₂.

In some embodiments, each R or L or at least one R or L (e.g., in formula (I), (II), or (IIa)) can include an oxygen atom. In particular embodiments, one or more R or L can be optionally substituted alkoxy or optionally substituted alkanoyloxy. Non-limiting R or L substituents include, e.g., methoxy, ethoxy, isopropoxy (i-PrO), t-butoxy (t-BuO), acetate (—OC(O)—CH₃), and —O═C(CH₃)—CH═C(CH₃)—O— (acac).

Any formulas herein can include one or more neutral ligands. Non-limiting neutral ligands include an optionally substituted amine (e.g., NR₃ or R₂N-Ak-NR₂, in which each R can be, independently, H, optionally substituted alkyl, optionally substituted hydrocarbyl, or optionally substituted aryl, and Ak is optionally substituted alkylene), an optionally substituted phosphine (e.g., PR₃ or R₂P-Ak-PR₂, in which each R can be, independently, H, optionally substituted alkyl, optionally substituted hydrocarbyl, or optionally substituted aryl, and Ak is optionally substituted alkylene), an optionally substituted ether (e.g., OR₂, in which each R can be, independently, H, optionally substituted alkyl, optionally substituted hydrocarbyl, or optionally substituted aryl), an optionally substituted alkyl, an optionally substituted alkene, an optionally substituted alkyne, an optionally substituted benzene, oxo, or carbon monoxide.

Any formulas herein can include one or more multidentate (e.g., bidentate) ligands. Non-limiting multidentate ligand include a diketonate (e.g., acetylacetonate (acac) or —OC(R¹)-Ak-(R¹)CO— or —OC(R¹)—C(R²)—(R¹)CO—), a bidentate chelating dinitrogen (e.g., —N(R¹)-Ak-N(R¹)— or —N(R³)—CR⁴—CR²═N(R¹)—), an aromatic (e.g., —Ar—), an amidinate (e.g., —N(R¹)—C(R²)—N(R¹)—), an aminoalkoxide (e.g., —N(R¹)-Ak-O— or —N(R¹)₂-Ak-O—), a diazadienyl (e.g., —N(R¹)—C(R²)—C(R²)—N(R¹)—), a cyclopentadienyl, a pyrazolate, an optionally substituted heterocyclyl, an optionally substituted alkylene, or an optionally substituted heteroalkylene. In particular embodiments, each R¹ is, independently, H, optionally substituted alkyl, optionally substituted haloalkyl, or optionally substituted aryl; each R² is, independently, H or optionally substituted alkyl; R³ and R⁴, taken together, forms an optionally substituted heterocyclyl; Ak is optionally substituted alkylene; and Ar is optionally substituted arylene.

In particular embodiments, the precursor includes tin. In some embodiments, the tin precursor includes SnR or SnR₂ or SnR₄ or R₃SnSnR₃, wherein each R is, independently, H, halo, optionally substituted C₁₋₁₂ alkyl, optionally substituted C₁₋₁₂ alkoxy, optionally substituted amino (e.g., —NR¹R²), optionally substituted C₂₋₁₂ alkenyl, optionally substituted C₂₋₁₂ alkynyl, optionally substituted C₃₋₈ cycloalkyl, optionally substituted aryl, cyclopentadienyl, optionally substituted bis(trialkylsilyl)amino (e.g., —N(SiR¹R²R³)₂), optionally substituted alkanoyloxy (e.g., acetate), a diketonate (e.g., —OC(R¹)-Ak-(R²)CO—), or a bidentate chelating dinitrogen (e.g., —N(R¹)-Ak-N(R¹)—). In particular embodiments, each R¹, R², and R³ is, independently, H or C₁₋₁₂ alkyl (e.g., methyl, ethyl, isopropyl, t-butyl, or neopentyl); and Ak is optionally substituted C₁₋₆ alkylene. In particular embodiments, each R is, independently, halo, optionally substituted C₁₋₁₂ alkoxy, optionally substituted amino, optionally substituted aryl, cyclopentadienyl, or a diketonate. Non-limiting tin precursors include SnF₂, SnH₄, SnBr₄, SnCl₄, SnI₄, tetramethyl tin (SnMe₄), tetraethyl tin (SnEt₄), trimethyl tin chloride (SnMe₃Cl), dimethyl tin dichloride (SnMe₂Cl₂), methyl tin trichloride (SnMeCl₃), tetraallyltin, tetravinyl tin, hexaphenyl ditin (IV) (Ph₃Sn—SnPh₃, in which Ph is phenyl), dibutyldiphenyltin (SnBu₂Ph₂), trimethyl(phenyl) tin (SnMe₃Ph), trimethyl(phenylethynyl) tin, tricyclohexyl tin hydride, tributyl tin hydride (SnBu₃H), dibutyltin diacetate (SnBu₂(CH₃COO)₂), tin(II) acetylacetonate (Sn(acac)₂), tributyltin ethoxide (SnBu₃(OEt)), dibutyltin dimethoxide (SnBu₂(OMe)₂), tributyltin methoxide (SnBu₃(OMe)), tin(IV) tert-butoxide (Sn(t-BuO)₄), n-butyltin tributoxide (Sn(n-Buxt-BuO)₃), tetrakis(dimethylamino)tin (Sn(NMe₂)₄), tetrakis(ethylmethylamino)tin (Sn(NMeEt)₄), tetrakis(diethylamino)tin(IV) (Sn(NEt₂)₄), (dimethylamino)trimethyl tin(IV) (Sn(Me)₃(NMe₂), Sn(i-Pr)(NMe₂)₃, Sn(n-Bu)(NMe₂)₃, Sn(s-Bu)(NMe₂)₃, Sn(i-Bu)(NMe₂)₃, Sn(t-Bu)(NMe₂)₃, Sn(t-Bu)₂(NMe₂)₂, Sn(t-Bu)(NEt₂)₃, Sn(tbba), Sn(II) (1,3-bis(1,1-dimethylethyl)-4,5-dimethyl-(4R,5R)-1,3,2-diazastannolidin-2-ylidene), or bis[bis(trimethylsilyl)amino]tin (Sn[N(SiMe₃)₂]₂).

In other embodiments, the precursor includes bismuth, such as in BiR₃, wherein each R is, independently, halo, optionally substituted C₁₋₁₂ alkyl, mono-C₁₋₁₂ alkylamino (e.g., —NR¹H), di-C₁₋₁₂ alkylamino (e.g., —NR¹R²), optionally substituted aryl, optionally substituted bis(trialkylsilyl)amino (e.g., —N(SiR¹R²R³)₂), or a diketonate (e.g., —OC(R⁴)-Ak-(R⁵)CO—). In particular embodiments, each R¹, R², and R³ is, independently, C₁₋₁₂ alkyl (e.g., methyl, ethyl, isopropyl, t-butyl, or neopentyl); and each R⁴ and R⁵ is, independently, H or optionally substituted C₁₋₁₂ alkyl (e.g., methyl, ethyl, isopropyl, t-butyl, or neopentyl). Non-limiting bismuth precursors include BiCl₃, BiMe₃, BiPh₃, Bi(NMe₂)₃, Bi[N(SiMe₃)₂]₃, and Bi(thd)₃, in which thd is 2,2,6,6-tetramethyl-3,5-heptanedionate.

In other embodiments, the precursor includes tellurium, such as TeR₂ or TeR₄, wherein each R is, independently, halo, optionally substituted C₁₋₁₂ alkyl (e.g., methyl, ethyl, isopropyl, t-butyl, and neopentyl), optionally substituted C₁₋₁₂ alkoxy, optionally substituted aryl, hydroxyl, oxo, or optionally substituted trialkylsilyl. Non-limiting tellurium precursors include dimethyl tellurium (TeMe₂), diethyl tellurium (TeEt₂), di(n-butyl) tellurium (Te(n-Bu)₂), di(isopropyl) tellurium (Te(i-Pr)₂), di(t-butyl) tellurium (Te(t-Bu)₂), t-butyl tellurium hydride (Te(t-Bu)(H)), Te(OEt)₄, bis(trimethylsilyl)tellurium (Te(SiMe₃)₂), and bis(triethylsilyl) tellurium (Te(SiEt₃)₂).

The precursor can include antimony, such as in SbR₃, wherein each R is, independently, halo, optionally substituted C₁₋₁₂ alkyl (e.g., methyl, ethyl, isopropyl, t-butyl, and neopentyl), optionally substituted C₁₋₁₂ alkoxy, or optionally substituted amino (e.g., —NR¹R², in which each R¹ and R² is, independently, H or optionally substituted C₁₋₁₂ alkyl). Non-limiting antimony precursors include SbCl₃, Sb(OEt)₃, Sb(On-Bu)₃, and Sb(NMe₂)₃.

Other precursors include indium precursors, such as in InR₃, wherein each R is, independently, halo, optionally substituted C₁₋₁₂ alkyl (e.g., methyl, ethyl, isopropyl, t-butyl, and neopentyl), or a diketonate (e.g., —OC(R⁴)-Ak-(R⁵)CO—, in which each R⁴ and R⁵ is, independently, H or C₁₋₁₂ alkyl). Non-limiting indium precursors include InCp, in which Cp is cyclopentadienyl, InCl₃, InMe₃, In(acac)₃, In(CF₃COCHCOCH₃)₃, and In(thd)₃.

The precursor can include iodine, such as RI, wherein R is iodo (I), hydrogen (H), optionally substituted C₁₋₁₂ alkyl, or periodate. Non-limiting iodine precursors include hydrogen iodide (HI), iodine gas (I₂), diiodomethane (CH₂I₂), and periodate.

Yet other precursors and non-limiting substituents are described herein. For instance, precursors can be any having a structure of formulas (I), (II), and (IIa), as described above; or formulas (III), (IV), (V), (VI), (VII), or (VIII), as described below. Any of the substituents M, R, X, or L, as described herein, can be employed in any of formulas (I), (II), (IIa), (III), (IV), (V), (VI), (VII), or (VIII).

Various atoms present in the precursor and/or counter-reactant can be provided within a gradient film. In some embodiments of the techniques discussed herein, a non-limiting strategy that can further improve absorption within a PR film by creating a vertically graded film. The strategy of engineering a vertical composition gradient in a PR film is particularly applicable to dry deposition methods, such as CVD and ALD, and can be realized by tuning the flow ratios between different precursors, reactants, counter-reactants, or gases during deposition. The type of composition gradients that can be engineered include: the ratios between different R or L ligands for the precursor, use of different precursors having different M atoms, use of different precursors having different R ligands, use of different counter-reactants, and combinations of the above that can be modified or changed during deposition.

Such gradient films can be formed by using any precursors (e.g., tin or non-tin precursors) and/or counter-reactants described herein. Yet other films, methods, precursors, and other compounds are described in U.S. Provisional Pat. Appl. No. 62/909,430, filed Oct. 2, 2019, and International Appl No. PCT/US20/53856, filed Oct. 1, 2020, published as International Pub. No. WO 2021/067632, in which each is titled SUBSTRATE SURFACE MODIFICATION WITH HIGH EUV ABSORBERS FOR HIGH PERFORMANCE EUV PHOTORESISTS; and International Appl. No. PCT/US20/70172, filed Jun. 24, 2020, published as International Pub. No. WO 2020/264557, and titled PHOTORESIST WITH MULTIPLE PATTERNING RADIATION-ABSORBING ELEMENTS AND/OR VERTICAL COMPOSITION GRADIENT, the disclosures of which at least relating to the composition, deposition, and patterning of directly photopatternable metal-containing films to form EUV resist masks are incorporated by reference herein.

Various atoms present in the precursor(s) and/or counter-reactant(s) can be provided within a capping layer, which in turn is disposed on any useful layer or structure. The capping layer can be any useful thickness (e.g., any thickness described herein, including from about 0.1 nm to about 5 nm).

Furthermore, two or more different precursors can be employed within each layer (e.g., a film or a capping layer). For instance, two or more of any metal-containing precursors herein can be employed to form an alloy. In one non-limiting instance, tin telluride can be formed by employing tin precursor including an —NR₂ ligand with RTeH, RTeD, or TeR₂ precursors, in which R is an alkyl, particularly t-butyl or i-propyl. In another instance, a metal telluride can be formed by using a first precursor including an alkoxy or a halo ligand (e.g., SbCl₃) with a tellurium-containing precursor including a trialkylsilyl ligand (e.g., bis(trimethylsilyl)tellurium).

Yet other exemplary EUV-sensitive materials, as well as processing methods and apparatuses, are described in U.S. Pat. No. 9,996,004; Int. Pat. Pub. No. WO 2020/102085; and Int. Pat. Pub. No. WO 2019/217749, each of which is incorporated herein by reference in its entirety.

As described herein, the films, layers, and methods herein can be employed with any useful precursor. In some instances, the precursor includes a metal halide having the following formula (III):

MXₙ (III),
in which M is a metal, X is halo, and n is 2 to 4, depending on the selection of M. Exemplary metals for M include Sn, Te, Bi, or Sb. Exemplary metal halides include SnBr₄, SnCl₄, SnI₄, and SbCl₃.

Another non-limiting precursor includes a structure having formula (IV):

MRₙ (IV),
in which M is a metal; each R is independently H, an optionally substituted alkyl, amino (e.g., —NR₂, in which each R is independently alkyl), optionally substituted bis(trialkylsilyl)amino (e.g., —N(SiR₃)₂, in which each R is independently alkyl), or an optionally substituted trialkylsilyl (e.g., —SiR₃, in which each R is independently alkyl); and n is 2 to 4, depending on the selection of M. Exemplary metals for M include Sn, Te, Bi, or Sb. The alkyl group may be CₙH₂ₙ₊₁, where n is 1, 2, 3, or greater. Exemplary organometallic agents include SnMe₄, SnEt₄, TeRₙ, RTeR, t-butyl tellurium hydride (Te(t-Bu)(H)), dimethyl tellurium (TeMe₂), di(t-butyl) tellurium (Te(t-Bu)₂), di(isopropyl)tellurium (Te(i-Pr)₂), bis(trimethylsilyl)tellurium (Te(SiMe₃)₂), bis(triethylsilyl) tellurium (Te(SiEt₃)₂), tris(bis(trimethylsilyl)amido) bismuth (Bi[N(SiMe₃)₂]₃), Sb(NMe₂)₃, and the like.

Another non-limiting precursor can include a capping agent having the following formula (V):

MLₙ (V),
in which M is a metal; each L is independently an optionally substituted alkyl, amino (e.g., —NR¹R², in which each of R¹ and R² can be H or alkyl, such as any described herein), alkoxy (e.g., —OR, in which R is alkyl, such as any described herein), halo, or other organic substituent; and n is 2 to 4, depending on the selection of M. Exemplary metals for M include Sn, Te, Bi, or Sb. Exemplary ligands include dialkylamino (e.g., dimethylamino, methylethylamino, and diethylamino), alkoxy (e.g., t-butoxy and isopropoxy), halo (e.g., F, Cl, Br, and I), or other organic substituents (e.g., acetylacetone or N²,N³-di-tertbutyl-butane-2,3-diamino). Non-limiting capping agents include SnCl₄; SnI₄; Sn(NR₂)₄, wherein each of R is independently methyl or ethyl; or Sn(t-BuO)₄. In some embodiments, multiple types of ligands are present.

A precursor can include a hydrocarbyl-substituted capping agent having the following formula (VI):

RₙMXₘ (VI),
wherein M is a metal, R is a C₂₋₁₀ alkyl or substituted alkyl having a beta-hydrogen, and X is a suitable leaving group upon reaction with a hydroxyl group of the exposed hydroxyl groups. In various embodiments, n=1 to 3, and m=4−n, 3−n, or 2−n, so long as m>0 (or m≥1). For example, R may be t-butyl, t-pentyl, t-hexyl, cyclohexyl, isopropyl, isobutyl, sec-butyl, n-butyl, n-pentyl, n-hexyl, or derivatives thereof having a heteroatom substituent in the beta position. Suitable heteroatoms include halogen (F, Cl, Br, or I), or oxygen (—OH or —OR). X may be dialkylamino (e.g., dimethylamino, methylethylamino, or diethylamino), alkoxy (e.g., t-butoxy, isopropoxy), halo (e.g., F, Cl, Br, or I), or another organic ligand. Examples of hydrocarbyl-substituted capping agents include t-butyltris(dimethylamino)tin (Sn(t-Bu)(NMe₂)₃), n-butyltris(dimethylamino)tin (Sn(n-Bu)(NMe₂)₃), t-butyltris(diethylamino)tin (Sn(t-Bu)(NEt₂)₃), di(t-butyl)di(dimethylamino)tin (Sn(t-Bu)₂(NMe₂)₂), sec-butyltris(dimethylamino)tin (Sn(s-Bu)(NMe₂)₃), n-pentyltris(dimethylamino)tin (Sn(n-pentyl)(NMe₂)₃), i-butyltris(dimethylamino) tin (Sn(i-Bu)(NMe₂)₃), i-propyltris(dimethylamino)tin (Sn(i-Pr)(NMe₂)₃), t-butyltris(t-butoxy)tin (Sn(t-Bu)(t-BuO)₃), n-butyl(tris(t-butoxy)tin (Sn(n-Bu)(t-BuO)₃), or isopropyltris(t-butoxy)tin (Sn(i-Pr)(t-BuO)₃).

In various embodiments, a precursor includes at least one alkyl group on each metal atom that can survive the vapor-phase reaction, while other ligands or ions coordinated to the metal atom can be replaced by the counter-reactants. Accordingly, another non-limiting precursor includes an organometallic agent having the formula (VII):

MₐR_{b}L_{c} (VII),
in which M is a metal; R is an optionally substituted alkyl; L is a ligand, ion, or other moiety which is reactive with the counter-reactant; a≥1; b≥1; and c≥1. In particular embodiments, a=1, and b+c=4. In some embodiments, M is Sn, Te, Bi, or Sb. In particular embodiments, each L is independently amino (e.g., —NR¹R², in which each of R¹ and R² can be H or alkyl, such as any described herein), alkoxy (e.g., —OR, in which R is alkyl, such as any described herein), or halo (e.g., F, Cl, Br, or I). Exemplary agents include SnMe₃Cl, SnMe₂Cl₂, SnMeCl₃, SnMe(NMe₂)₃, SnMe₂(NMe₂)₂, SnMe₃(NMe₂), and the like.

In other embodiments, the non-limiting precursor includes an organometallic agent having the formula (VIII):

MₐL_{c} (VIII),
in which M is a metal; L is a ligand, ion, or other moiety which is reactive with the counter-reactant; a≥1; and c≥1. In particular embodiments, c=n−1, and n is 2, 3, or 4. In some embodiments, M is Sn, Te, Bi, or Sb. Counter-reactants preferably have the ability to replace the reactive moieties ligands or ions (e.g., L in formulas herein) so as to link at least two metal atoms via chemical bonding.

In any embodiment herein, R can be an optionally substituted alkyl (e.g., C₁₋₁₀ alkyl). In one embodiment, alkyl is substituted with one or more halo (e.g., halo-substituted C₁₋₁₀ alkyl, including one, two, three, four, or more halo, such as F, Cl, Br, or I). Exemplary R substituents include CₙH₂ₙ₊₁, preferably wherein n≥3; and CₙFₓH₍₂ₙ₊₁₋ₓ₎, wherein 1≤x≤2n+1. In various embodiments, R has at least one beta-hydrogen, beta-halogen, or beta-fluorine. For example, R may be selected from the group consisting of i-propyl, n-propyl, t-butyl, i-butyl, n-butyl, sec-butyl, n-pentyl, i-pentyl, t-pentyl, sec-pentyl, and mixtures thereof.

In any embodiment herein, L may be any moiety readily displaced by a counter-reactant to generate an M-OH moiety, such as a moiety selected from the group consisting of an amino (e.g., —NR¹R², in which each of R¹ and R² can be H or alkyl, such as any described herein), alkoxy (e.g., —OR, in which R is alkyl, such as any described herein), carboxylates, halo (e.g., F, Cl, Br, or I), and mixtures thereof.

Counter-reactants preferably have the ability to replace the reactive moieties, ligands, or ions (e.g., L in formulas herein) so as to link at least two metal atoms via chemical bonding. Exemplary counter-reactants include oxygen-containing counter-reactants, such as oxygen (O₂), ozone (O₃), water, peroxides (e.g., hydrogen peroxide), oxygen plasma, water plasma, alcohols, dihydroxy alcohols, polyhydroxy alcohols, fluorinated dihydroxy alcohol, fluorinated polyhydroxy alcohols, fluorinated glycols, formic acid, and other sources of hydroxyl moieties, as well as combinations thereof. In various embodiments, a counter-reactant reacts with the precursor by forming oxygen bridges between neighboring metal atoms. Other potential counter-reactants include hydrogen sulfide and hydrogen disulfide, which can crosslink metal atoms via sulfur bridges and bis(trimethylsilyl)tellurium, which can crosslink metal atoms via tellurium bridges. In addition, hydrogen iodide may be utilized to incorporate iodine into the film.

Yet other non-limiting counter-reactants include a chalcogenide precursor having the formula ZR₂, wherein: Z is sulfur, selenium, or tellurium; and each R is, independently, H, optionally substituted alkyl (e.g., methyl, ethyl, n-propyl, isopropyl, n-butyl, t-butyl, etc.), optionally substituted alkenyl, optionally substituted aryl, optionally substituted amino, optionally substituted alkoxy, or optionally substituted trialkylsilyl.

Exemplary organometallic agents include SnMeCl₃, (N²,N³-di-t-butyl-butane-2,3-diamido) tin(II) (Sn(tbba)), bis(bis(trimethylsilyl)amido) tin(II), tetrakis(dimethylamino) tin(IV) (Sn(NMe₂)₄), t-butyl tris(dimethylamino) tin (Sn(t-butyl)(NMe₂)₃), i-butyl tris(dimethylamino) tin (Sn(i-Bu)(NMe₂)₃), n-butyl tris(dimethylamino) tin (Sn(n-Bu)(NMe₂)₃), sec-butyl tris(dimethylamino) tin (Sn(s-Bu)(NMe₂)₃), i-propyl(tris)dimethylamino tin (Sn(i-Pr)(NMe₂)₃), n-propyl tris(diethylamino) tin (Sn(n-Pr)(NEt₂)₃), and analogous alkyl(tris)(t-butoxy) tin compounds, such as t-butyl tris(t-butoxy) tin (Sn(t-Buxt-BuO)₃). In some embodiments, the organometallic agents are partially fluorinated.

In some embodiments, patterning structure can include a surface layer or film comprising exposed hydroxyl groups or hydroxyl-terminated SnOₓ. Without limiting the mechanism, function or utility of present technology, it is believed that the hydroxyl-terminated SnOₓ layer may offer benefits such as improved adhesion of materials deposited on the surface of the substrate and enhanced absorption of EUV (or other radiation) during patterning. Sensitivity to EUV or other irradiation and resolution may be dependent on the properties of the SnOₓ layer, such as thickness, density and short-range charge transfer characteristics. In various embodiments, the SnOₓ layer has a thickness of from 0.1 nm to 20 nm, or from 0.2 nm to 10 nm, or from 0.5 nm to 5 nm.

In some embodiments, the hydroxyl-terminated SnOₓ layer is deposited on a surface of the substrate by vapor deposition. In such methods, the deposition comprises reacting Sn—Xₙ with an oxygen-containing counter-reactant, wherein X is a ligand such as dialkylamino, (e.g., dimethylamino, methylethylamino, and diethylamino), alcohol (e.g., t-butoxy, and isopropoxy), halogen (e.g., F, Cl, Br, and I), or other organic substituent (e.g., acetylacetone, N2,N3-di-tertbutyl-butane-2,3-diamino). For example, Sn—Xₙ may be SnCl₄, SnI₄, or Sn(NR₂)₄ wherein R is methyl or ethyl, or Sn(t-BuO)₄. In some embodiments, multiple types of ligands are present. The oxygen-containing counter-reactant may be selected from the group consisting of water, hydrogen peroxide, formic acid, alcohols, oxygen, ozone, and combinations thereof.

Suitable vapor deposition processes include chemical vapor deposition (CVD), atomic layer deposition (ALD), plasma-enhanced chemical vapor deposition (PECVD), or plasma-enhanced atomic layer deposition (PEALD). In some embodiments, the deposition is ALD, in a cyclical process of depositing the Sn—Xₙ and depositing the oxygen-containing counter-reactant. In some embodiments, the deposition is CVD, by simultaneously flowing the Sn—Xₙ and the oxygen-containing counter-reactant. Materials and processes among those useful herein for depositing SnOₓ layers are described in Nazarov et al., Atomic Layer Deposition of Tin Dioxide Nanofilms: A Review, 40 Rev. Adv. Mater. Sci. 262 (2015). A SnOₓ substrate may be deposited by a CVD or ALD process, as described herein.

A surface activation operation may be used to activate the surface for future operations. For example, for a SiOx surface, a water or oxygen/hydrogen plasma may be used to create hydroxyl groups on the surface. For a carbon- or hydrocarbon-based surface, a water, hydrogen/oxygen or CO₂ plasma or ozone treatment may be used to create carboxylic acids/or hydroxyl groups. Such approaches can improve adhesion of resist features to the substrate, which might otherwise delaminate or lift off in the solvent used for development.

Adhesion may also be enhanced by inducing roughness in the substrate surface to increase the surface area available for interaction, as well as directly improve mechanical adhesion. For example, first a sputtering process using Ar or other non-reactive ion bombardment can be used to produce rough surfaces. Then, the surface can be terminated with a desired surface functionality as described above (e.g., hydroxyl and/or carboxylic acid groups). On carbon, a combination approach can be employed wherein a chemically reactive oxygen-containing plasma such as CO₂, O₂, H₂O (or mixtures of H₂ and O₂) can be used to etch away a thin layer of film with local non-uniformity and simultaneously terminate with —OH, —OOH, or —COOH groups. This may be done with or without bias. In conjunction with the surface modification strategies mentioned above, this approach could serve the dual purpose of surface roughening and chemical activation of the substrate surface, either for direct adhesion to an inorganic metal-oxide based resist or as an intermediate surface modification for further functionalization.

The patterning structure can include any useful substrate. For instance, an incoming wafer can be prepared with a substrate surface of a desired material, with the uppermost material being the layer into which the resist pattern is transferred. While the material selection may vary depending on integration, it is generally desired to select a material which can be etched with high selectivity to (i.e., much faster than) the EUV resist or resist film. In some embodiments, the substrate is a hardmask, which is used in lithographic etching of an underlying semiconductor material. The hardmask may comprise any of a variety of materials, including amorphous carbon (a-C), tin oxide (e.g., SnOₓ), silicon oxide (e.g., SiOₓ, including SiO₂), silicon oxynitride (e.g., SiOₓN_{y}), silicon oxycarbide (e.g., SiOₓC_{y}), silicon nitride (e.g., Si₃N₄), titanium oxide (e.g., TiO₂), titanium nitride (e.g., TiN), tungsten (e.g., W), doped carbon (e.g., W-doped C), tungsten oxide (e.g., WOₓ), hafnium oxide (e.g., HfO₂), zirconium oxide (e.g., ZrO₂), and aluminum oxide (e.g., Al₂O₃). Suitable substrate materials can include various carbon-based films (e.g., ashable hardmask (AHM), silicon-based films (e.g., SiOₓ, SiCₓ, SiOₓC_{y}, SiOₓN_{y}, SiOₓC_{y}N_{z}), a-Si:H, poly-Si, or SiN), or any other (generally sacrificial) film applied to facilitate the patterning process). For example, the substrate may preferably comprise SnOx, such as SnO₂. In various embodiments, the layer may be from 1 nm to 100 nm thick, or from 2 nm to 10 nm thick.

In cases where there are device features present on the substrate to be patterned which create significant topography, another important function of an underlayer can be to overcoat and planarize the existing topography so that the subsequent patterning step may be performed on a flat surface with all areas of the pattern in focus. For such applications, the underlayer (or at least one of multiple underlayers) is generally applied using spin-coating techniques. When the photoresist material being employed possesses a significant inorganic component, for example it exhibits a predominately metal oxide framework, the underlayer may advantageously be a carbon-based film, applied either by spin-coating or by dry vacuum-based deposition processes. The layer may include various AHM films with carbon- and hydrogen-based compositions, and may be doped with additional elements such as tungsten, boron, nitrogen, or fluorine.

In various embodiments, the surface (e.g., of the substrate and/or the film) comprises exposed hydroxyl groups on its surface. In general, the surface may be any surface that comprises, or has been treated to produce, an exposed hydroxyl surface. Such hydroxyl groups may be formed on the surface by surface treatment of a substrate using oxygen plasma, water plasma, or ozone. In other embodiments, the surface of the film can be treated to provide exposed hydroxyl groups, upon which a capping layer can be applied. In various embodiments, the hydroxyl-terminated metal oxide layer has a thickness of from 0.1 nm to 20 nm, or from 0.2 nm to 10 nm, or from 0.5 nm to 5 nm.

The implementations disclosed herein describe deposition of a material on a substrate such as a wafer, substrate, or other work piece. The work piece may be of various shapes, sizes, and materials. In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry has a diameter of about 200 mm, or 300 mm, or 450 mm. Unless otherwise stated, the processing details recited herein (e.g., flow rates, power levels, etc.) are relevant for processing 300 mm diameter substrates, or for treating chambers that are configured to process 300 mm diameter substrates, and can be scaled as appropriate for substrates or chambers of other sizes. In addition to semiconductor wafers, other work pieces that may be used implementations disclosed herein include various articles such as printed circuit boards and the like. The processes and apparatuses can be used in the fabrication of semiconductor devices, displays, and the like.

### Lithographic Processes

Patterning of thin films in semiconductor processing is often one step in the fabrication of semiconductors. Patterning involves lithography. In photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a via or line in a Damascene structure is no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with photolithography methods. EUV light sources at approximately 10-20 nm, or 11-14 nm wavelength, for example 13.5 nm wavelength, can be used for leading-edge lithography tools, also referred to as scanners. The EUV radiation is strongly absorbed in a wide range of solid and fluid materials including quartz and water vapor, and so operates in a vacuum.

Traditional organic chemically amplified resists (CAR) have a few drawbacks when used in EUV lithography, particularly low absorption coefficient in EUV region and acid diffusion of photo-activated chemical species. To overcome the low absorption coefficient, a relatively thick CAR film is necessary, but at the risk of pattern collapse. Moreover, the broad clearing radius during the acid diffusion process leads to relatively high line roughness in patterned CAR films. Quenchers may be used to reduce the acid diffusion radius, but at the cost of decreased sensitivity. As such, the lithographic performance of current CARs is generally unable to reach the desired EUV lithographic performance.

Directly photopatternable EUV resists containing metals and/or metal oxides mixed within organic components show promise in that they can enhance the EUV photon absorption and generate secondary electrons and/or show increased etch selectivity to an underlying film stack and device layers. Spin-on organometallic resists, such as are available from Inpria Corp., Corvallis, OR, have a substantially higher absorption coefficient than CARs and can be significantly thinner while still providing good etch resistance. Spin-on formulations generally result in spatially homogenous films.

Dry deposition of metal-organic based photopatternable EUV resists has also been described, for example in our prior International Application PCT/US19/31618, published as International Pub. No. WO2019/217749, filed May 9, 2019, and titled METHODS FOR MAKING EUV PATTERNABLE HARD MASKS, the disclosure of which relating to the composition, dry deposition, and patterning of directly photopatternable metal-organic based metal oxide films to form EUV resist masks is incorporated by reference herein.

In most or all of these metal-organic based resists, other than the metal center, all other elements have low EUV absorption cross-section. The introduction of other, highly-EUV-absorbing, elements into the resist either as an alternative metal center or as part of the counter-reactant or by substitution of fluorine or iodine for hydrogen on the organic groups that can further increase the EUV absorption in the PR and thus further reduce the EUV dosage required for patterning, and our prior work has explored these possibilities.

Further improvement in EUV lithographic organometallic resist performance is contemplated by increasing the sensitivity, reducing the line edge roughness, and/or improving the resolution, captured in a term referenced herein as “z-factor”. The present disclosure addresses the underlayer of the organometallic resist film, outlining methods to improve the sensitivity of these resists through the incorporation of elements with high EUV absorption under the photoactive layer of the film to increase the EUV absorptivity and patterning performance of EUV photoresists. Described compositions, structures, and methods may be applicable to both dry deposited organometallic photoresist strategies as well as CARs and spin-on metalorganic films.

EUV lithography makes use of EUV resists, which may be polymer-based chemically amplified resists produced by liquid-based spin-on techniques or metal oxide-based resists produced by dry vapor-deposited techniques. Such EUV resists can include any EUV-sensitive film or material described herein. Lithographic methods can include patterning the resist, e.g., by exposure of the EUV resist with EUV radiation to form a photo pattern, followed by developing the pattern by removing a portion of the resist according to the photo pattern to form a mask.

It should also be understood that while the present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. Such methods include those where a substrate (e.g., optionally having exposed hydroxyl groups) is contacted with a precursor (e.g., any described herein) to form a metal oxide (e.g., a layer including a network of metal oxide bonds, which may include other non-metal and non-oxygen groups) film as the imaging/PR layer on the surface of the substrate. The specific methods may depend on the particular materials and applications used in the semiconductor substrate and ultimate semiconducting device. Thus, the methods described in this application are merely exemplary of the methods and materials that may be used in present technology. In some embodiments, lithography includes use of a radiation source having a wavelength that is between 10 nm and 400 nm.

Directly photopatternable EUV resists may be composed of or contain metals and/or metal oxides. The metals/metal oxides are highly promising in that they can enhance the EUV photon absorption and generate secondary electrons and/or show increased etch selectivity to an underlying film stack and device layers. Additional processes employed during lithography are described in detail below.

### Deposition Processes, Including Dry or Wet Deposition

As discussed above, the present disclosure provides methods for films on semiconductor substrates, which may be patterned using EUV or other next generation lithographic techniques. Methods include those where polymerized organometallic materials are produced in a vapor and deposited on a substrate. In some embodiments, dry deposition can employ any useful precursor (e.g., metal halides, capping agents, or organometallic agents described herein). In other embodiments, a spin-on formulation may be used. Deposition processes can include applying a EUV-sensitive material as a resist film or an EUV-sensitive film.

Such EUV-sensitive films comprise materials which, upon exposure to EUV, undergo changes, such as the loss of bulky pendant ligands bonded to metal atoms. If the exposed region can be further treated to provide a dense M-O-M rich material, then EUV-induced cleavage can provide intermediates that are retained by use of negative tone developers.

Through EUV patterning, areas of the film are created that have altered physical or chemical properties relative to unexposed regions. These properties may be exploited in subsequent processing, such as to dissolve either unexposed or exposed regions or to selectively deposit materials on either the exposed or unexposed regions. In some embodiments, the unexposed film has a hydrophobic surface, and the exposed film has a hydrophilic surface (it being recognized that the hydrophilic properties of exposed and unexposed regions are relative to one another) under the conditions at which such subsequent processing is performed. For example, the removal of material may be performed by leveraging differences in chemical composition, density, and cross-linking of the film. Removal may be by wet processing or dry processing, as further described herein.

The thickness of the EUV-patternable film formed on the surface of the substrate may vary according to the surface characteristics, materials used, and processing conditions. In various embodiments, the film thickness may range from about 0.5 nm to about 100 nm. Preferably, the film has a sufficient thickness to absorb most of the EUV light under the conditions of EUV patterning. For example, the overall absorption of the resist film may be 70% or less (e.g., 60% or less, 50% or less, 40% or less, 30% or less, 20% or less, 10% or less, or 5% or less), so that the resist material at the bottom of the resist film is sufficiently exposed. In some embodiments, the film thickness is from 10 nm to 20 nm. Without limiting the mechanism, function, or utility of the present disclosure, it is believed that the processes of the present disclosure have beneficial surface adhesion properties of the substrate and can be applied to a wide variety of substrates. Moreover, as discussed herein, the deposited films may closely conform to surface features, providing advantages in forming masks over substrates, such as substrates having underlying features, without “filling in” or otherwise planarizing such features.

The film may be composed of a metal oxide layer deposited in any useful manner. Such a metal oxide layer can be deposited or applied by using any EUV-sensitive material described herein, such as a precursor (e.g., metal-containing precursor, a metal halide, a capping agent, or an organometallic agent) in combination with a counter-reactant. In exemplary processes, a polymerized organometallic material is formed in vapor phase or in situ on the surface of the substrate in order to provide the metal oxide layer. The metal oxide layer may be employed as a film, an adhesion layer, or a capping layer.

Optionally, the metal oxide layer can include a hydroxyl-terminated metal oxide layer, which can be deposited by employing a capping agent (e.g., any described herein) with an oxygen-containing counter-reactant. Such a hydroxyl-terminated metal oxide layer can be employed, e.g., as an adhesion layer between two other layers, such as between the substrate and the film and/or between the photoresist layer and the capping layer.

Exemplary deposition techniques (e.g., for a film) include any described herein, such as ALD (e.g., thermal ALD and plasma-enhanced ALD), spin-coat deposition, PVD including PVD co-sputtering, CVD (e.g., PE-CVD or LP-CVD), sputter deposition, e-beam deposition including e-beam co-evaporation, etc., or a combination thereof, such as ALD with a CVD component, such as a discontinuous, ALD-like process in which precursors and counter-reactants are separated in either time or space.

Further description of precursors and methods for their deposition as EUV photoresist films applicable to this disclosure may be found in International Appl. No. PCT/US19/31618, published as International Pub. No. WO2019/217749, filed May 9, 2019, and titled METHODS FOR MAKING EUV PATTERNABLE HARD MASKS. The thin films may include optional materials in addition to a precursor and a counter-reactant to modify the chemical or physical properties of the film, such as to modify the sensitivity of the film to EUV or enhancing etch resistance. Such optional materials may be introduced, such as by doping during vapor phase formation prior to deposition on the substrate, during deposition on the substrate, and/or after deposition of the film. In some embodiments, a gentle remote H₂ plasma may be introduced so as to replace some Sn-L bonds with Sn—H, for example, which can increase reactivity of the resist under EUV. In other embodiments, CO₂ may be introduced to replace some Sn—O bonds with Sn—CO₃ bonds, which can be more resistant to dry or wet development.

In general, methods can include mixing a vapor stream of a precursor (e.g., a metal-containing precursor, such as an organometallic agent) with an optional vapor stream of a counter-reactant so as to form a polymerized organometallic material, and depositing the organometallic material onto the surface of the semiconductor substrate. In some embodiments, mixing the precursor and optional counter-reactant can form a polymerized organometallic material. As will be understood by one of ordinary skill in the art, the mixing and depositing aspects of the process may be concurrent, in a substantially continuous process.

In an exemplary continuous CVD process, two or more gas streams, in separate inlet paths, of sources of precursor and optional counter-reactant are introduced to the deposition chamber of a CVD apparatus, where they mix and react in the gas phase, to form agglomerated polymeric materials (e.g., via metal-oxygen-metal bond formation) or a film on the substrate. Gas streams may be introduced, for example, using separate injection inlets or a dual-plenum showerhead. The apparatus is configured so that the streams of precursor and optional counter-reactant are mixed in the chamber, allowing the precursor and optional counter-reactant to react to form a polymerized organometallic material or a film (e.g., a metal oxide coating or agglomerated polymeric materials, such as via metal-oxygen-metal bond formation).

For depositing metal oxide, the CVD process is generally conducted at reduced pressures, such as from 0.1 Torr to 10 Torr. In some embodiments, the process is conducted at pressures from 1 Torr to 2 Torr. The temperature of the substrate is preferably below the temperature of the reactant streams. For example, the substrate temperature may be from 0° C. to 250° C., or from ambient temperature (e.g., 23° C.) to 150° C.

For depositing agglomerated polymeric materials, the CVD process is generally conducted at reduced pressures, such as from 10 mTorr to 10 Torr. In some embodiments, the process is conducted at from 0.5 to 2 Torr. The temperature of the substrate is preferably at or below the temperature of the reactant streams. For example, the substrate temperature may be from 0° C. to 250° C., or from ambient temperature (e.g., 23° C.) to 150° C. In various processes, deposition of the polymerized organometallic material on the substrate occurs at rates inversely proportional to surface temperature. Without limiting the mechanism, function or utility of present technology, it is believed that the product from such vapor-phase reaction becomes heavier in molecular weight as metal atoms are crosslinked by counter-reactants, and is then condensed or otherwise deposited onto the substrate. In various embodiments, the steric hindrance of the bulky alkyl groups further prevents the formation of densely packed network and produces low density films having increased porosity.

Using dry deposition methods, the composition of the film can be tuned as it grows. In a CVD process, this may be accomplished by changing the relative flows of a first precursor and a second precursor during deposition. Deposition may occur between 30° C. and 200° C. at pressures between 0.01 Torr to 100 Torr, but more generally between about 0.1 Torr and 10 Torr.

A film (e.g., a metal oxide coating or agglomerated polymeric materials, such as via metal-oxygen-metal bond formation) may also be deposited by an ALD process. For example, the precursor(s) and optional counter-reactant are introduced at separate times, representing an ALD cycle. The precursors react on the surface, forming up to a monolayer of material at a time for each cycle. This may allow for excellent control over the uniformity of film thickness across the surface. The ALD process is generally conducted at reduced pressures, such as from 0.1 Torr to 10 Torr. In some embodiments, the process is conducted from 1 Torr to 2 Torr. The substrate temperature may be from 0° C. to 250° C., or from ambient temperature (e.g., 23° C.) to 150° C. The process may be a thermal process or, preferably, a plasma-assisted deposition.

Any of the deposition methods herein can be modified to allow for use of two or more different precursors. In one embodiment, the precursors can include the same metal but different ligands. In another embodiment, the precursors can include different metal groups. In one non-limiting instance, alternating flows of various volatile precursors can provide a mixed metal-containing layer, such as use of a metal alkoxide precursor having a first metal (e.g., Sn) with a silyl-based precursor having a different second metal (e.g., Te).

Processes herein can be used to achieve a surface modification. In some iterations, a vapor of the precursor may be passed over the wafer. The wafer may be heated to provide thermal energy for the reaction to proceed. In some iterations, the heating can be between about 50° C. to about 250° C. In some cases, pulses of the precursor may be used, separated by pump and/or purging steps. For instance, a first precursor may be pulsed between pulses of a second precursor pulses resulting in ALD or ALD-like growth. In other cases, both precursors may be flowed at the same time. Examples of elements useful for surface modification include I, F, Sn, Bi, Sb, Te, and oxides or alloys of these compounds.

The processes herein can be used to deposit a thin metal oxide or metal by ALD or CVD. Examples include tin oxide (SnOx), bismuth oxide (BiOx), and Te. Following deposition, the film may be capped with an alkyl substituted precursor of the form MₐR_{b}L_{c}, as described elsewhere herein. A counter-reactant may be used to better remove the ligands, and multiple cycles may be repeated to ensure complete saturation of the substrate surface. The surface can then ready for the EUV-sensitive film to be deposited. One possible method is to produce a thin film of SnOx. Possible chemistries include growth of SnO₂ by cycling tetrakis(dimethylamino)tin and a counter-reactant such as water or O₂ plasma. After the growth, a capping agent could be used. For example, isopropyltris(dimethylamino)tin vapor may be flown over the surface.

Deposition processes can be employed on any useful surface. As referred to herein, the “surface” is a surface onto which a film of the present technology is to be deposited or that is to be exposed to EUV during processing. Such a surface can be present on a substrate (e.g., upon which a film is to be deposited) or on a film (e.g., upon which a capping layer can be deposited).

Any useful substrate can be employed, including any material construct suitable for lithographic processing, particularly for the production of integrated circuits and other semiconducting devices. In some embodiments, substrates are silicon wafers. Substrates may be silicon wafers upon which features have been created (“underlying topographical features”), having an irregular surface topography.

Such underlying topographical features may include regions in which material has been removed (e.g., by etching) or regions in which materials have been added (e.g., by deposition) during processing prior to conducting a method of this technology. Such prior processing may include methods of this technology or other processing methods in an iterative process by which two or more layers of features are formed on the substrate. Without limiting the mechanism, function, or utility of the present technology, it is believed that, in some embodiments, methods of the present technology offer advantages relative to methods among those known in the art in which photolithographic films are deposited on the surface of substrates using spin casting methods. Such advantages may derive from the conformance of the films of the present technology to underlying features without “filling in” or otherwise planarizing such features, and the ability to deposit films on a wide variety of material surfaces.

In some embodiments, the substrate is a hard mask, which is used in lithographic etching of an underlying semiconductor material. The hard mask may comprise any of a variety of materials, including amorphous carbon (a-C), tin oxide (e.g., SnOₓ), silicon oxide (e.g., SiO₂), silicon oxynitride (e.g., SiOₓN_{y}), silicon oxycarbide (e.g., SiOₓC_{y}), silicon nitride (e.g., Si₃N₄), titanium oxide (e.g., TiO₂), titanium nitride (e.g., TiN), tungsten (e.g., W), doped carbon (e.g., W-doped C), tungsten oxide (e.g., WOₓ), hafnium oxide (e.g., HfO₂), zirconium oxide (e.g., ZrO₂), and aluminum oxide (e.g., Al₂O₃). For example, the substrate may preferably comprise SnOₓ, such as SnO₂. In various embodiments, the layer may be from 1 nm to 100 nm thick, or from 2 nm to 10 nm thick.

In some non-limiting embodiments, a substrate comprises an underlayer. An underlayer may be deposited on a hard mask or other layer and is generally underneath a resist film (or imaging layer), as described herein. An underlayer may be used to improve the sensitivity of a PR, increase EUV absorptivity, and/or increase the patterning performance of the PR. In cases where there are device features present on the substrate to be patterned which create significant topography, another important function of the underlayer can be to overcoat and planarize the existing topography so that the subsequent patterning step may be performed on a flat surface with all areas of the pattern in focus. For such applications, the underlayer (or at least one of multiple underlayers) may be applied using spin-coating techniques. When the PR material being employed possesses a significant inorganic component, for example it exhibits a predominately metal oxide framework, the underlayer may advantageously be a carbon-based film, applied either by spin-coating or by dry vacuum-based deposition processes. The layer may include various ashable hard mask (AHM) films with carbon- and hydrogen-based compositions and may be doped with additional elements, such as tungsten, boron, nitrogen, or fluorine.

In various embodiments, the surface (e.g., of the substrate and/or the film) comprises exposed hydroxyl groups on its surface. In general, the surface may be any surface that comprises, or has been treated to produce, an exposed hydroxyl surface. Such hydroxyl groups may be formed on the surface by surface treatment of a substrate using oxygen plasma, water plasma, or ozone. In other embodiments, the surface of the film can be treated to provide exposed hydroxyl groups, upon which a capping layer can be applied. In various embodiments, the hydroxyl-terminated metal oxide layer has a thickness of from 0.1 nm to 20 nm, or from 0.2 nm to 10 nm, or from 0.5 nm to 5 nm.

### EUV Exposure Processes

EUV exposure of the film can provide EUV exposed regions having activated reactive centers including a metal atom (M), which are produced by EUV-mediated cleavage events. Such reactive centers can include dangling metal bonds, M-H groups, cleaved M-ligand groups, dimerized M-M bonds, or M-O-M bridges.

EUV exposure can have a wavelength in the range of about 10 nm to about 20 nm in a vacuum ambient, such as a wavelength of from 10 nm to 15 nm, e.g., 13.5 nm. In particular, patterning can provide EUV exposed regions and EUV unexposed regions to form a pattern.

The present technology can include patterning using EUV, as well as DUV or e-beam. In such patterning, the radiation is focused on one or more regions of the resist film. The exposure can be performed such that resist film comprises one or more regions that are not exposed to the radiation. The resulting resist film may comprise a plurality of exposed and unexposed regions, creating a pattern consistent with the creation of transistor or other features of a semiconductor device, formed by addition or removal of material from the substrate in subsequent processing of the substrate. EUV, DUV and e-beam radiation methods and equipment among useful herein include methods and equipment known in the art.

In some EUV lithography techniques, an organic hard mask (e.g., an ashable hard mask of PECVD amorphous hydrogenated carbon) is patterned using a photoresist process. During photoresist exposure, EUV radiation is absorbed in the resist and in the substrate below, producing highly energetic photoelectrons (e.g., about 100 eV) and in turn a cascade of low-energy secondary electrons (e.g., about 10 eV) that diffuse laterally by several nanometers. These electrons increase the extent of chemical reactions in the resist which increases its EUV dose sensitivity. However, a secondary electron pattern that is random in nature is superimposed on the optical image. This unwanted secondary electron exposure results in loss of resolution, observable line edge roughness (LER) and linewidth variation in the patterned resist. These defects are replicated in the material to be patterned during subsequent pattern transfer etching.

A vacuum-integrated metal hard mask process and related vacuum-integrated hardware that combines film formation (deposition/condensation) and optical lithography with the result of greatly improved EUV lithography (EUVL) performance—e.g. reduced line edge roughness—is disclosed herein.

In various embodiments described herein, a deposition (e.g., condensation) process (e.g., ALD or MOCVD carried out in a PECVD tool, such as the Lam Vector®) can be used to form a thin film of a metal-containing film, such a photosensitive metal salt or metal-containing organic compound (organometallic compound), with a strong absorption in the EUV (e.g., at wavelengths on the order of 10 nm to 20 nm), for example at the wavelength of the EUVL light source (e.g., 13.5 nm=91.8 eV). This film photo-decomposes upon EUV exposure and forms a metal mask that is the pattern transfer layer during subsequent etching (e.g., in a conductor etch tool, such as the Lam 2300® Kiyo®).

Following deposition, the EUV-patternable thin film is patterned by exposure to a beam of EUV light, optionally under relatively high vacuum. For EUV exposure, the metal-containing film can then be deposited in a chamber integrated with a lithography platform (e.g., a wafer stepper such as the TWINSCAN NXE: 3300B® platform supplied by ASML of Veldhoven, NL) and transferred under vacuum so as not to react before exposure. Integration with the lithography tool is facilitated by the fact that EUVL also requires a greatly reduced pressure given the strong optical absorption of the incident photons by ambient gases such as H₂O, O₂, etc. In other embodiments, the photosensitive metal film deposition and EUV exposure may be conducted in the same chamber.

### Development Processes, Including Wet or Dry Development

EUV exposed or unexposed areas, as well as absorber layers, can be removed by any useful development process. In one embodiment, the EUV exposed region can have activated reactive centers, such as dangling metal bonds, M-H groups, or dimerized M-M bonds. Such reactive centers can further react to form a densified region within the EUV exposed region. In some embodiments, EUV exposed regions are retained, and EUV unexposed regions are moved by use of dry or wet development.

In particular embodiments, M-H groups can be selectively removed by employing one or more dry development processes (e.g., halide chemistry). In other embodiments, M-M bonds can be selectively removed by employing a development process, e.g., use of hot ethanol and water to provide soluble M(OH)n groups. In yet other embodiments, EUV exposed regions are removed by use of development (e.g., by using a positive tone developer). In some embodiments, EUV unexposed regions are removed by use of dry development.

As described herein, dry development processes can be used to process a film (e.g., in which dry development can be used alone, before wet development, after wet development, before wet treatment, or before dry treatment). Non-limiting dry development processes can include use of halides, such as HCl— or HBr-based processes. While this disclosure is not limited to any particular theory or mechanism of operation, the approach is understood to leverage the chemical reactivity of the dry-deposited EUV photoresist films with the clean chemistry (e.g., HCl, HBr, and BCl₃) to form volatile products using vapors or plasma. Such volatile products can be removed in any manner (e.g., by treating with an aqueous acid, as described herein). The dry-deposited EUV photoresist films can be removed with etch rates of up to 1 nm/s. The quick removal of dry-deposited EUV photoresist films by these chemistries is applicable to chamber cleaning, backside clean, bevel clean, and PR developing. Although the films can be removed using vapors at various temperatures (e.g., HCl or HBr at a temperature greater than −10° C., or BCl₃ at a temperature greater than 80° C., for example), a plasma can also be used to further accelerate or enhance the reactivity.

Plasma processes include transformer coupled plasma (TCP), inductively coupled plasma (ICP) or capacitively coupled plasma (CCP), employing equipment and techniques among those known in the art. For example, a process may be conducted at a pressure of >0.5 mTorr (e.g., such as from 1 mTorr to 100 mTorr), at a power level of <1000 W (e.g., <500 W). Temperatures may be from 30° C. to 300° C. (e.g., 30° C. to 120° C.), at flow rate of 100 to 1000 standard cubic centimeters per minute (sccm), e.g., about 500 sccm, for from 1 to 3000 seconds (e.g., 10 seconds to 600 seconds).

Where the halide reactant flows are of hydrogen gas and halide gas, a remote plasma/UV radiation is used to generate radicals from the H₂ and Cl₂ and/or Br₂, and the hydrogen and halide radicals are flowed to the reaction chamber to contact the patterned EUV photoresist on the substrate layer of the wafer. Suitable plasma power may range from 100 W to 500 W, with no bias. It should be understood that while these conditions are suitable for some processing reactors, e.g., a Kiyo etch tool available from Lam Research Corporation, Fremont, CA, a wider range of process conditions may be used according to the capabilities of the processing reactor.

In thermal development processes, the substrate is exposed to dry development chemistry (e.g., a Lewis Acid) in a vacuum chamber (e.g., oven). Suitable chambers can include a vacuum line, a dry development hydrogen halide chemistry gas (e.g., HBr, HCl) line, and heaters for temperature control. In some embodiments, the chamber interior can be coated with corrosion resistant films, such as organic polymers or inorganic coatings. One such coating is polytetrafluoroethylene ((PTFE), e.g., Teflon™). Such materials can be used in thermal processes of this disclosure without risk of removal by plasma exposure.

The process conditions for the dry development may be reactant flow of 100 sccm to 500 sccm (e.g., 500 sccm HBr or HCl), temperature of −10° C. to 120° C. (e.g., −10° C.), pressure of 1 mTorr to 500 mTorr (e.g., 300 mTorr) with no plasma and for a time of about 10 sec to 1 min, dependent on the photoresist film and their composition and properties.

In various embodiments, methods of the present disclosure combine all dry steps of film deposition, formation by vapor deposition, (EUV) lithographic photopatterning, and dry development. In such processes, a substrate may directly go to a dry development/etch chamber following photopatterning in an EUV scanner. Optionally, dry treatment with an acidic vapor is performed after dry development. In other embodiments, wet treatment with an acidic solution is performed after dry development.

In other embodiments, methods of the present disclosure combine all dry steps of film deposition, formation by vapor deposition and (EUV) lithographic photopatterning, but which is followed by wet development. Optionally, dry treatment with an acidic vapor is performed after wet development. In other embodiments, wet treatment with an acidic solution is performed after wet development.

In various embodiments, the EUV photoresist, containing some amount of metal, metal oxide and organic components, can be dry developed by a thermal, plasma (e.g., including possibly photoactivated plasma, such as lamp-heated or UV lamp heated), or a mixture of thermal and plasma methods while flowing a dry development gas including a compound of formula RₓZ_{y}, where R═B, Al, Si, C, S, SO with x>0 and Z═Cl, H, Br, F, CH₄ and y>0. The dry development can result in a positive tone, in which the RₓZ_{y} species selectively removes the exposed material, leaving behind the unexposed counterpart as a mask. In some embodiments, the exposed portions of organotin oxide-based photoresist films are removed by dry development in accordance with this disclosure. Positive tone dry development may be achieved by the selective dry development (removal) of EUV exposed regions exposed to flows comprising hydrogen halides or hydrogen and halides, including HCl and/or HBr without striking a plasma, or flows of H₂ and Cl₂ and/or Br₂ with a remote plasma or UV radiation generated from plasma to generate radicals.

Wet development methods can also be employed. In particular embodiments, such wet developments methods are used to remove EUV exposed regions to provide a negative tone resist or a positive tone resist. Exemplary, non-limiting wet development can include use of an developer (e.g., an aqueous acidic developer, non-aqueous acidic developer, or an acid developer in an organic solvent) that includes a halide (e.g., HF, HCl, or HBr), an organic acid (e.g., formic acid, acetic acid, oxalic acid, or citric acid), or an organohalide compound (e.g., such as an organofluorine compound, including trifluoroacetic acid; an organochlorine compound; an organobromine compound, or an organoiodine compound); or use of an organic developer, such as an alcohol (e.g., isopropyl alcohol (IPA)), a ketone (e.g., 2-heptanone, cyclohexanone, or acetone), an ether, such as a glycol ether (e.g., propylene glycol methyl ether (PGME) or propylene glycol methyl ether acetate (PGMEA)), or an ester (e.g., γ-butyrolactone or ethyl 3-ethoxypropionate (EEP)), as well as combinations thereof. Other acids (e.g., aqueous acids) are described herein. Non-limiting combinations include water with an acidic developer.

In some embodiments, wet development includes a neutral developer (e.g., a pH neutral developer, such as water) or a peroxide-containing developer (e.g., including hydrogen peroxide, H₂O₂).

Other development methodologies can include use of an aqueous developer, a non-aqueous developer, an alkaline developer (e.g., an aqueous alkaline developer or a non-aqueous alkaline developer), such as those including ammonium, e.g., ammonium hydroxide ([NH₄]⁺[OH]⁻); ammonium-based ionic liquids, e.g., tetramethylammonium hydroxide (TMAH), tetraethylammonium hydroxide (TEAH), tetrapropylammonium hydroxide (TPAH), tetrabutylammonium hydroxide (TBAH), or other quaternary alkylammonium hydroxides; an organoamine, such as mono-, di-, and tri-organoamines (e.g., dimethylamine, diethylamine, ethylenediamine, triethylenetetramine); or an alkanolamine, such as monoethanolamine, diethanolamine, triethanolamine, or diethyleneglycolamine. In other embodiments, the alkaline developer can include nitrogen-containing bases, e.g., compounds having the formula R^{N1}NH₂, R^{N1}R^{N2}NH, R^{N1}R^{N2}R^{N3}N, or R^{N1}R^{N2}R^{N3}R^{N4}N⁺X^{N1-}, where each of R^{N1}, R^{N2}, R^{N3}, and R^{N4} is, independently, an organo substituent (e.g., optionally substituted alkyl, optionally substituted hydroxyalkyl, or any described herein), or two or more organo substituents that can be joined together, and X^{N1-} may comprise OH⁻, F⁻, Cl⁻, Br⁻, I⁻, or other art-known quaternary ammonium cationic species. These bases may also comprise heterocyclyl nitrogen compounds known in the art, some of which are described herein. Non-limiting combinations include water with a basic developer.

Yet other development methodologies can include use of a deprotecting solvent. Non-limiting deprotecting solvents include an organic acid (e.g., any herein, such as oxalic acid) or include choline ([N(CH₃)₃CH₂CH₂OH]⁺), such as choline hydroxide ([N(CH₃)₃CH₂CH₂OH]⁺ [OH]⁻).

The developer can be used in any useful concentration. In one embodiment, the developer solution includes about 0.5 wt. % to about 30 wt. % of the developer(s) in a solvent (e.g., an aqueous solvent, a non-aqueous solvent, an organic solvent, or a combination thereof), including concentrations from about 1 wt. % to about 20 wt. % and 1.1 wt. % to 10 wt. %.

The developer can be used with one or more additives, such as oxidizers, surfactants, salts, and chelating agents. Additives can be optionally present in an amount of less than 10 wt. % or less than 5 wt. % in a developing solution. Non-limiting oxidizers include a peroxide or a peracid, such as hydrogen peroxide, benzoyl peroxide, urea peroxide, or mixtures thereof.

Any of the developers herein can include one or more surfactants. Surfactant can include a positive, negative, or neutral charge and may be selected from the group consisting of fluorinated or non-fluorinated surfactants. Non-limiting surfactants include anionic, cationic, and non-ionic surfactants, such as an alkylphenol ethoxylate (e.g., Triton™ X-100 (polyethylene glycol tert-octylphenyl ether), an octyl phenol ethoxylate, or a nonyl phenol ethoxylate), an alcohol ethoxylate (e.g., BRIJ® 56 (C₁₆H₃₃(OCH₂CH₂)₁₀OH), BRIJ® 58 (C₁₆H₃₃(OCH₂CH₂)₂₀OH), or a fatty alcohol ethoxylate), a fatty acid ethoxylate, a poloxamer, a fatty acid ester of glycerol, an acetylenic diol, an amine ethoxylate, a glucoside, a glucamide, a polyethylene glycol, or poly(ethylene glycol-co-propylene glycol), an ammonium perfluoroalkyl (e.g., ammonium perfluoroalkyl sulfonate or carboxylate), and combinations thereof.

Non-limiting salts include cation(s) selected from the group of ammonium, d-block metal cations (hafnium, zirconium, lanthanum, or the like), f-block metal cations (cerium, lutetium or the like), p-block metal cations (aluminum, tin, or the like), alkali metals (lithium, sodium, potassium or the like), and combinations thereof; and anion(s) selected from the group of fluoride, chloride, bromide, iodide, nitrate, sulfate, phosphate, silicate, borate, peroxide, butoxide, formate, oxalate, ethylenediamine-tetraacetic acid (EDTA), tungstate, molybdate, or the like and combinations thereof. Non-limiting chelating agents can include polyamines, alcohol amines, amino acids, carboxylic acids, or combinations thereof.

In particular embodiments, a positive tone developer is an acidic developer in an aqueous solvent; an acidic developer in an organic solvent; an aqueous alkaline developer (e.g., including NH₄OH, TMAH, TEAH, TPAH, or TBAH, which can be with or without H₂O₂); an aqueous acidic developer (e.g., including HCl or HF); an organic developer; or a deprotecting solvent (e.g., including oxalic acid, choline, or choline hydroxide). A developer can include one solvent or a solvent combination.

Wet development can include any useful process, including immersion development, puddle development, and spray development. After or during any of these processes, the substrate can be rotated to remove dissolved portions of the film while simultaneously drying the film.

The development process can include both wet and dry development processes. Such a process can include an initial wet development followed by a later dry development, or vice versa. Development can also occur in cycles, in which a plurality of wet development processes are used, a plurality of dry development processes are used, or a plurality of wet and dry development processes are employed.

### Other Processes

The methods herein can include any other useful processes, as described below.

For the backside and bevel clean process, the vapor and/or the plasma can be limited to a specific region of the wafer to ensure that only the backside and the bevel are removed, without any film degradation on the frontside of the wafer. The EUV photoresist films being removed are generally composed of Sn, O and C, but the same clean approaches can be extended to films of other metal oxide resists and materials. In addition, this approach can also be used for film strip and PR rework.

Suitable process conditions for a dry bevel edge and backside clean may be a reactant flow of 100 sccm to 500 sccm (e.g., 500 sccm HCl, HBr, or H₂ and Cl₂ or Br₂, BCl₃ or H₂), temperature of −10° C. to 120° C. (e.g., 20° C.), pressure of 20 mTorr to 500 mTorr (e.g., 300 mTorr), plasma power of 0 to 500 W at high frequency (e.g., 13.56 MHz), and for a time of about 10 sec to 20 sec, dependent on the photoresist film and composition and properties. It should be understood that while these conditions are suitable for some processing reactors, e.g., a Kiyo etch tool available from Lam Research Corporation, Fremont, CA, a wider range of process conditions may be used according to the capabilities of the processing reactor.

Photolithography processes can involve one or more bake steps, to facilitate the chemical reactions required to produce chemical contrast between exposed and unexposed regions of the photoresist. For high volume manufacturing (HVM), such bake steps can be performed on tracks where the wafers are baked on a hot-plate at a pre-set temperature under ambient air or in some cases N₂ flow. More careful control of the bake ambient as well as introduction of additional reactive gas component in the ambient during these bake steps can help further reduce the dose requirement and/or improve pattern fidelity.

According to various aspects of this disclosure, one or more post-treatments to metal and/or metal oxide-based photoresists after deposition (e.g., post-application bake (PAB) or another post-application treatment) and/or exposure (e.g., post-exposure bake (PEB), which can be omitted; or another post-exposure treatment) and/or development (e.g., post-development bake (PDB) or another post-development treatment) are capable of increasing material property differences between exposed and unexposed photoresist and therefore decreasing dose to size (DtS), improving PR profile, and improving line edge and width roughness (LER/LWR) after subsequent dry development. Such processing can involve a thermal process with the control of temperature, gas ambient, and moisture, resulting in improved dry development performance in processing to follow. In some instances, a remote plasma might be used. Yet in certain instances, PAB and/or PEB and/or PDB are not performed.

In the case of post-application processing (e.g., PAB), a thermal process with control of temperature (e.g., with heating or cooling), gas ambient (e.g., air, H₂O, CO₂, CO, O₂, O₃, CH₄, CH₃OH, N₂, H₂, NH₃, N₂O, NO, Ar, He, or their mixtures) or under vacuum, and moisture can be used after deposition and before exposure to change the composition of unexposed metal and/or metal oxide photoresist. The change can increase the EUV sensitivity of the material and thus lower dose to size and edge roughness can be achieved after exposure and dry development.

In the case of post-exposure processing (e.g., PEB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum, and moisture can be used to change the composition of both unexposed and exposed photoresist. The change can increase the composition/material properties difference between the unexposed and exposed photoresist and the etch rate difference of dry development etch gas between the unexposed and exposed photoresist. A higher etch selectivity can thereby be achieved. Due to the improved selectivity, a squarer PR profile can be obtained with improved surface roughness, and/or less photoresist residual/scum. In particular embodiments, PEB can be performed in air and in the optional presence of moisture and CO₂. In other embodiments, PEB can be omitted.

In the case of post-development processing (e.g., post-development bake or PDB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum (e.g., with UV), and moisture can be used to change the composition of the unexposed photoresist. In particular embodiments, the condition also includes use of plasma (e.g., including O₂, O₃, Ar, He, or their mixtures). The change can increase the hardness of material, which can be beneficial if the film will be used as a resist mask when etching the underlying substrate.

In these cases, in alternative implementations, the thermal process could be replaced by a remote plasma process to increase reactive species to lower the energy barrier for the reaction and increase productivity. Remote plasma can generate more reactive radicals and therefore lower the reaction temperature/time for the treatment, leading to increased productivity.

Accordingly, one or multiple processes may be applied to modify the photoresist itself to increase dry or wet development selectivity. This thermal or radical modification can increase the contrast between unexposed and exposed material and thus increase the selectivity of the subsequent development step. The resulting difference between the material properties of unexposed and exposed material can be tuned by adjusting process conditions including temperature, gas flow, moisture, pressure, and/or RF power.

For dry-developed or wet-developed resist films, the treatment temperature in a PAB, PEB, or PDB can be varied to tune and optimize the treatment process, for example from about 90° C. to 250° C. for PAB and about 170° C. to 250° C. or more for PEB and/or PDB. In particular embodiments, PEB is omitted.

In particular embodiments, the PAB, PEB, and/or PDB treatments may be conducted with gas ambient flow in the range of 100 sccm to 10000 sccm, moisture content in the amount of a few percent up to 100% (e.g., 20%-50%), at a pressure between atmospheric and vacuum, and for a duration of about 30 s to 15 min, for example about 1 to 2 min. In particular embodiments, PEB is omitted.

These findings can be used to tune the treatment conditions to tailor or optimize processing for particular materials and circumstances. For example, the selectivity achieved for a given EUV dose with a 220° C. to 250° C. PEB thermal treatment in air at about 20% humidity for about 2 minutes can be made similar to that for about a 30% higher EUV dose with no such thermal treatment. Depending on the selectivity requirements/constraints of the semiconductor processing operation, a thermal treatment such as described herein can be used to lower the EUV dose needed. Or, if higher selectivity is required and higher dose can be tolerated, much higher selectivity, up to 100 times exposed vs. unexposed, can be obtained.

Yet other steps can include in situ metrology, in which physical and structural characteristics (e.g., critical dimension, film thickness, etc.) can be assessed during the photolithography process. Modules to implement in situ metrology include, e.g., scatterometry, ellipsometry, downstream mass spectroscopy, and/or plasma enhanced downstream optical emission spectroscopy modules.

### Apparatuses

The present disclosure also includes any apparatus configured to perform any methods described herein. In one embodiment, the apparatus for depositing a film includes a deposition module comprising a chamber for depositing one or more precursor(s) to provide a film; a patterning module comprising an EUV photolithography tool with a source of sub-30 nm wavelength radiation; and a development module comprising a chamber for developing a film (e.g., with an acid or any development chemistry described herein). Post-development treatment (e.g., with an acid) can be provided within the development module, in another process chamber, or in a separate treatment module.

The apparatus can further include a controller having instructions for such modules. In one embodiment, the controller includes one or more memory devices, one or more processors, and system control software coded with instructions for conducting deposition of the film. Such includes can include for, in the deposition module, depositing one or more precursor(s) to provide a film and optionally conducting a PAB or a post-application treatment of the film; in the patterning module, patterning the film with sub-30 nm resolution directly by EUV exposure, thereby forming a pattern within the film; and in the development module, developing the film. In particular embodiments, the development module provides for removal of the EUV exposed or EUV unexposed region(s), thereby providing a pattern within the film. The development module can include developing the pattern in the presence of an acid.

In another embodiment, the apparatus further includes a post-development treatment module, which can provide a process chamber for conducting a post-development treatment of the film. Any post-development process herein can be performed in the post-development treatment module, in which processes can include performing an acid treatment of a pattern, a post-development bake (PDB) operation, a plasma-based etch process, and/or other operations described herein.

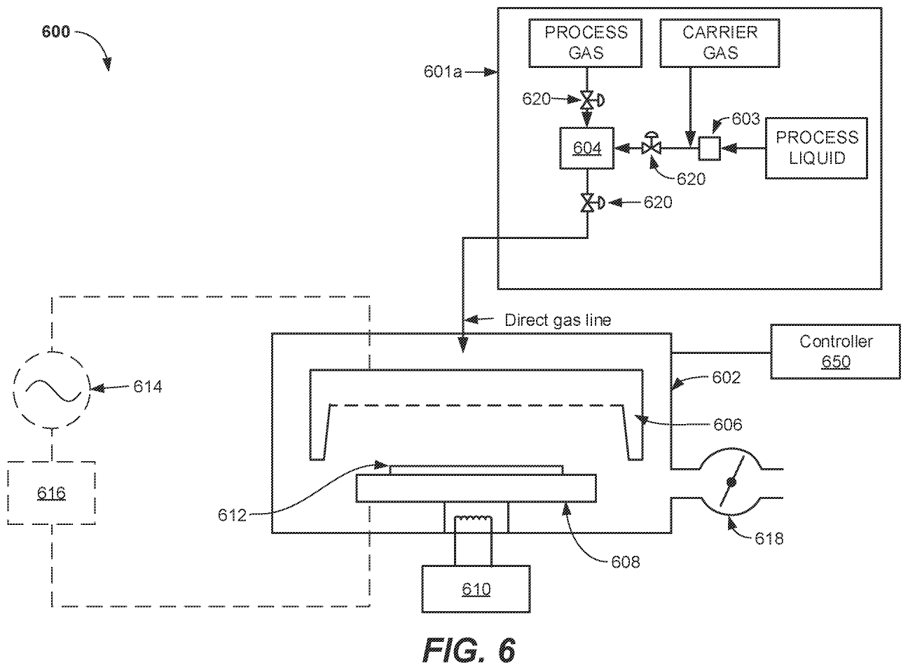

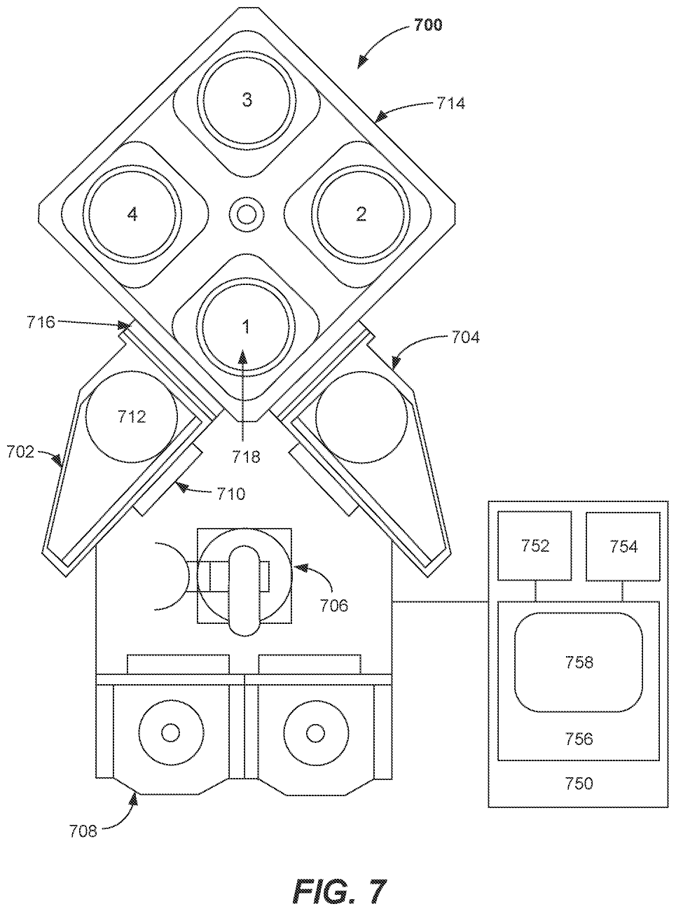

FIG. 6 depicts a schematic illustration of an embodiment of process station 600 having a process chamber body 602 for maintaining a low-pressure environment that is suitable for implementation of described dry deposition and development embodiments as described herein. A plurality of process stations 600 may be included in a common low pressure process tool environment. For example, FIG. 7 depicts an embodiment of a multi-station processing tool 700, such as a VECTOR® processing tool available from Lam Research Corporation, Fremont, CA. In some embodiments, one or more hardware parameters of the process station 600 including those discussed in detail below may be adjusted programmatically by one or more computer controllers 650.

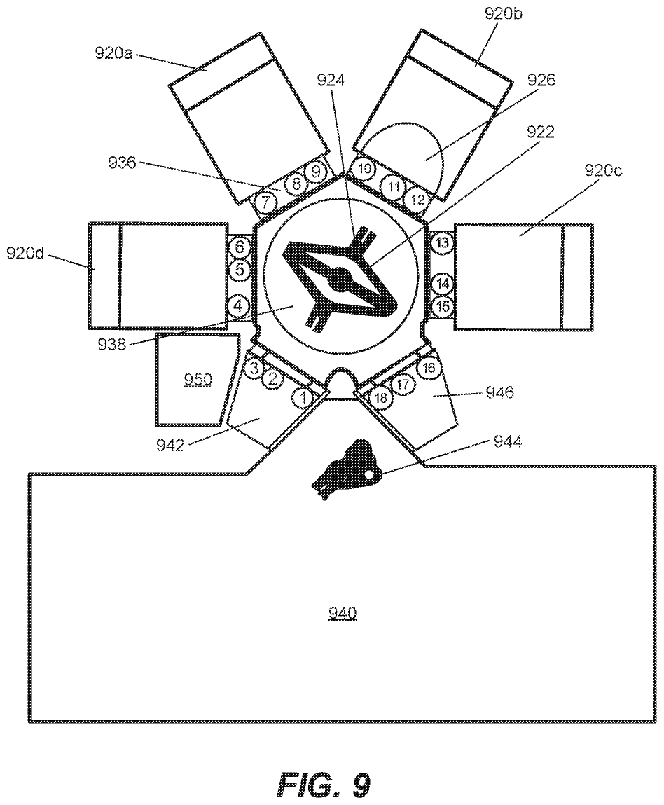

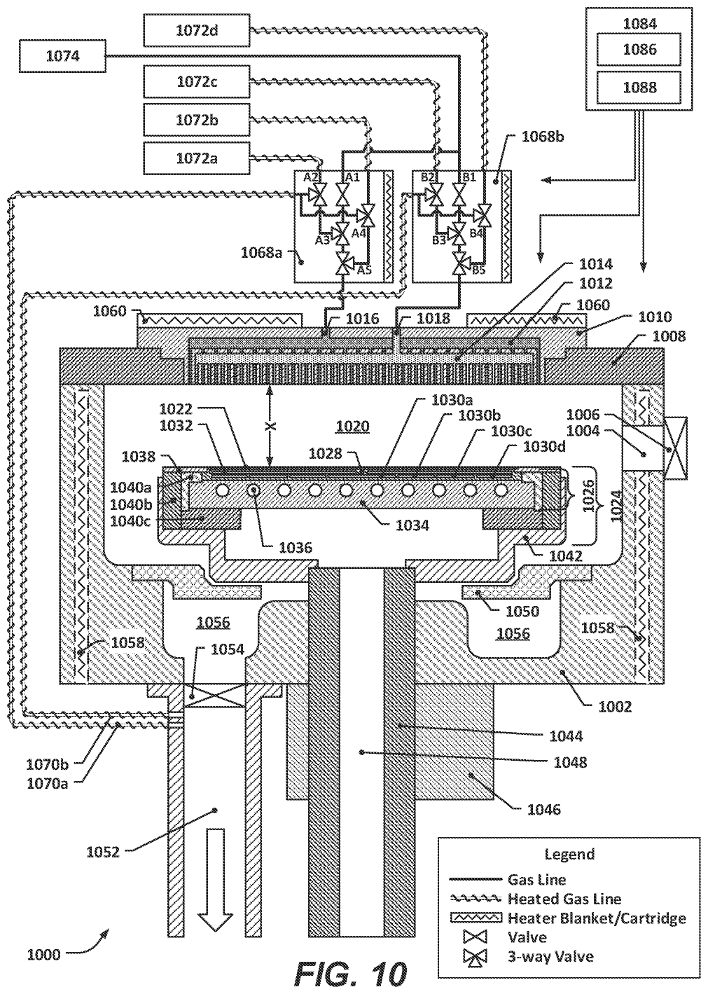

A process station may be configured as a module in a cluster tool. FIG. 9 depicts a semiconductor process cluster tool architecture with vacuum-integrated deposition and patterning modules suitable for implementation of the embodiments described herein. Such a cluster process tool architecture can include resist deposition, resist exposure (EUV scanner), resist development and/or etch modules, as described above and further below with reference to FIGS. 6, 8, and 10.

In some embodiments, certain of the processing functions can be performed consecutively in the same module, for example dry development and etch. And embodiments of this disclosure are directed to methods and apparatus for receiving a wafer, including a photopatterned EUV resist thin film layer disposed on a layer or layer stack to be etched, to a dry development/etch chamber following photopatterning in an EUV scanner; dry developing the photopatterned EUV resist thin film layer; and then etching the underlying layer using the patterned EUV resist as a mask, as described herein.

In other embodiments, all dry processes are employed. Embodiments of this disclosure can be directed to methods and apparatus for receiving a wafer, including a photopatterned EUV resist thin film layer disposed on a layer or layer stack to be etched, to a dry development/etch chamber following photopatterning in an EUV scanner; dry developing the photopatterned EUV resist thin film layer; and then treating the patterned EUV resist within a dry treatment process including an acid. In certain instance, dry developing includes an acid, and the dry treatment process can be optionally omitted. In other instance, dry developing may or may not include an acid, and the dry treatment is performed in the presence of acid.

In other embodiments, differing modules can be employs, especially if a dry process is followed by a wet process or vice versa. Non-limiting embodiments of this disclosure are directed to methods and apparatus for receiving a wafer; depositing an EUV resist thin film layer in a dry deposition process (e.g., using a vapor) or a wet deposition process (e.g., using a liquid), followed by photopatterning in an EUV scanner; and then wet developing or dry developing the photopatterned EUV resist thin film layer (e.g., optionally with an acid), as described herein. Other non-limiting embodiments of this disclosure are directed to methods and apparatus for receiving a wafer; depositing an EUV resist thin film layer in a dry deposition process or a wet deposition process, followed by photopatterning in an EUV scanner; developing the photopatterned EUV resist thin film layer; and then treating the pattern with dry treatment process or a wet treatment process including an acid, as described herein.

Returning to FIG. 6, process station 600 fluidly communicates with reactant delivery system 601a for delivering process gases to a distribution showerhead 606. Reactant delivery system 601a optionally includes a mixing vessel 604 for blending and/or conditioning process gases, for delivery to showerhead 606. One or more mixing vessel inlet valves 620 may control introduction of process gases to mixing vessel 604. Where plasma exposure is used, plasma may also be delivered to the showerhead 606 or may be generated in the process station 600. As noted above, in at least some embodiments, non-plasma thermal exposure is favored.

FIG. 6 includes an optional vaporization point 603 for vaporizing liquid reactant to be supplied to the mixing vessel 604. In some embodiments, a liquid flow controller (LFC) upstream of vaporization point 603 may be provided for controlling a mass flow of liquid for vaporization and delivery to process station 600. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 606 distributes process gases toward substrate 612. In the embodiment shown in FIG. 6 the substrate 612 is located beneath showerhead 606 and is shown resting on a pedestal 608. Showerhead 606 may have any suitable shape, and may have any suitable number and arrangement of ports for distributing process gases to substrate 612.

In some embodiments, pedestal 608 may be raised or lowered to expose substrate 612 to a volume between the substrate 612 and the showerhead 606. It will be appreciated that, in some embodiments, pedestal height may be adjusted programmatically by a suitable computer controller 650.

In some embodiments, pedestal 608 may be temperature controlled via heater 610. In some embodiments, the pedestal 608 may be heated to a temperature of greater than 0° C. and up to 300° C. or more, for example 50 to 120° C., such as about 65 to 80° C., during non-plasma thermal exposure of a photopatterned resist to hydrogen halide dry development chemistry, such as HBr, HCl, or BCl₃, as described in disclosed embodiments.

Further, in some embodiments, pressure control for process station 600 may be provided by a butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to the process station 600.

In some embodiments, a position of showerhead 606 may be adjusted relative to pedestal 608 to vary a volume between the substrate 612 and the showerhead 606. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers 650.

Where plasma may be used, for example in gentle plasma-based dry development embodiments and/or etch operations conducted in the same chamber, showerhead 606 and pedestal 608 electrically communicate with a radio frequency (RF) power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Examples of suitable powers are up to about 500 W.

In some embodiments, instructions for a controller 650 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a recipe phase may include instructions for setting a flow rate of a dry development chemistry reactant gas, such as HBr or HCl, and time delay instructions for the recipe phase. In some embodiments, the controller 650 may include any of the features described below with respect to system controller 750 of FIG. 7.

As described above, one or more process stations may be included in a multi-station processing tool. FIG. 7 shows a schematic view of an embodiment of a multi-station processing tool 700 with an inbound load lock 702 and an outbound load lock 704, either or both of which may include a remote plasma source. A robot 706 at atmospheric pressure is configured to move wafers from a cassette loaded through a pod 708 into inbound load lock 702 via an atmospheric port 710. A wafer is placed by the robot 706 on a pedestal 712 in the inbound load lock 702, the atmospheric port 710 is closed, and the load lock is pumped down. Where the inbound load lock 702 includes a remote plasma source, the wafer may be exposed to a remote plasma treatment to treat the silicon nitride surface in the load lock prior to being introduced into a processing chamber 714. Further, the wafer also may be heated in the inbound load lock 702 as well, for example, to remove moisture and adsorbed gases. Next, a chamber transport port 716 to processing chamber 714 is opened, and another robot (not shown) places the wafer into the reactor on a pedestal of a first station shown in the reactor for processing. While the embodiment depicted in FIG. 7 includes load locks, it will be appreciated that, in some embodiments, direct entry of a wafer into a process station may be provided.

The depicted processing chamber 714 includes four process stations, numbered from 1 to 4 in the embodiment shown in FIG. 7. Each station has a heated pedestal (shown at 718 for station 1), and gas line inlets. It will be appreciated that in some embodiments, each process station may have different or multiple purposes. For example, in some embodiments, a process station may be switchable between dry development and etch process modes. Additionally or alternatively, in some embodiments, processing chamber 714 may include one or more matched pairs of dry development and etch process stations. While the depicted processing chamber 714 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 7 depicts an embodiment of a wafer handling system 790 for transferring wafers within processing chamber 714. In some embodiments, wafer handling system 790 may transfer wafers between various process stations and/or between a process station and a load lock. It will be appreciated that any suitable wafer handling system may be employed. Non-limiting examples include wafer carousels and wafer handling robots. FIG. 7 also depicts an embodiment of a system controller 750 employed to control process conditions and hardware states of process tool 700. System controller 750 may include one or more memory devices 756, one or more mass storage devices 754, and one or more processors 752. Processor 752 may include a CPU or computer, analog, and/or digital input/output connections, stepper motor controller boards, etc.

In some embodiments, system controller 750 controls all of the activities of process tool 700. System controller 750 executes system control software 758 stored in mass storage device 754, loaded into memory device 756, and executed on processor 752. Alternatively, the control logic may be hard coded in the controller 750. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 758 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 700. System control software 758 may be configured in any suitable way. For example, various process tool component subroutines or control objects may be written to control operation of the process tool components used to carry out various process tool processes. System control software 758 may be coded in any suitable computer readable programming language.

In some embodiments, system control software 758 may include input/output control (IOC) sequencing instructions for controlling the various parameters described above. Other computer software and/or programs stored on mass storage device 754 and/or memory device 756 associated with system controller 750 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 718 and to control the spacing between the substrate and other parts of process tool 700.

A process gas control program may include code for controlling hydrogen halide gas composition (e.g., HBr or HCl gas as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 750. The user interface may include a display screen, graphical software displays of the apparatus and/or process conditions, and user input devices such as pointing devices, keyboards, touch screens, microphones, etc.

In some embodiments, parameters adjusted by system controller 750 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 750 from various process tool sensors. The signals for controlling the process may be output on the analog and digital output connections of process tool 700. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 750 may provide program instructions for implementing the above-described deposition processes. The program instructions may control a variety of process parameters, such as DC power level, RF bias power level, pressure, temperature, etc. The instructions may control the parameters to operate dry development and/or etch processes according to various embodiments described herein.

The system controller 750 can include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 750.

In some implementations, the system controller 750 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 750, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 750 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 750 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 750, in some implementations, may be a part of or coupled to a computer that is integrated with, coupled to the system, otherwise networked to the system, or a combination thereof. For example, the system controller 750 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 750 receives instructions in the form of data, which specify parameters for each of the processing steps to be performed during one or more operations. It should be understood that the parameters may be specific to the type of process to be performed and the type of tool that the system controller 750 is configured to interface with or control. Thus, as described above, the system controller 750 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the system controller 750 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Inductively coupled plasma (ICP) reactors which, in certain embodiments, may be suitable for etch operations suitable for implementation of some embodiments, are now described. Although ICP reactors are described herein, in some embodiments, it should be understood that capacitively coupled plasma reactors may also be used.

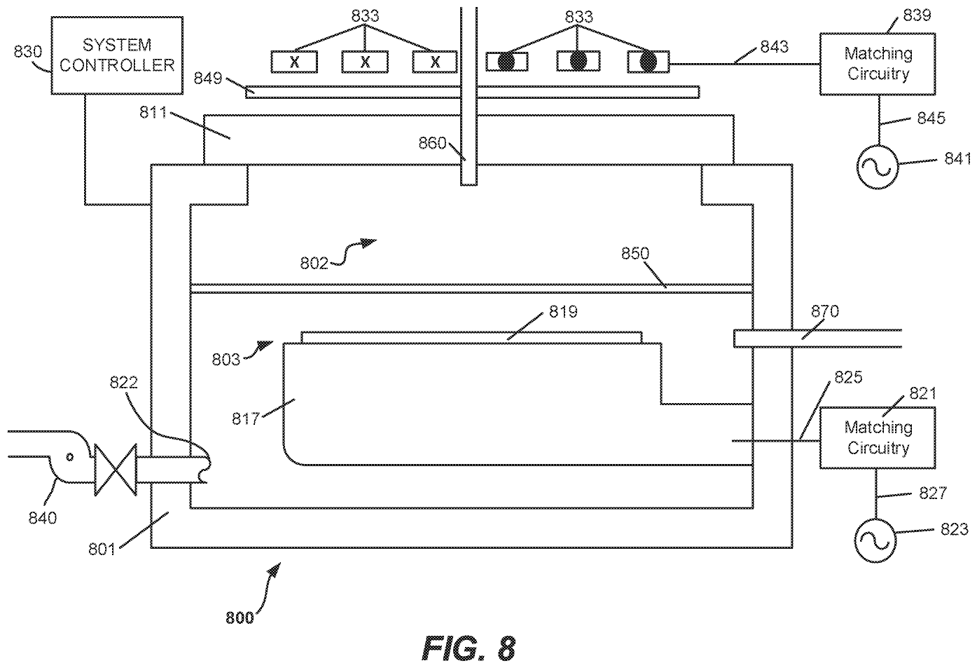

FIG. 8 schematically shows a cross-sectional view of an inductively coupled plasma apparatus 800 appropriate for implementing certain embodiments or aspects of embodiments such as dry development and/or etch, an example of which is a Kiyo® reactor, produced by Lam Research Corp. of Fremont, CA. In other embodiments, other tools or tool types having the functionality to conduct the dry development and/or etch processes described herein may be used for implementation.

The inductively coupled plasma apparatus 800 includes an overall process chamber 824 structurally defined by chamber walls 801 and a window 811. The chamber walls 801 may be fabricated from stainless steel or aluminum. The window 811 may be fabricated from quartz or other dielectric material. An optional internal plasma grid 850 divides the overall process chamber into an upper sub-chamber 802 and a lower sub chamber 803. In most embodiments, plasma grid 850 may be removed, thereby utilizing a chamber space made of sub chambers 802 and 803. A chuck 817 is positioned within the lower sub-chamber 803 near the bottom inner surface. The chuck 817 is configured to receive and hold a semiconductor wafer 819 upon which the etching and deposition processes are performed. The chuck 817 can be an electrostatic chuck for supporting the wafer 819 when present. In some embodiments, an edge ring (not shown) surrounds chuck 817, and has an upper surface that is approximately planar with a top surface of the wafer 819, when present over chuck 817. The chuck 817 also includes electrostatic electrodes for chucking and dechucking the wafer 819. A filter and DC clamp power supply (not shown) may be provided for this purpose. Other control systems for lifting the wafer 819 off the chuck 817 can also be provided. The chuck 817 can be electrically charged using an RF power supply 823. The RF power supply 823 is connected to matching circuitry 821 through a connection 827. The matching circuitry 821 is connected to the chuck 817 through a connection 825. In this manner, the RF power supply 823 is connected to the chuck 817. In various embodiments, a bias power of the electrostatic chuck may be set at about 50 V or may be set at a different bias power depending on the process performed in accordance with disclosed embodiments. For example, the bias power may be between about 20 V and about 100 V, or between about 30 V and about 150 V.

Elements for plasma generation include a coil 833 is positioned above window 811. In some embodiments, a coil is not used in disclosed embodiments. The coil 833 is fabricated from an electrically conductive material and includes at least one complete turn. The example of a coil 833 shown in FIG. 8 includes three turns. The cross sections of coil 833 are shown with symbols, and coils having an “X” extend rotationally into the page, while coils having a “e” extend rotationally out of the page. Elements for plasma generation also include an RF power supply 841 configured to supply RF power to the coil 833. In general, the RF power supply 841 is connected to matching circuitry 839 through a connection 845. The matching circuitry 839 is connected to the coil 833 through a connection 843. In this manner, the RF power supply 841 is connected to the coil 833. An optional Faraday shield 849a is positioned between the coil 833 and the window 811. The Faraday shield 849a may be maintained in a spaced apart relationship relative to the coil 833. In some embodiments, the Faraday shield 849a is disposed immediately above the window 811. In some embodiments, the Faraday shield 849b is between the window 811 and the chuck 817. In some embodiments, the Faraday shield 849b is not maintained in a spaced apart relationship relative to the coil 833. For example, the Faraday shield 849b may be directly below the window 811 without a gap. The coil 833, the Faraday shield 849a, and the window 811 are each configured to be substantially parallel to one another. The Faraday shield 849a may prevent metal or other species from depositing on the window 811 of the process chamber 824.

Process gases may be flowed into the process chamber through one or more main gas flow inlets 860 positioned in the upper sub-chamber 802 and/or through one or more side gas flow inlets 870. Likewise, though not explicitly shown, similar gas flow inlets may be used to supply process gases to a capacitively coupled plasma processing chamber. A vacuum pump, e.g., a one or two stage mechanical dry pump and/or turbomolecular pump 840, may be used to draw process gases out of the process chamber 824 and to maintain a pressure within the process chamber 824. For example, the vacuum pump may be used to evacuate the lower sub-chamber 803 during a purge operation of ALD. A valve-controlled conduit may be used to fluidically connect the vacuum pump to the process chamber 824 so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 800, one or more process gases may be supplied through the gas flow inlets 860 and/or 870. In certain embodiments, process gas may be supplied only through the main gas flow inlet 860, or only through the side gas flow inlet 870. In some cases, the gas flow inlets shown in the figure may be replaced by more complex gas flow inlets, one or more showerheads, for example. The Faraday shield 849a and/or optional grid 850 may include internal channels and holes that allow delivery of process gases to the process chamber 824. Either or both of Faraday shield 849a and optional grid 850 may serve as a showerhead for delivery of process gases. In some embodiments, a liquid vaporization and delivery system may be situated upstream of the process chamber 824, such that once a liquid reactant or precursor is vaporized, the vaporized reactant or precursor is introduced into the process chamber 824 via a gas flow inlet 860 and/or 870.

Radio frequency power is supplied from the RF power supply 841 to the coil 833 to cause an RF current to flow through the coil 833. The RF current flowing through the coil 833 generates an electromagnetic field about the coil 833. The electromagnetic field generates an inductive current within the upper sub-chamber 802. The physical and chemical interactions of various generated ions and radicals with the wafer 819 etch features of and selectively deposit layers on the wafer 819.

If the plasma grid 850 is used such that there is both an upper sub-chamber 802 and a lower sub-chamber 803, the inductive current acts on the gas present in the upper sub-chamber 802 to generate an electron-ion plasma in the upper sub-chamber 802. The optional internal plasma grid 850 limits the amount of hot electrons in the lower sub-chamber 803. In some embodiments, the apparatus 800 is designed and operated such that the plasma present in the lower sub-chamber 803 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 803 through port 822. The chuck 817 disclosed herein may operate at elevated temperatures ranging between about 10° C. and about 250° C. The temperature will depend on the process operation and specific recipe.

Apparatus 800 may be coupled to facilities (not shown) when installed in a clean room or a fabrication facility. Facilities include plumbing that provide processing gases, vacuum, temperature control, and environmental particle control. These facilities are coupled to apparatus 800, when installed in the target fabrication facility. Additionally, apparatus 800 may be coupled to a transfer chamber that allows robotics to transfer semiconductor wafers into and out of apparatus 800 using automation.

In some embodiments, a system controller 830 (which may include one or more physical or logical controllers) controls some or all of the operations of a process chamber 824. The system controller 830 may include one or more memory devices and one or more processors. In some embodiments, the apparatus 800 includes a switching system for controlling flow rates and durations when disclosed embodiments are performed. In some embodiments, the apparatus 800 may have a switching time of up to about 500 ms, or up to about 750 ms. Switching time may depend on the flow chemistry, recipe chosen, reactor architecture, and other factors.

In some implementations, the system controller 830 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 830, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 830 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 830, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 830 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 830 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL). Processing for deposition, PAB, EUV exposure, development, or other post-development process (e.g., PDB, plasma etch, acid treatment, and the like) may be conducted in separate process chambers, and/or process chambers may be configured as a module in a cluster tool architecture with vacuum-integrated deposition and patterning modules suitable for implementation of the embodiments described herein. In some embodiments, certain of the processing functions can be performed consecutively in the same chamber or module, for example dry deposition and PAB.

The EUVL patterning tool may be a standalone device from which the substrate is moved into and out of for deposition and etching as described herein. Or, as described below, the EUVL patterning tool may be a module on a larger multi-component tool. FIG. 9 depicts a semiconductor process cluster tool architecture with vacuum-integrated deposition, EUV patterning and dry development/etch modules that interface with a vacuum transfer module, suitable for implementation of the processes described herein. While the processes may be conducted without such vacuum integrated apparatus, such apparatus may be advantageous in some implementations.

FIG. 9 depicts a semiconductor process cluster tool architecture with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 938 interfaces with four processing modules 920a-920d, which may be individually optimized to perform various fabrication processes. By way of example, processing modules 920a-920d may be implemented to perform deposition, evaporation, ELD, dry development, etch, strip, and/or other semiconductor processes. For example, module 920a may be an ALD reactor that may be operated to perform in a non-plasma, thermal atomic layer depositions as described herein, such as Vector tool, available from Lam Research Corporation, Fremont, CA. And module 920b may be a PECVD tool, such as the Lam Vector®. It should be understood that the figure is not necessarily drawn to scale.

Airlocks 942 and 946, also known as a loadlocks or transfer modules, interface with the VTM 938 and a patterning module 940. For example, as noted above, a suitable patterning module may be the TWINSCAN NXE: 3300B® platform supplied by ASML of Veldhoven, NL). This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a stand-alone EUVL scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 9 but without the integrated patterning module.

Airlock 942 may be an “outgoing” loadlock, referring to the transfer of a substrate out from the VTM 938 serving a deposition module 920a to the patterning module 940, and airlock 946 may be an “ingoing” loadlock, referring to the transfer of a substrate from the patterning module 940 back in to the VTM 938. The ingoing loadlock 946 may also provide an interface to the exterior of the tool for access and egress of substrates. Each process module has a facet that interfaces the module to VTM 938. For example, deposition process module 920a has facet 936. Inside each facet, sensors, for example, sensors 1-18 as shown, are used to detect the passing of wafer 926 when moved between respective stations. Patterning module 940 and airlocks 942 and 946 may be similarly equipped with additional facets and sensors, not shown.

Main VTM robot 922 transfers wafer 926 between modules, including airlocks 942 and 946. In one embodiment, robot 922 has one arm, and in another embodiment, robot 922 has two arms, where each arm has an end effector 924 to pick wafers such as wafer 926 for transport. Front-end robot 944, in is used to transfer wafers 926 from outgoing airlock 942 into the patterning module 940, from the patterning module 940 into ingoing airlock 946. Front-end robot 944 may also transport wafers 926 between the ingoing loadlock and the exterior of the tool for access and egress of substrates. Because ingoing airlock module 946 has the ability to match the environment between atmospheric and vacuum, the wafer 926 is able to move between the two pressure environments without being damaged.

It should be noted that a EUVL tool can operate at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 942 may provide this function by holding the transferred wafers at a lower pressure, no higher than the pressure in the patterning module 940, for a period of time and exhausting any off-gassing, so that the optics of the patterning tool 940 are not contaminated by off-gassing from the substrate. A suitable pressure for the outgoing, off-gassing airlock is no more than 1E-8 Torr.

In some embodiments, a system controller (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 950 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

It should be noted that the computer controlling the wafer movement can be local to the cluster architecture, or can be located external to the cluster architecture in the manufacturing floor, or in a remote location and connected to the cluster architecture via a network. A controller as described above with respect to any of FIG. 6, 7, 8, or 10 may be implemented with the tool in FIG. 9.

FIG. 10 shows an example of a deposition chamber (e.g., for vapor-based deposition of a film). As can be seen, an apparatus 1000 is depicted that has a processing chamber 1002 that includes a lid 1008. The processing chamber 1002 may include a wafer transfer passage 1004 through one of the walls of the processing chamber 1002 that is sized to allow a substrate 1022 to be passed therethrough and into the interior of the processing chamber 1002, where the substrate 1022 may be placed on a wafer support 1024. The wafer transfer passage 1004 may have a gate valve 1006 or similar door mechanism that may be operated to seal or unseal the wafer transfer passage, thereby allowing the environment within the processing chamber 1002 to be isolated from the environment on the other side of the gate valve 1006. For example, the processing chamber 1002 may be provided substrates 1022 via a wafer handling robot that is located in an adjoining transfer chamber. Such a transfer chamber may, for example, have multiple processing chambers 1002 arranged around its periphery, with each such processing chamber 1002 connected with the transfer chamber via a corresponding gate valve 1006.

The wafer support 1024 may, for example, include an electrostatic chuck (ESC) 1026, which may be used to provide a wafer support surface for supporting the substrate 1022. The ESC 1026 may include, for example, a base plate 1034 that is bonded to a top plate 1028 that is placed atop the base plate 1034. The top plate 1028 may, for example, be made of a ceramic material and may have embedded within it several other components. In the depicted example, the top plate 1028 has two separate electrical systems embedded within it. One such system is an electrostatic clamping electrode system, which may have one or more clamping electrodes 1032 that may be used to generate an electric charge within the substrate 1022 that causes the substrate 1022 to be drawn against the wafer support surface of the top plate 1028. In the implementation of FIG. 10, there are two clamping electrodes 1032 that provide a bi-polar electrostatic clamping system, although some implementations may use only a single clamping electrode 1032 to provide a mono-polar electrostatic clamping system.

The other system is a thermal control system that may be used to control the temperature of the substrate 1022 during processing conditions. In FIG. 10, the thermal control system is a multi-zone thermal control system featuring four annular resistance heater traces 1030a, 1030b, 1030c, and 1030d that are concentric with one another and positioned beneath the clamping electrodes 1032. The center resistance heater traces 1030a may, in some implementations, fill a generally circular area, and each resistance heater trace 1030a/b/c/d may follow a generally serpentine or otherwise meandering path within a corresponding annular region. Each resistance heater trace 1030a/b/c/d may be individually controlled to provide a variety of radial heating profiles in the top plate 1028; such a four-zone heating system may, for example, be controlled to maintain the substrate 1022 so as to have a temperature uniformity of +0.5° C. in some cases. While the apparatus 1000 of FIG. 10 features a four-zone heating system in the ESC 1026, other implementations may use single-zone or multi-zone heating systems having more or fewer than four zones.

In some implementations, of, for example, temperature control mechanisms discussed above, heat pumps may be used instead of resistance heating traces. For example, in some implementations, the resistance heater traces may be replaced by, or augmented by, Peltier junctions or other, similar devices that may be controlled to “pump” heat from one side thereof to another. Such mechanisms may be used, for example, to draw heat from the top plate 1028 (and thus the substrate 1022) and direct it into the baseplate 1034 and the heat exchange passages 1036, thereby allowing the substrate 1022 to be cooled more rapidly and more effectively, if desired.

The ESC 1026 may also include, for example, a base plate 1034 that may be used to provide structural support to the underside of the top plate 1028 and which may also act as a heat dispersion system. For example, the base plate 1034 may include one or more heat exchange passages 1036 that are arranged in a generally distributed fashion throughout the base plate 1034, e.g., the heat exchange passages 1036 may follow a serpentine, circular switchback, or spiral pattern around the center of the base plate 1034. A heat exchange medium, e.g., water or inert fluorinated liquid, may be circulated through the heat exchange passages 1036 during use. The flow rate and temperature of the heat exchange medium may be externally controlled so as to result in a particular heating or cooling behavior in the base plate 1034.

The ESC 1026 may, for example, be supported by a wafer support housing 1042 that is connected with, and supported by, a wafer support column 1044. The wafer support column 1044 may, for example, have a routing passage 1048 other pass-throughs for routing cabling, fluid flow conduits, and other equipment to the underside of the base plate 1034 and/or the top plate 1028. For example, while not shown in FIG. 10, cabling for providing electrical power to the resistance heater traces 1030a/b/c/d may be routed through the routing passage 1048, as may cabling for providing electrical power to the clamping electrodes 1032. Other cables, e.g., cables for temperature sensors, may also be routed through the routing passage 1048 to locations in the interior of the wafer support 1024. In implementations with a temperature-controllable base plate 1034, conduits for conveying heat exchange medium to and from the base plate 1034 may also be routed through the routing passage 1048. To avoid undue clutter, such cables and conduits are not depicted in FIG. 10, but it is to be understood that they would, nonetheless, be present.

The apparatus 1000 of FIG. 10 also includes a wafer support z-actuator 1046 that may provide movable support to the wafer support column 1044. The wafer support z-actuator 1046 may be actuated to cause the wafer support column 1044, and the wafer support 1024 supported thereby, to move up or down vertically, e.g., by up to several inches, within a reaction space 1020 of the processing chamber 1002. In doing so, a gap distance X between the substrate 1022 and the underside of the showerhead 1010 may be tuned depending on various process conditions.

The wafer support 1024 may also include, in some implementations, one or more edge rings that may be used to control and/or fine-tune various process conditions. In FIG. 10, an upper edge ring 1038 is provided that lies on top of, for example, lower edge rings 1040a and 1040b, which, in turn, are supported by the wafer support housing 1042 and a third lower edge ring 1040c. The upper edge ring 1038 may, for example, be generally subjected to the same processing environment as the substrate 1022, whereas the lower edge rings 1040a/b/c may generally be shielded from the processing environment. Due to the increased exposure of the upper edge ring 1038, the upper edge ring 1038 may have a limited lifespan and may require more frequent replacement or cleaning as compared with the lower edge rings 1040a/b/c.

The apparatus 1000 may also include a system for removing process gases from the processing chamber 1002 during and after processing concludes. For example, the processing chamber 1002 may include an annular plenum 1056 that encircles the wafer support column 1044. The annular plenum 1056 may, in turn, be fluidically connected with a vacuum foreline 1052 that may be connected with a vacuum pump, e.g., such as may be located beneath a subfloor below the apparatus 1000. A regulator valve 1054 may be provided in between the vacuum foreline 1052 and the processing chamber 1002 and actuated to control the flow into the vacuum foreline 1052. In some implementations, a baffle 1050, e.g., an annular plate or other structure that may serve to make the flow into the annular plenum 1056 more evenly distributed about the circumference of the wafer support column 1044, may be provided to reduce the chances of flow non-uniformities developing in reactants flowed across the substrate 1022.

The showerhead 1010, as shown, is a dual-plenum showerhead 1010 and includes a first plenum 1012 that is provided process gas via a first inlet 1016 and a second plenum 1014 that is provided process gas via a second inlet 1018. Generally, two plenums can be employed to maintain separation between the precursor(s) and the counter-reactant(s) prior to release of the precursor and the counter-reactant. The showerhead 1010 may, in some implementations, have more than two plenums. In some instances, a single plenum is used to deliver the precursor(s) into the reaction space 1020 of the processing chamber 1002. Each plenum may have a corresponding set of gas distribution ports that fluidically connect the respective plenum with the reaction space 1020 through the faceplate of the showerhead 1010 (the faceplate being the portion of the showerhead 1010 that is interposed between the lowermost plenum and the reaction space 1020).

The first inlet 1016 and the second inlet 1018 of the showerhead 1010 may be provided processing gases via a gas supply system, which may be configured to provide one or more precursor(s) and/or counter-reactant(s), as discussed herein. The depicted apparatus 1000 is configured to provide multiple precursors and multiple counter-reactants. For example, a first valve manifold 1068a may be configured to provide precursor(s) to the first inlet 1016, while a second valve manifold 1068b may be configured to provide other precursor(s) or other counter-reactants to the second inlet 1018.

A first valve manifold 1068a may be configured to provide one or more precursor(s) to the first inlet 1016, while a second valve manifold 1068b may be configured to provide other precursor(s) or other reactant to the second inlet 1018. In this example, the first valve manifold 1068a, for example, includes multiple valves A1-A5. Valve A2 may, for example, be a three-way valve that has one port fluidically connected with a first vaporizer 1072a, another port fluidically connected with a bypass line 1070a, and a third port fluidically connected with a port on another 3-way valve A3. Similarly, valve A4 may be another three-way valve that has one port fluidically connected with a second vaporizer 1072b, another port fluidically connected with the bypass line 1070a, and a third port fluidically connected with a port on another 3-way valve A5. One of the other ports on valve A5 may be fluidically connected with the first inlet 1016 while the remaining port on valve A5 may be fluidically connected with one of the remaining ports on the valve A3. The remaining port on the valve A3 may, in turn, be fluidically connected with the valve A1 which may be fluidically interposed between the valve A3 and a purge gas source 1074, e.g., nitrogen, argon, or other suitably inert gas (with respect to precursor(s) and/or counter-reactant(s)). In some embodiments, only the first valve manifold is employed.

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

The first valve manifold 1068a may, for example, be controllable to cause vapors from one or both of the vaporizers 1072a and 1072b to be flowed either to the processing chamber 1002 or through the first bypass line 1070a and into the vacuum foreline 1052. The first valve manifold 1068a may also be controllable to cause a purge gas to be flowed from the purge gas source 1074 and into the first inlet 1016.

For example, to flow vapor from the first vaporizer 1072a into the reaction space 1020, the valve A2 may be actuated to cause the vapor from the first vaporizer 1072a to first flow into the first bypass line 1070a. This flow may be maintained for a period of time sufficient to allow the flow of the vapor to reach steady state flow conditions. After sufficient time has passed (or after a flow meter, if used, indicates that the flow rate is stable), valves A2, A3, and A5 may be actuated to cause the vapor flow from the first vaporizer 1072a to be directed to the first inlet. Similar operations with valves A4 and A5 may be performed to deliver vapor from the second vaporizer 1072b to the first inlet 1016. In some instances, it may be desirable to purge one of the vapors from the first plenum 1012 by actuating the valves A1, A3, and A5 so as to cause the purge gas from the purge gas source 1074 to be flowed into the first inlet 1016. In some additional implementations, it may be desirable to simultaneously flow vapor from one of the vaporizers 1072a or 1072b in tandem with flowing gas from the purge gas into the first inlet 1016. Such implementations may be used to dilute the concentration of the reactant(s) contained in such vapor(s).

It will be appreciated that the second valve manifold 1068b may be controlled in a similar manner, e.g., by controlling valves B1-B5, to provide vapors from vaporizers 1072c and 1072d to the second inlet 1018 or to the second bypass line 1070b. It will be further appreciated that different manifold arrangements may be utilized as well, including a single unitary manifold that includes valves for controlling flow of the precursor(s), counter-reactant(s), or other reactants to the first inlet 1016 and the second inlet 1018.

As mentioned earlier, some apparatuses 1000 may feature a lesser number of vapor sources, e.g., only two vaporizers 1072, in which case the valve manifold(s) 1068 may be modified to have a lesser number of valves, e.g., only valves A1-A3.

As discussed above, apparatuses such as apparatus 1000, which may be used to provide for dry deposition of films, may be configured to maintain particular temperature profiles within the processing chamber 1002. In particular, such apparatuses 1000 may be configured to maintain the substrate 1022 at a lower temperature, e.g., at least 25° C. to 50° C. lower, than most of the equipment of the apparatus 1002 that comes into direct contact with the precursor(s) and/or counter-reactant(s). Additionally, the temperature of the equipment of the apparatus 1000 that comes into direct contact with the precursor(s) and/or counter-reactant(s) may be kept to an elevated level that is sufficiently high that condensation of the vaporized reactants on the surfaces of such equipment is discouraged. At the same time, the substrate 1022 temperature may be controlled to a level that promotes condensation, or at least deposition, of the reactants on the substrate 1022.

To provide for such temperature control, various heating systems may be included in the apparatus 1000. For example, the processing chamber 1002 may have receptacles for receiving cartridge heaters 1058, e.g., for a processing chamber 1002 that has a generally cylindrical interior volume but a square or rectangular external shape, vertical holes for receiving cartridge heaters 1058 may be bored into the four corners of the chamber 1002 housing. In some implementations, the showerhead 1010 may be covered with heater blankets 1060, which may be used to apply heat across the exposed upper surface of the showerhead 1010 to keep the showerhead temperature elevated. It may also be beneficial to heat various gas lines that are used to conduct the vaporized reactants from the vaporizers 1072 to the showerhead 1010. For example, resistive heater tape may be wound around such gas lines and used to heat them to an elevated temperature. As shown in FIG. 10, all of the gas lines that potentially have precursor(s) and/or counter-reactant(s) flowing through them are shown as being heated, including the bypass lines 1070. The only exceptions are the gas lines from the valve manifolds 1068 to the first inlet 1016 and the second inlet 1018, which may be quite short and may be indirectly heated by the showerhead 1010. Of course, even these gas lines may be actively heated, if desired. In some implementations, heaters may be provided proximate to the gate valve 1006 to provide heat to the gate valve as well.

The various operational systems of the apparatus 1000 may be controlled by a controller 1084, which may include one or more processors 1086 and one or more memory devices 1088 that are operatively connected with each other and that are communicatively connected with various systems and subsystems of the apparatus 1000 so as to provide for control functionality for those systems. For example, the controller 1084 may be configured to control the valves A1-A5 and B1-B5, the various heaters 1058, 1060, the vaporizers 1072, the regulator valve 1054, the gate valve 1006, the wafer support z-actuator, and so forth.

Once the film layer has been deposited on the substrate 1022, the substrate 1022 may, as noted above, be transferred to one or more subsequent processing chambers or tool for additional operations (e.g., any described herein). Further deposition apparatuses are described in International Patent Application No. PCT/US2020/038968, filed Jun. 22, 2020, published as International Publication No. WO 2020/263750, titled “APPARATUS FOR PHOTORESIST DRY DEPOSITION,” which is herein incorporated by reference in its entirety.

Embodiments of this disclosure are directed to such processing and processing apparatus.

### EXAMPLES

### Example 1: Dry Development of Organo-Tin-Tellurium (Organo-Sn—Te) Films with Acid

The present disclosure encompasses the use of dry development methods for highly absorbing metal-containing photoresist (PR), such as bimetallic PR containing Sn and Te. Compared to PR including tin oxide hydroxide, a resist film including additional highly absorbing metal elements (e.g., Te, Sb, Bi, and others described herein) can be incorporated to further improve EUV absorption and potentially lower lithographic cost. In some instances, by incorporating elements like Te in the film, EUV absorption can improved by up to 50%, as compared to a control film lacking Te.

Incorporation of new elements can substantially change the materials composition and properties of the PRs, which may require additional development methods. For instance, although similar halide-based chemistry can etch a bimetallic Sn—Te PR material to some extent, the low volatility of Te-containing reaction products (e.g., tellurium halide compounds) and etch selectivity between Sn and Te can bring additional challenges, especially at temperature below room temperature. Using the vapor of acid molecules (e.g., an inorganic acid, an organic acid, or others described herein) with an oxygen-containing reactant, such bimetallic resist materials can be developed. In one non-limiting instance, dry development includes use of a halogen-containing acid (e.g., HCl, HBr, HI, or trifluoroacetic acid) with O₂ as the oxygen-containing reactant. In particular embodiments, mixing the oxygen-containing reactant with one or more etch gases can produce a more consistent etch, as compared to etch gases lacking the oxygen-containing reactant.

In addition to of a halogen-containing acid, development can include the use of molecules that can decompose or hydrolyze to generate an acid molecule. Such molecules can include BCl₃ and the like, which can selectively remove the unexposed organo-Sn—Te films, generating negative tone patterns.

In addition to inorganic acid molecules, organic acids may be employed to selectively remove unexposed regions. In some embodiments, the organic acid has a reasonably high vapor pressure. Non-limiting organic acids include trifluoroacetic acid, formic acid, acetic acid, propionic acid, and others described herein (e.g., in Table 1). In particular embodiments, the organic acid has a vapor pressure of about 1 Torr or greater at 25° C.

TABLE 1

| | Vapor pressure |
|---|---|
| Name | [Torr, at 25° C.] |
| trifluoroacetic acid | 110 Torr |
| formic acid | 42.6 Torr |
| acetic acid | 15.7 Torr |
| propionic acid | 3.53 Torr |
| butyric acid | 1.65 Torr |
| glycolic acid | 0.02 Torr |

After development, additional operations can be performed to remove products formed as a result of exposure to acid. In one instance, a further operation can include exposure to an increased temperature (e.g., at a temperature of up to about 150° C.; at a temperature from about 0° C. to 200° C., 0° C. to 175° C., or 0° C. to 150° C.; or a temperature described herein for a bake operation). In another instance, a further can include exposure to a hard bake operation, e.g., at a temperature of about 0° C. to 300° C., 0° C. to 250° C., or 0° C. to 200° C. Without wishing to be limited my mechanism, an increased temperature can be useful to vaporize the reaction products formed from acid exposure in the unexposed area. The reaction product can be any that results from a reaction between an element within the film and an atom from the acid. A non-limiting reaction product can include a metal halide, in which the film provides the metal and the acid is a halogen-containing acid that provides the halogen. Examples of metal halide includes MX₂, MX₃, or MX₄, in which M is a highly absorbing element (e.g., Te, In, Sn, Sb, and/or Bi) and X is a halogen. Metal halides can also include tellurium halide (e.g., TeCl₂, TeBr₂, TeI₂, and the like). Another non-limiting reaction product can include a metal acetate, in which the film provides the metal and the acid is an acetate-containing acid that provides the acetate.

In yet another instance, a further operation can include exposure to a plasma. Without wishing to be limited by mechanism, plasma may be used to remove residual species or other products formed as a result of exposure to a development operation or to an acid. The plasma can include any chemistry, inert gas, or reactive gas, such a hydrogen halide (e.g., HCl, HBr, HF, and the like) or other halogen-containing molecules (e.g., BCl₃, CₓF_{y}, CₓF_{y}H_{z}, and the like).

In particular embodiment, the dry development strategy described here can enable the all dry process (e.g., from deposition to development) for a highly absorbing metal-containing resist material (e.g., an organo-Sn—Te film).

### Example 2: Wet Development of Organo-Tin-Tellurium (Organo-Sn—Te) Films with Acid

The present disclosure encompasses the use of wet development methods for highly absorbing metal-containing photoresist (PR), such as bimetallic PR containing Sn and Te. Using an acid solution in different solvents or solvent mixtures, such bimetallic resist materials can be developed, generating negative tone patterns. Both acid concentration and the type of solvent/solvent mixture can impact on the selectivity and etch rate, and consequently exposure sensitivity of the resist.

In particular embodiments, an acid solution in different solvents or solvent mixtures can selectively remove unexposed resist materials, generating negative tone patterns. In one embodiments, an inorganic acid within a solution is employed, in which this process showed better selectivity and higher etch rate even at a concentration as low as 0.1% (v/v). Non-limiting inorganic acids include hydrogen halides (e.g., HCl, HBr, HI, and combinations thereof), phosphoric acid, sulfuric acid, and combinations thereof.

In other embodiments, an organic acid within a solution employed. Non-limiting organic acids include formic acid, acetic acid, trifluoroacetic acid, and the like. Such an organic acid can be used in any useful concentration, such as more than about 0.1% (v/v) or from about 0.1% (v/v) to 10% (v/v) of an acid in a solvent (e.g., an aqueous solvent, such as water).

Any solvent can be employed within the solution. In one embodiment, the solvent is an aqueous solvent, e.g., water. In another embodiment, the solvent is an organic solvent. Non-limiting organic solvents include an alcohol (e.g., isopropyl alcohol (IPA)), a ketone (e.g., 2-heptanone, acetone, and the like), an ether (e.g., propylene glycol methyl ether (PGME) or propylene glycol methyl ether acetate (PGMEA)), an ester (e.g., n-butyl acetate, γ-butyrolactone, or ethyl 3-ethoxypropionate (EEP)), as well as combinations thereof, which can be used as a wet developer. The choice of solvent/solvent mixtures can impact the selectivity and/or etch rate.

### Definitions

By “acid” is meant any molecule, ion, or compound capable of donating a proton or forming a covalent bond with an electron pair.

By “acyloxy” or “alkanoyloxy,” as used interchangeably herein, is meant an acyl or alkanoyl group, as defined herein, attached to the parent molecular group through an oxy group. In particular embodiments, the alkanoyloxy is —O—C(O)-Ak, in which Ak is an alkyl group, as defined herein. In some embodiments, an unsubstituted alkanoyloxy is a C₂₋₇ alkanoyloxy group. Exemplary alkanoyloxy groups include acetoxy.

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl. Non-limiting unsubstituted alkenyl groups include allyl and vinyl. In some embodiments, the unsubstituted alkenyl group is a C₂₋₆, C₂₋₈, C₂₋₁₀, C₂₋₁₂, C₂₋₁₆, C₂₋₁₈, C₂₋₂₀, C₂₋₂₄, C₃₋₈, C₃₋₁₀, C₃₋₁₂, C₃₋₁₆, C₃₋₁₈, C₃₋₂₀, or C₃₋₂₄ alkenyl group.

By “alkenylene” is meant a multivalent (e.g., bivalent) form of an alkenyl group, which is an optionally substituted C₂₋₂₄ alkyl group having one or more double bonds. The alkenylene group can be cyclic (e.g., C₃₋₂₄ cycloalkenyl) or acyclic. The alkenylene group can be substituted or unsubstituted. For example, the alkenylene group can be substituted with one or more substitution groups, as described herein for alkyl. Exemplary, non-limiting alkenylene groups include —CH═CH— or —CH═CHCH₂—.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 24 carbon atoms, such as methyl (Me), ethyl (Et), n-propyl (n-Pr), isopropyl (i-Pr), cyclopropyl, n-butyl (n-Bu), isobutyl (i-Bu), s-butyl (s-Bu), t-butyl (t-Bu), cyclobutyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can include haloalkyl, in which the alkyl group is substituted by one or more halo groups, as described herein. In another example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (3) aryl; (4) arylalkoxy (e.g., —O-Lk-Ar, wherein Lk is a bivalent form of optionally substituted alkyl and Ar is optionally substituted aryl); (5) aryloyl (e.g., —C(O)—Ar, wherein Ar is optionally substituted aryl); (6) cyano (e.g., —CN); (7) carboxyaldehyde (e.g., —C(O)H); (8) carboxyl (e.g., —CO₂H); (9) C₃₋₈ cycloalkyl (e.g., a monovalent saturated or unsaturated non-aromatic cyclic C₃₋₈ hydrocarbon group); (10) halo (e.g., F, Cl, Br, or I); (11) heterocyclyl (e.g., a 5-, 6- or 7-membered ring, unless otherwise specified, containing one, two, three, or four non-carbon heteroatoms, such as nitrogen, oxygen, phosphorous, sulfur, or halo); (12) heterocyclyloxy (e.g., —O-Het, wherein Het is heterocyclyl, as described herein); (13) heterocyclyloyl (e.g., —C(O)—Het, wherein Het is heterocyclyl, as described herein); (14) hydroxyl (e.g., —OH); (15) N-protected amino; (16) nitro (e.g., —NO₂); (17) oxo (e.g., ═O); (18) —CO₂R^{A}, where R^{A} is selected from the group consisting of (a) C₁₋₆ alkyl, (b) C₄₋₁₈ aryl, and (c) (C₄₋₁₈ aryl) C₁₋₆alkyl (e.g., -Lk-Ar, wherein Lk is a bivalent form of optionally substituted alkyl group and Ar is optionally substituted aryl); (19) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -Lk-Ar, wherein Lk is a bivalent form of optionally substituted alkyl group and Ar is optionally substituted aryl); and (20) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., Lk-Ar, wherein Lk is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -Lk-Cy, wherein Lk is a bivalent form of optionally substituted alkyl group and Cy is optionally substituted cycloalkyl, as described herein), wherein in one embodiment no two groups are bound to the nitrogen atom through a carbonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₈, C₁₋₁₀, C₁₋₁₂, C₁₋₁₆, C₁₋₁₈, C₁₋₂₀, C₁₋₂₄, C₂₋₆, C₂₋₈, C₂₋₁₀, C₂₋₁₂, C₂₋₁₆, C₂₋₁₈, C₂₋₂₀, C₂₋₂₄, C₃₋₈, C₃₋₁₀, C₃₋₁₂, C₃₋₁₆, C₃₋₁₈, C₃₋₂₀, or C₃₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl. In some embodiments, the unsubstituted alkynyl group is a C₂₋₆, C₂₋₈, C₂₋₁₀, C₂₋₁₂, C₂₋₁₆, C₂₋₁₈, C₂₋₂₀, C₂₋₂₄, C₃₋₈, C₃₋₁₀, C₃₋₁₂, C₃₋₁₆, C₃₋₁₆, C₃₋₂₀, or C₃₋₂₄ alkynyl group.

By “alkynylene” is meant a multivalent (e.g., bivalent) form of an alkynyl group, which is an optionally substituted C₂₋₂₄ alkyl group having one or more triple bonds. The alkynylene group can be cyclic or acyclic. The alkynylene group can be substituted or unsubstituted. For example, the alkynylene group can be substituted with one or more substitution groups, as described herein for alkyl. Exemplary, non-limiting alkynylene groups include —C≡C— or —C≡CCH₂—.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for alkyl or aryl.

By “(aryl)(alkyl)ene” is meant a bivalent form including an arylene group, as described herein, attached to an alkylene or a heteroalkylene group, as described herein. In some embodiments, the (aryl)(alkyl)ene group is -L-Ar— or -L-Ar-L- or —Ar-L-, in which Ar is an arylene group and each L is, independently, an optionally substituted alkylene group or an optionally substituted heteroalkylene group.

By “carbonyl” is meant a —C(O)— group, which can also be represented as >C═O, or a —CO group.

By “carboxyl” is meant a —CO₂H group.

By “carboxylic acid” is meant an acid, as defined herein, having one or more carboxyl groups. Examples of carboxylic acids include a monocarboxylic acid (having a single carboxyl group) or a dicarboxylic acid (having two carboxyl groups).

By “carboxyalkyl” is meant an alkyl group, as defined herein, substituted by one or more carboxyl groups, as defined herein.

By “carboxyaryl” is meant an aryl group, as defined herein, substituted by one or more carboxyl groups, as defined herein.

By “cyclic anhydride” is meant a 3-, 4-, 5-, 6- or 7-membered ring (e.g., a 5-, 6- or 7-membered ring), unless otherwise specified, having a —C(O)—O—C(O)— group within the ring. The term “cyclic anhydride” also includes bicyclic, tricyclic and tetracyclic groups in which any of the above rings is fused to one, two, or three rings independently selected from the group consisting of an aryl ring, a cyclohexane ring, a cyclohexene ring, a cyclopentane ring, a cyclopentene ring, and another monocyclic heterocyclic ring. Exemplary cyclic anhydride groups include a radical formed from succinic anhydride, glutaric anhydride, maleic anhydride, phthalic anhydride, isochroman-1,3-dione, oxepanedione, tetrahydrophthalic anhydride, hexahydrophthalic anhydride, pyromellitic dianhydride, naphthalic anhydride, 1,2-cyclohexanedicarboxylic anhydride, etc., by removing one or more hydrogen. Other exemplary cyclic anhydride groups include dioxotetrahydrofuranyl, dioxodihydroisobenzofuranyl, etc. The cyclic anhydride group can also be substituted or unsubstituted. For example, the cyclic anhydride group can be substituted with one or more groups including those described herein for heterocyclyl.

By “cycloalkenyl” is meant a monovalent unsaturated non-aromatic or aromatic cyclic hydrocarbon group of from three to eight carbons, unless otherwise specified, having one or more double bonds. The cycloalkenyl group can also be substituted or unsubstituted. For example, the cycloalkenyl group can be substituted with one or more groups including those described herein for alkyl.

By “cycloalkyl” is meant a monovalent saturated or unsaturated non-aromatic or aromatic cyclic hydrocarbon group of from three to eight carbons, unless otherwise specified, and is exemplified by cyclopropyl, cyclobutyl, cyclopentyl, cyclopentadienyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “halo” is meant F, Cl, Br, or I.

By “haloalkenyl” is meant an alkenyl group, as defined herein, substituted with one or more halo.

By “haloalkyl” is meant an alkyl group, as defined herein, substituted with one or more halo.

By “haloalkynyl” is meant an alkynyl group, as defined herein, substituted with one or more halo.

By “haloaryl” is meant an aryl group, as defined herein, substituted with one or more halo.

By “heteroalkyl” is meant an alkyl group, as defined herein, containing one, two, three, or four non-carbon heteroatoms (e.g., independently selected from the group consisting of nitrogen, oxygen, phosphorous, sulfur, selenium, or halo).

By “heteroalkylene” is meant a bivalent form of an alkyl group, as defined herein, containing one, two, three, or four non-carbon heteroatoms (e.g., independently selected from the group consisting of nitrogen, oxygen, phosphorous, sulfur, selenium, or halo). The heteroalkylene group can be substituted or unsubstituted. For example, the heteroalkylene group can be substituted with one or more substitution groups, as described herein for alkyl.

By “heterocyclyl” is meant a 3-, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofiranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl benzylsultimyl, bipyrazinyl, bipyridinyl, carbazolyl (e.g., 4H-carbazolyl), carbolinyl (e.g., β-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for alkyl.

By “hydrocarbyl” is meant a univalent group formed by removing a hydrogen atom from a hydrocarbon. Non-limiting unsubstituted hydrocarbyl groups include alkyl, alkenyl, alkynyl, and aryl, as defined herein, in which these groups include only carbon and hydrogen atoms. The hydrocarbyl group can be substituted or unsubstituted. For example, the hydrocarbyl group can be substituted with one or more substitution groups, as described herein for alkyl. In other embodiments, any alkyl or aryl group herein can be replaced with a hydrocarbyl group, as defined herein.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like.

By “hydroxyaryl” is meant an aryl group, as defined herein, substituted by one to three hydroxyl groups, with the proviso that no more than one hydroxyl group may be attached to a single carbon atom of the aryl group and is exemplified by hydroxyphenyl, dihydroxyphenyl, and the like.

By “isocyanato” is meant —NCO.

By “oxido” is meant an —O⁻ group.

By “oxo” is meant an ═O group.

By “oxoacid” is meant an acid, as defined herein, that contains one or more oxygen atoms. Non-limiting oxoacids include a phosphorous oxoacid (e.g., an oxoacid, as defined herein, including one or more phosphorous atoms) or a sulfur oxoacid (e.g., an oxoacid, as defined herein, including one or more sulfur atoms).

By “phosphine” is meant a trivalent or tetravalent phosphorous having hydrocarbyl moieties. In some embodiments, phosphine is a —PR^{P}₃ group, where each R^{P} is, independently, H, optionally substituted alkyl, or optionally substituted aryl. The phosphine group can be substituted or unsubstituted. For example, the phosphine group can be substituted with one or more substitution groups, as described herein for alkyl.

By “selenol” is meant an —SeH group.

By “tellurol” is meant an —TeH group.

By “thioisocyanato” is meant —NCS.

By “thiol” is meant an —SH group.

As used herein, the terms “top,” “bottom,” “upper,” “lower,” “above,” and “below” are used to provide a relative relationship between structures. The use of these terms does not indicate or require that a particular structure must be located at a particular location in the apparatus.

### CONCLUSION

Process and apparatus for use of an acid for developing or treating a radiation-sensitive film. In some instances, use of the acid (in a dry or wet process) for negative tone development of dry deposited (e.g., by chemical vapor deposition (CVD)) EUV photopatternable resist films, is disclosed. In other instances, use of the acid (in a dry or wet process) for removing residual resist components is also disclosed.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the disclosure.

The following sample claims are provided for further illustration of certain embodiments of the disclosure. The disclosure is not necessarily limited to these embodiments.

1. A method comprising:
exposing a radiation-sensitive resist film to a patterning radiation source, thereby providing an exposed resist film having an exposed region and an unexposed region, wherein the resist film comprises two or more elements having a high patterning radiation-absorption cross-section;
developing the exposed resist film by removing the unexposed region, thereby forming a pattern by a negative tone development process; and
optionally treating the pattern,
wherein the method comprises either:
performing said developing in the presence of an acid, or
performing said treating the pattern in the presence of an acid.

2. The method of claim 1, wherein the method comprises performing said developing in the presence of an acid.

3. (canceled)

4. The method of claim 2, wherein said developing comprises delivering a vapor of an acid or a reactant configured to provide the acid to the exposed film.

5. The method of claim 4, wherein the reactant configured to provide the acid comprises a halogenated borane, trichloroborane (BCl₃), tribromoborane (BBr₃), triiodoborane (BI₃), a halogenated silane, tetrachlorosilane (SiCl₄), tetrabromosilane (SiBr₄), tetraiodosilane (SiI₄), or a trialkyl silyl halide including trimethylsilyl chloride, trimethylsilyl bromide, trimethylsilyl iodide, triethylsilyl chloride, triethylsilyl bromide, triethylsilyl iodide, tripropylsilyl chloride, tripropylsilyl bromide, tripropylsilyl iodide, triisopropylsilyl chloride, triisopropylsilyl bromide, triisopropylsilyl iodide, tributylsilyl chloride, tributylsilyl bromide, tributylsilyl iodide, triisobutylsilyl chloride, triisobutylsilyl bromide, triisobutylsilyl iodide, trisecbutylsilyl chloride, trisecbutylsilyl bromide, trisecbutylsilyl iodide, tritertbutylsilyl chloride, tritertbutylsilyl bromide, tritertbutylsilyl iodide, dimethyl-ethyl-silyl chloride, dimethyl-propyl-silyl chloride, dimethyl-isopropyl-silyl chloride, dimethyl-butyl-silyl chloride, dimethyl-isobutyl-silyl chloride, dimethyl-secbutyl-silyl chloride, dimethyl-tertbutyl-silyl chloride, dimethyl-tertbutyl-silyl bromide, dimethyl-tertbutyl-silyl iodide, methyl-diethyl-silyl chloride, methyl-diethyl-silyl bromide, methyl-diethyl-silyl iodide, methyl-dipropyl-silyl chloride, methyl-diisopropyl-silyl chloride, methyl-dibutyl-silyl chloride, methyl-diisobutyl-silyl chloride, methyl-disecbutyl-silyl chloride, methyl-ditertbutyl-silyl chloride, methyl-ditertbutyl-silyl bromide, methyl-ditertbutyl-silyl iodide, a dialkyl dihalo silane including: dimethyldichloro silane, dimethyldibromo silane, dimethyldiiodo silane, diethyldichloro silane, diethyldibromo silane, diethyldiiodo silane, dipropyldichloro silane, dipropyldibromo silane, dipropyldiiodo silane, diisopropyldichloro silane, diisopropyldibromo silane, diisopropyldiiodo silane, dibutyldichloro silane, dibutyldibromo silane, dibutyldiiodo silane, diisobutyldichloro silane, diisobutyldibromo silane, diisobutyldiiodo silane, disecbutyldichloro silane, disecbutyldibromo silane, disecbutyldiiodo silane, ditertbutyldichloro silane, ditertbutyldibromo silane, ditertbutyldiiodo silane, methyl-ethyl-dichloro silane, methyl-ethyl-dibromo silane, methyl-ethyl-diiodo silane, methyl-propyl-dichloro silane, methyl-isopropyl-dichloro silane, methyl-butyl-dichloro silane, methyl-isobutyl-dichloro silane, methyl-secbutyl-dichloro silane, methyl-tertbutyl-dichloro silane, methyl-tertbutyl-dibromide silane, methyl-tertbutyl-diiodo silane, or a combination thereof.

6. The method of claim 4, wherein the acid comprises an inorganic acid, a halogen-containing acid, a hydrogen halide, an organic acid, a phosphorus oxoacid, a sulfur oxoacid, a carboxylic acid, or a silyl halide.

7. The method of claim 6, wherein the inorganic acid is selected from the group consisting of hydrogen chloride (HCl), hydrogen bromide (HBr), hydrogen iodide (HI), and a combination thereof.

8. (canceled)

9. The method of claim 6, wherein the organic acid comprises formic acid, acetic acid, trifluoroacetic acid, or a combination thereof.

10. (canceled)

11. (canceled)

12. The method of claim 2, wherein said developing comprises delivering the acid in a solvent.

13. The method of claim 12, wherein the solvent is an aqueous solvent or an organic solvent; or wherein the solvent comprises water, an alcohol, a ketone, an ether, an ester, or a combination thereof.

14. The method of claim 12, wherein the acid comprises an inorganic acid, a halogen-containing acid, a hydrogen halide, an organic acid, a phosphorus oxoacid, a sulfur oxoacid, a carboxylic acid, or a silyl halide.

15. The method of claim 14, wherein the inorganic acid is selected from the group consisting of hydrogen chloride (HCl), hydrogen bromide (HBr), hydrogen iodide (HI), phosphoric acid, sulfuric acid, and a combination thereof.

16. The method of claim 14, wherein the organic acid comprises formic acid, acetic acid, trifluoroacetic acid, oxalic acid, citric acid, or a combination thereof.

17. (canceled)

18. The method of claim 1, further comprising, after said developing:
performing a plasma-based etch process.

19. The method of claim 1, further comprising, after said developing:
performing a post-development bake (PDB).

20. The method of claim 1, wherein the method comprises performing said treating the pattern in the presence of an acid.

21. The method of claim 20, wherein said developing comprises use of an acidic developer.

22. The method of claim 20, wherein said developing comprises use of a vapor-based acidic etchant.

23. The method of claim 22, wherein the vapor-based acidic etchant comprises hydrogen chloride (HCl), hydrogen bromide (HBr), boron trichloride (BCl₃), silicon tetrachloride (SiCl₄), a combination of hydrogen gas (H₂) and chlorine gas (Cl₂), or a combination of hydrogen gas (H₂) and bromine gas (Br₂), a trialkyl silyl halide including trimethylsilyl chloride, trimethylsilyl bromide, trimethylsilyl iodide, triethylsilyl chloride, triethylsilyl bromide, triethylsilyl iodide, tripropylsilyl chloride, tripropylsilyl bromide, tripropylsilyl iodide, triisopropylsilyl chloride, triisopropylsilyl bromide, triisopropylsilyl iodide, tributylsilyl chloride, tributylsilyl bromide, tributylsilyl iodide, triisobutylsilyl chloride, triisobutylsilyl bromide, triisobutylsilyl iodide, trisecbutylsilyl chloride, trisecbutylsilyl bromide, trisecbutylsilyl iodide, tritertbutylsilyl chloride, tritertbutylsilyl bromide, tritertbutylsilyl iodide, dimethyl-ethyl-silyl chloride, dimethyl-propyl-silyl chloride, dimethyl-isopropyl-silyl chloride, dimethyl-butyl-silyl chloride, dimethyl-isobutyl-silyl chloride, dimethyl-secbutyl-silyl chloride, dimethyl-tertbutyl-silyl chloride, dimethyl-tertbutyl-silyl bromide, dimethyl-tertbutyl-silyl iodide, methyl-diethyl-silyl chloride, methyl-diethyl-silyl bromide, methyl-diethyl-silyl iodide, methyl-dipropyl-silyl chloride, methyl-diisopropyl-silyl chloride, methyl-dibutyl-silyl chloride, methyl-diisobutyl-silyl chloride, methyl-disecbutyl-silyl chloride, methyl-ditertbutyl-silyl chloride, methyl-ditertbutyl-silyl bromide, methyl-ditertbutyl-silyl iodide, a dialkyl dihalo silane including: dimethyldichloro silane, dimethyldibromo silane, dimethyldiiodo silane, diethyldichloro silane, diethyldibromo silane, diethyldiiodo silane, dipropyldichloro silane, dipropyldibromo silane, dipropyldiiodo silane, diisopropyldichloro silane, diisopropyldibromo silane, diisopropyldiiodo silane, dibutyldichloro silane, dibutyldibromo silane, dibutyldiiodo silane, diisobutyldichloro silane, diisobutyldibromo silane, diisobutyldiiodo silane, disecbutyldichloro silane, disecbutyldibromo silane, disecbutyldiiodo silane, ditertbutyldichloro silane, ditertbutyldibromo silane, ditertbutyldiiodo silane, methyl-ethyl-dichloro silane, methyl-ethyl-dibromo silane, methyl-ethyl-diiodo silane, methyl-propyl-dichloro silane, methyl-isopropyl-dichloro silane, methyl-butyl-dichloro silane, methyl-isobutyl-dichloro silane, methyl-secbutyl-dichloro silane, methyl-tertbutyl-dichloro silane, methyl-tertbutyl-dibromide silane, methyl-tertbutyl-diiodo silane, or a combination thereof.

24. The method of claim 20, wherein said treating comprises removing a residual species containing at least one of the two or more elements having the high patterning radiation-absorption cross-section.

25. (canceled)

26. The method of claim 24, wherein said treating comprises delivering a vapor of the acid or a reactant configured to provide the acid to the exposed film.

27. The method of claim 26, wherein the acid comprises an inorganic acid, a halogen-containing acid, a hydrogen halide, an inorganic acid, a phosphorus oxoacid, a sulfur oxoacid, or a carboxylic acid.

28. The method of claim 27, wherein the reactant configured to provide the acid comprises a halogenated borane, trichloroborane (BCl₃), tribromoborane (BBr₃), triiodoborane (BI₃), a halogenated silane, tetrachlorosilane (SiCl₄), tetrabromosilane (SiBr₄), tetraiodosilane (SiI₄), a trialkyl silyl halide including trimethylsilyl chloride, trimethylsilyl bromide, trimethylsilyl iodide, triethylsilyl chloride, triethylsilyl bromide, triethylsilyl iodide, tripropylsilyl chloride, tripropylsilyl bromide, tripropylsilyl iodide, triisopropylsilyl chloride, triisopropylsilyl bromide, triisopropylsilyl iodide, tributylsilyl chloride, tributylsilyl bromide, tributylsilyl iodide, triisobutylsilyl chloride, triisobutylsilyl bromide, triisobutylsilyl iodide, trisecbutylsilyl chloride, trisecbutylsilyl bromide, trisecbutylsilyl iodide, tritertbutylsilyl chloride, tritertbutylsilyl bromide, tritertbutylsilyl iodide, dimethyl-ethyl-silyl chloride, dimethyl-propyl-silyl chloride, dimethyl-isopropyl-silyl chloride, dimethyl-butyl-silyl chloride, dimethyl-isobutyl-silyl chloride, dimethyl-secbutyl-silyl chloride, dimethyl-tertbutyl-silyl chloride, dimethyl-tertbutyl-silyl bromide, dimethyl-tertbutyl-silyl iodide, methyl-diethyl-silyl chloride, methyl-diethyl-silyl bromide, methyl-diethyl-silyl iodide, methyl-dipropyl-silyl chloride, methyl-diisopropyl-silyl chloride, methyl-dibutyl-silyl chloride, methyl-diisobutyl-silyl chloride, methyl-disecbutyl-silyl chloride, methyl-ditertbutyl-silyl chloride, methyl-ditertbutyl-silyl bromide, methyl-ditertbutyl-silyl iodide, a dialkyl dihalo silane including: dimethyldichloro silane, dimethyldibromo silane, dimethyldiiodo silane, diethyldichloro silane, diethyldibromo silane, diethyldiiodo silane, dipropyldichloro silane, dipropyldibromo silane, dipropyldiiodo silane, diisopropyldichloro silane, diisopropyldibromo silane, diisopropyldiiodo silane, dibutyldichloro silane, dibutyldibromo silane, dibutyldiiodo silane, diisobutyldichloro silane, diisobutyldibromo silane, diisobutyldiiodo silane, disecbutyldichloro silane, disecbutyldibromo silane, disecbutyldiiodo silane, ditertbutyldichloro silane, ditertbutyldibromo silane, ditertbutyldiiodo silane, methyl-ethyl-dichloro silane, methyl-ethyl-dibromo silane, methyl-ethyl-diiodo silane, methyl-propyl-dichloro silane, methyl-isopropyl-dichloro silane, methyl-butyl-dichloro silane, methyl-isobutyl-dichloro silane, methyl-secbutyl-dichloro silane, methyl-tertbutyl-dichloro silane, methyl-tertbutyl-dibromide silane, methyl-tertbutyl-diiodo silane, or a combination thereof.

29. (canceled)

30. (canceled)

31. The method of claim 24, wherein said treating comprises delivering the acid in a solvent.

32. The method of claim 31, wherein the acid comprises an inorganic acid, a halogen-containing acid, a hydrogen halide, an organic acid, a phosphorus oxoacid, a sulfur oxoacid, a carboxylic acid, or a silyl halide.

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)
